(19) United States
(12) Patent Application Publication
(10) Pub. No.: US 2022/0020981 A1
(43) Pub. Date: Jan. 20, 2022

(54) POSITIVE ELECTRODE ACTIVE MATERIAL, SECONDARY BATTERY, ELECTRONIC DEVICE, AND VEHICLE

(71) Applicant: SEMICONDUCTOR ENERGY LABORATORY CO., LTD., ATSUGI-SHI, KANAGAWA-KEN (JP)

(72) Inventors: Yohei MOMMA, Isehara, Kanagawa (JP); Mayumi MIKAMI, Atsugi, Kanagawa (JP); Teruaki OCHIAI, Atsugi, Kanagawa (JP); Kazuhei NARITA, Ota, Tokyo (JP); Jyo SAITO, Atsugi, Kanagawa (JP)

(21) Appl. No.: 17/292,471

(22) PCT Filed: Nov. 7, 2019
(86) PCT No.: PCT/IB2019/059559

§ 371 Date: May 10, 2021

(30) Foreign Application Priority Data
Nov. 16, 2018 (JP) 2018-215956
Nov. 21, 2018 (JP) 2018-218471

(51) Int. Cl. H01M 4/525; H01M 10/0525; H01M 4/38; H01M 4/58; B60L 58/12

(52) U.S. Cl. CPC H01M 4/525; H01M 10/0525; H01M 2010/4292; H01M 4/582; B60L 58/12; H01M 4/382

(57) ABSTRACT

A positive electrode active material for a lithium ion secondary battery which has a large capacity and a good charge-and-discharge cycle performance is provided. The positive electrode active material includes lithium, cobalt, oxygen, and magnesium, and has a compound represented by a layered rock-salt crystal structure. A space group of the compound is represented by R-3m. The compound is a composite oxide in which magnesium is substituted for a lithium position and a cobalt position. The compound is a particle. The magnesium substituted for a lithium position and a cobalt position exists more in the region from the surface to 5 nm than in the region deeper than 10 nm from the surface. More magnesium is substituted for a lithium position than for a cobalt position.

### TECHNICAL FIELD

One embodiment of the present invention relates to an object, a method, or a manufacturing method. Alternatively, the present invention relates to a process, a machine, manufacture, or a composition (composition of matter). One embodiment of the present invention relates to a semiconductor device, a display device, a light-emitting device, a power storage device, a lighting device, an electronic device, or a manufacturing method thereof. In particular, one embodiment of the present invention relates to a positive electrode active material that can be used for a secondary battery, a secondary battery, and an electronic device including a secondary battery.

Note that in this specification, a power storage device refers to every element and device having a function of storing power. Examples of the power storage device include a storage battery (also referred to as a secondary battery) such as a lithium-ion secondary battery, a lithium-ion capacitor, and an electric double layer capacitor.

In addition, electronic devices in this specification mean all devices including power storage devices, and electro-optical devices including power storage devices, information terminal devices including power storage devices, and the like are all electronic devices.

### BACKGROUND ART

In recent years, a variety of power storage devices such as lithium-ion secondary batteries, lithium-ion capacitors, and air batteries have been actively developed. In particular, demand for lithium-ion secondary batteries with high output and high energy density have rapidly grown with development of the semiconductor industry, for portable information terminals such as mobile phones, smartphones, tablets, and laptop computers; portable music players; digital cameras; medical equipment; next-generation clean energy vehicles (such as hybrid electric vehicles (HEV), electric vehicles (EV), plug-in hybrid electric vehicles (PHEV)); and the like; lithium-ion secondary batteries are essential as rechargeable energy supply sources for today's information society.

Performances required for lithium-ion secondary batteries include much higher energy density, improved cycle performance, safety under a variety of environments, improved long-term reliability, and the like.

Thus, improvement of a positive electrode active material has been studied to improve the cycle performance and increase the capacity of lithium-ion secondary batteries (Patent Document 1 and Patent Document 2). In addition, a crystal structure of a positive electrode active material also has been studied (Non-Patent Document 1 to Non-Patent Document 3).

X-ray diffraction (XRD) is a method used for analyzing a crystal structure of a positive electrode active material. With the use of the ICSD (Inorganic Crystal Structure Database) shown in Non-Patent Document 5, XRD data can be analyzed.

Non-patent document 6 and Non-patent document 7 show that an energy of a compound corresponding to its crystal structure, composition, and the like can be calculated using the first-principles calculation.

### REFERENCE

### Patent Document

[Patent Document 1] Japanese Patent Application Laid-Open No. 2002-216760
[Patent Document 2] Japanese Patent Application Laid-Open No. 2006-261132

### Non-Patent Document

[Non-Patent Document 1] Toyoki Okumura et al., “Correlation of lithium ion distribution and X-ray absorption near-edge structure in O3- and O2-lithium cobalt oxides from first-principle calculation”, Journal of Materials Chemistry, 2012, 22, pp. 17340-17348.
[Non-Patent Document 2] Motohashi, T. et al., “Electronic phase diagram of the layered cobalt oxide system LiₓCoO₂ (0.0≤x≤1.0)”, Physical Review B, 80 (16); 165114.
[Non-Patent Document 3] Zhaohui Chen et al., “Staging Phase Transitions in LiₓCoO₂, Journal of The Electrochemical Society, 2002, 149 (12) A1604-A1609.
[Non-Patent Document 4] W. E. Counts et al., Journal of the American Ceramic Society, (1953), 36 [1] 12-17. FIG. 01471.
[Non-Patent Document 5] Belsky, A. et al., “New developments in the Inorganic Crystal Structure Database (ICSD): accessibility in support of materials research and design”, Acta Cryst. (2002), B58, 364-369.
[Non-Patent Document 6] Dudarev, S. L. et al, “Electron-energy-loss spectra and the structural stability of nickel oxide: An LSDA1U study”, Physical Review B, 1998, 57(3) 1505.
[Non-Patent Document 7] Zhou, F. et al, “First-principles prediction of redox potentials in transition-metal compounds with LDA+U”, Physical Review B, 2004, 70 235121.

### SUMMARY OF THE INVENTION

### Problems to be Solved by the Invention

An object of one embodiment of the present invention is to provide a positive electrode active material that has high capacity and excellent charge-and-discharge cycle performance for a lithium-ion secondary battery, and a manufacturing method thereof. Another object of one embodiment of the present invention is to provide a manufacturing method of a positive electrode active material with high productivity. Another object of one embodiment of the present invention is to provide a positive electrode active material that suppresses a decrease in capacity in charge-and-discharge cycles when used in a lithium-ion secondary battery. Another object of one embodiment of the present invention is to provide a secondary battery with a large capacity. Another object of one embodiment of the present invention is to provide a secondary battery with excellent charge-and-discharge performance. Another object is to provide a positive electrode active material in which elution of a transition metal such as cobalt is suppressed even when a state being charged with a high voltage is held for a long time. Another object of one embodiment of the present invention is to provide a highly safe or reliable secondary battery.

Another object of one embodiment of the present invention is to provide a novel material, novel active material particles, a novel power storage device, or a manufacturing method thereof.

Note that the description of these objects does not preclude the existence of other objects. One embodiment of the present invention does not have to achieve all these objects. Note that other objects can be taken from the description of the specification, the drawings, and the claims.

### Means for Solving the Problems

One embodiment of the present invention is a positive electrode active material including lithium, cobalt, oxygen, and magnesium and a compound represented as a layered rock-salt crystal structure. A space group of the compound is represented as R-3m. The compound is a compound in which magnesium is substituted for a lithium position and a cobalt position of a composite oxide including lithium and cobalt. The compound is a particle. Magnesium substituted for the lithium position and the cobalt position exists more in a region from a surface of the particle to 5 nm than in a region at a depth of 10 nm or more from the surface. More magnesium is substituted for the lithium position than for the cobalt position.

In the above structure, the positive electrode active material contains fluorine, for example.

In the above structure, for example, the compound has a charge depth with a cobalt coordinate (0,0,0.5) and an oxygen coordinate (0,0,x) (0.20≤x≤0.25) in a unit cell, and a volume of the unit cell at the charge depth differs from a volume of the unit cell at a charge depth of 0 by 2.5% or less.

Alternatively, one embodiment of the present invention is a secondary battery including the positive electrode active material described above.

Alternatively, one embodiment of the present invention is a secondary battery; a charging voltage is V and an amount of change of V is dV; a charging capacity is Q and an amount of change of Q is dQ; in a dQ/dV vs V curve which shows a relation between dQ/dV, which is a ratio of dQ to dV, and V, the dQ/dV vs V curve is measured at a rate greater than or equal to 0.1 C and less than or equal to 1.0 C; the measurement is performed at a temperature greater than or equal to of 10° C. and less than or equal to 35° C.; the dQ/dV vs V curve is measured twice within the V range of 4.54 V to 4.58 V; the dQ/dV vs V curve includes a first peak in the second measurement within the V range of 4.54 V to 4.58 V; the voltage is a voltage with reference to a redox potential of lithium metal.

In the above structure, for example, the dQ/dV vs V curve is measured within the V range of 4.05 V to 4.58 V, the dQ/dV vs V curve has a second peak within the V range of 4.08 V to 4.18 V, the dQ/dV vs V curve has a third peak within the V range of 4.18 V to 4.25 V, and the voltage is a voltage with reference to a redox potential of lithium metal.

In the above structure, for example, the secondary battery includes a positive electrode; at a charging voltage V at which the second peak is observed, the positive electrode has a crystal structure corresponding to a space group P2/m; at a charging voltage V at which the first peak is observed, the positive electrode has a crystal structure corresponding to a space group R-3m.

In the above structure, for example, the secondary battery includes a negative electrode, and the negative electrode is lithium metal.

In the above structure, for example, the positive electrode is taken out from the secondary battery, and the dQ/dV vs V curve is measured using lithium metal as a counter electrode of the positive electrode.

Alternatively, one embodiment of the present invention is a secondary battery; a charging voltage is V and an amount of change of V is dV; a charging capacity is Q and an amount of change of Q is dQ; in a dQ/dV vs V curve which shows a relation between dQ/dV, which is a ratio of dQ to dV, and V, the dQ/dV vs V curve is measured at a rate greater than or equal to 0.1 C and less than or equal to 1.0 C; the measurement is performed at a temperature greater than or equal to 10° C. and less than or equal to 35° C.; the dQ/dV vs V curve is repeatedly measured within the V range of 4.05 V to 4.58 V; the dQ/dV vs V curve includes a first peak within the V range of 4.54 V to 4.58 V; the dQ/dV vs V curve includes a second peak within the V range of 4.08 V to 4.18 V; the dQ/dV vs V curve includes a third peak within the V range of 4.18 V to 4.25 V; the voltage is a voltage with reference to a redox potential of lithium metal; a peak intensity of the first peak increases in 1st to 10th measurements; the peak intensity of the first peak decreases in 30th to 100th measurements; a voltage at a peak position of the second peak increases in the 30th to 100th measurements.

In the above structure, for example, the secondary battery includes a positive electrode; at the charging voltage V at which the second peak is observed, the positive electrode has a crystal structure corresponding to a space group P2/m, and at the charging voltage V at which the first peak is observed, the positive electrode has a crystal structure corresponding to a space group R-3m.

In the above structure, for example, the secondary battery includes a negative electrode, and the negative electrode is lithium metal.

In the above structure, for example, the positive electrode is taken out from the secondary battery, and the dQ/dV vs V curve is measured using lithium metal as a counter electrode of the positive electrode

Alternatively, one embodiment of the present invention is an electronic device including the secondary battery described in any of the above and a display portion

Alternatively, one embodiment of the present invention is a vehicle including the secondary battery described in any of the above and an electric motor.

### Effect of the Invention

According to one embodiment of the present invention, a positive electrode active material that has high capacity and excellent charge-and-discharge cycle performance for a lithium-ion secondary battery, and a manufacturing method thereof can be provided. In addition, a manufacturing method of a positive electrode active material with high productivity can be provided. In addition, a positive electrode active material that suppresses a decrease in capacity in charge-and-discharge cycles when used in a lithium-ion secondary battery can be provided. In addition, a secondary battery with a large capacity can be provided. In addition, a secondary battery with excellent charge-and-discharge performance can be provided. In addition, a positive electrode active material in which elution of a transition metal such as cobalt is suppressed even when a state being charged with a high voltage is held for a long time can be provided. In addition, a highly safe or reliable secondary battery can be provided. In addition, a novel material, novel active material particles, a novel power storage device, or a manufacturing method thereof can be provided.

### BRIEF DESCRIPTION OF THE DRAWINGS

FIG. 1 is a diagram showing the charge depth and crystal structures of a positive electrode active material of one embodiment of the present invention.

FIG. 2 is a diagram showing the charge depth and crystal structures of a conventional positive electrode active material.

FIG. 3 is XRD patterns calculated from the crystal structures.

FIG. 4A is a diagram showing a crystal structure of a positive electrode active material of one embodiment of the present invention. FIG. 4B is a diagram showing magnetism of a positive electrode active material of one embodiment of the present invention.

FIG. 5A is a diagram showing a crystal structure of a conventional positive electrode active material. FIG. 5B is a diagram showing magnetism of a conventional positive electrode active material.

FIG. 6A is a diagram showing a crystal structure. FIG. 6B is a diagram showing a crystal structure. FIG. 6C is a diagram showing a crystal structure.

FIG. 7A is a diagram showing a crystal structure. FIG. 7B is a diagram showing a crystal structure.

FIG. 8A is a diagram showing a crystal structure. FIG. 8B is a diagram showing a crystal structure.

FIG. 9A is a diagram showing a crystal structure. FIG. 9B is a diagram showing a crystal structure. FIG. 9C is a diagram showing a crystal structure.

FIG. 10A is a diagram showing a crystal structure. FIG. 10B is a diagram showing a crystal structure.

FIG. 11A is a diagram showing a crystal structure. FIG. 11B is a diagram showing a crystal structure. FIG. 11C is a diagram showing a crystal structure.

FIG. 12 is a diagram showing an example of a manufacturing method of the positive electrode active material of one embodiment of the present invention.

FIG. 13 is a diagram showing another example of a manufacturing method of the positive electrode active material of one embodiment of the present invention.

FIG. 14A is a cross-sectional view of an active material layer using a graphene compound as a conductive additive. FIG. 14B is a cross-sectional view of an active material layer using a graphene compound as a conductive additive.

FIG. 15A is a diagram showing a charging method of a secondary battery. FIG. 15B is a diagram showing a charging method of a secondary battery. FIG. 15C is a graph showing an example of a secondary battery voltage and a charging current.

FIG. 16A is a diagram showing a charging method of a secondary battery. FIG. 16B is a diagram showing a charging method of a secondary battery. FIG. 16C is a diagram showing a charging method of a secondary battery. FIG. 16D is a graph showing an example of a secondary battery voltage and a charging current.

FIG. 17 is a graph showing an example of a secondary battery voltage and a discharging current.

FIG. 18A is a diagram showing a coin-type secondary battery. FIG. 18B is a diagram showing a coin-type secondary battery. FIG. 18C is a diagram showing charge of a secondary battery.

FIG. 19A is a diagram showing a cylindrical secondary battery. FIG. 19B is a diagram showing a cylindrical secondary battery. FIG. 19C is a diagram showing cylindrical secondary batteries. FIG. 19D is a diagram showing cylindrical secondary batteries.

FIG. 20A is a diagram showing an example of a battery pack. FIG. 20B is a diagram showing an example of a battery pack.

FIG. 21A is a diagram showing an example of a battery pack. FIG. 21B is a diagram showing an example of a battery pack. FIG. 21C is a diagram showing an example of a battery pack. FIG. 21D is a diagram showing an example of a battery pack.

FIG. 22A is a diagram showing an example of a secondary battery. FIG. 22B is a diagram showing an example of a secondary battery.

FIG. 23 is a diagram showing an example of a wound body.

FIG. 24A is a diagram showing a structure of a laminated secondary battery. FIG. 24B is a diagram showing a laminated secondary battery. FIG. 24C is a diagram showing a laminated secondary battery.

FIG. 25A is a diagram showing a laminated secondary battery. FIG. 25B is a diagram showing a laminated secondary battery.

FIG. 26 is an external view of a secondary battery.

FIG. 27 is an external view of a secondary battery.

FIG. 28A is a diagram showing examples of a positive electrode and a negative electrode.

FIG. 28B is a diagram showing a manufacturing method of a secondary battery. FIG. 28C is a diagram showing a manufacturing method of a secondary battery.

FIG. 29A is a diagram showing a bendable secondary battery. FIG. 29B is a diagram showing a bendable secondary battery. FIG. 29C is a diagram showing a bendable secondary battery. FIG. 29D is a diagram showing a bendable secondary battery. FIG. 29E is a diagram showing a bendable secondary battery.

FIG. 30A is a diagram showing a bendable secondary battery. FIG. 30B is a diagram showing a bendable secondary battery.

FIG. 31A is a diagram showing an example of an electronic device. FIG. 31B is a diagram showing an example of an electronic device. FIG. 31C is a diagram showing an example of an electronic device. FIG. 31D is a diagram showing an example of an electronic device.

FIG. 31E is a diagram showing an example of a secondary battery. FIG. 31F is a diagram showing an example of an electronic device. FIG. 31G is a diagram showing an example of an electronic device. FIG. 31H is a diagram showing an example of an electronic device.

FIG. 32A is a diagram showing an example of an electronic device. FIG. 32B is a diagram showing an example of an electronic device. FIG. 32C is a diagram showing a charge control circuit.

FIG. 33 is a diagram showing examples of electronic devices.

FIG. 34A is a diagram showing an example of a vehicle. FIG. 34B is a diagram showing an example of a vehicle. FIG. 34C is a diagram showing an example of a vehicle.

FIG. 35A shows dQ/dV vs V curves. FIG. 35B shows dQ/dV vs V curves.

FIG. 36A shows charge-and-discharge curves. FIG. 36B shows charge-and-discharge curves.

FIG. 37A shows charge-and-discharge curves. FIG. 37B is a graph showing cycle performance.

FIG. 38 shows XRD results.

FIG. 39 shows XRD results.

FIG. 40A shows XRD results. FIG. 40B shows XRD results.

FIG. 41 shows XRD results.

FIG. 42 shows a dQ/dV vs V curve.

FIG. 43A shows dQ/dV vs V curves. FIG. 43B shows dQ/dV vs V curves.

### MODE FOR CARRYING OUT THE INVENTION

Embodiments of the present invention are described in detail with reference to the drawings. Note that the present invention is not limited to the following description, and it is readily understood by those skilled in the art that modes and details of the present invention can be modified in various ways. In addition, the present invention should not be construed as being limited to the description of embodiments below.

In addition, in this specification and the like, crystal planes and orientations are indicated by the Miller index. In the crystallography, a bar is placed over a number in the expression of crystal planes and orientations; however, in this specification and the like, crystal planes and orientations are in some cases expressed by placing a minus sign (−) before a number instead of placing the bar over the number because of patent expression limitations. Furthermore, an individual direction which shows an orientation in a crystal is denoted by “[ ]”, a set direction which shows all of the equivalent orientations is denoted by “< >”, an individual plane which shows a crystal plane is denoted by “( )”, and a set plane having equivalent symmetry is denoted by “{ }”.

In this specification and the like, segregation refers to a phenomenon in which in a solid made of a plurality of elements (e.g., A, B, and C), a certain element (e.g., B) is spatially non-uniformly distributed.

In this specification and the like, a superficial portion of a particle of an active material or the like refers to a region from a surface to a depth of approximately 10 nm. A plane generated by a crack may also be referred to as a surface. In addition, a region whose position is deeper than that of the superficial portion is referred to as an inner portion.

In this specification and the like, a layered rock-salt crystal structure of a composite oxide including lithium and a transition metal refers to a crystal structure in which a rock-salt ion arrangement where cations and anions are alternately arranged is included and the transition metal and lithium are regularly arranged to form a two-dimensional plane, so that lithium can be two-dimensionally diffused. Note that a defect such as a cation or anion vacancy may exist. Moreover, in the layered rock-salt crystal structure, strictly, a lattice of a rock-salt crystal is distorted in some cases.

In addition, in this specification and the like, a rock-salt crystal structure refers to a structure in which cations and anions are alternately arranged. Note that a cation or anion vacancy may exist.

In addition, in this specification and the like, a pseudo-spinel crystal structure of a composite oxide containing lithium and a transition metal refers to a space group R-3m, which is not a spinel crystal structure but a crystal structure in which oxygen is hexacoordinated to ions such as cobalt and magnesium, and the cation arrangement has symmetry similar to that of the spinel crystal structure. Note that in the pseudo-spinel crystal structure, oxygen is tetracoordinated to a light element such as lithium in some cases. Also in that case, the ion arrangement has symmetry similar to that of the spinel crystal structure.

The pseudo-spinel crystal structure can also be regarded as a crystal structure that contains Li between layers at random but is similar to a CdCl₂ type crystal structure. The crystal structure similar to the CdCl₂ type crystal structure is close to a crystal structure of lithium nickel oxide when charged up to a charge depth of 0.94 (Li_{0.06}NiO₂); however, pure lithium cobaltate or a layered rock-salt positive electrode active material containing a large amount of cobalt is known not to have this crystal structure generally.

Anions of a layered rock-salt crystal and anions of a rock-salt crystal have cubic closest packed structures (face-centered cubic lattice structures). Anions of a pseudo-spinel crystal are also presumed to have cubic closest packed structures. When the pseudo-spinel crystal is in contact with the layered rock-salt crystal and the rock-salt crystal, there is a crystal plane at which orientations of cubic closest packed structures composed of anions are aligned. Note that a space group of the layered rock-salt crystal and the pseudo-spinel crystal is R-3m, which is different from a space group Fm-3m of a rock-salt crystal (a space group of a general rock-salt crystal) and a space group Fd-3m of a rock-salt crystal (a space group of a rock-salt crystal having the simplest symmetry); thus, the Miller index of the crystal plane satisfying the above conditions in the layered rock-salt crystal and the pseudo-spinel crystal is different from that in the rock-salt crystal. In this specification, a state where the orientations of the cubic closest packed structures composed of anions in the layered rock-salt crystal, the pseudo-spinel crystal, and the rock-salt crystal are aligned is referred to as a state where crystal orientations are substantially aligned in some cases.

Whether the crystal orientations in two regions are substantially aligned can be judged from a TEM (transmission electron microscope) image, a STEM (scanning transmission electron microscope) image, a HAADF-STEM (high-angle annular dark field scanning transmission electron microscope) image, an ABF-STEM (annular bright-field scanning transmission electron microscope) image, and the like. X-ray diffraction (XRD), electron diffraction, neutron diffraction, and the like can also be used for judging. In a TEM image and the like, alignment of cations and anions can be observed as repetition of bright lines and dark lines. When the orientations of cubic closest packed structures in the layered rock-salt crystal and the rock-salt crystal are aligned, a state where an angle made by the repetition of bright lines and dark lines in the layered rock-salt crystal and the rock-salt crystal is less than or equal to 5°, preferably less than or equal to 2.5° can be observed. Note that in the TEM image and the like, light elements such as oxygen or fluorine cannot be clearly observed in some cases; however, in such a case, alignment of orientations can be judged by the arrangements of metal elements.

In addition, in this specification and the like, theoretical capacity of a positive electrode active material refers to the amount of electricity when all lithium that can be inserted and extracted contained in the positive electrode active material is extracted. For example, the theoretical capacity of LiCoO₂ is 274 mAh/g, the theoretical capacity of LiNiO₂ is 274 mAh/g, and the theoretical capacity of LiMn₂O₄ is 148 mAh/g.

In addition, in this specification and the like, a charge depth is 0 when all lithium that can be inserted and extracted is inserted, and a charge depth is 1 when all lithium that can be inserted and extracted in a positive electrode active material is extracted.

In addition, in this specification and the like, charging refers to transfer of lithium ions from a positive electrode to a negative electrode in a battery and transfer of electrons from a negative electrode to a positive electrode in an external circuit. For a positive electrode active material, extraction of lithium ions is called charging. Moreover, a positive electrode active material with a charge depth greater than or equal to 0.74 and less than or equal to 0.9, specifically, greater than or equal to 0.8 and less than or equal to 0.83 is referred to as a high-voltage charged positive electrode active material. Thus, for example, LiCoO₂ charged to 219.2 mAh/g is a high-voltage charged positive electrode active material. In addition, LiCoO₂ that is subjected to constant current charging in an environment at 25° C. and a charging voltage greater than or equal to 4.525 V and less than or equal to 4.65 V (in the case of a lithium counter electrode), and then subjected to constant voltage charging until the current value becomes 0.01 C or ⅕ to 1/100 of the current value at the time of the constant current charging is also referred to as a high-voltage charged positive electrode active material.

Similarly, discharging refers to transfer of lithium ions from a negative electrode to a positive electrode in a battery and transfer of electrons from a positive electrode to a negative electrode in an external circuit. Discharging of a positive electrode active material refers to insertion of lithium ions. Furthermore, a positive electrode active material with a charge depth of less than or equal to 0.06 or a positive electrode active material from which more than or equal to 90% of the charge capacity is discharged from a state where the positive electrode active material is charged with a high voltage is referred to as a sufficiently discharged positive electrode active material. For example, LiCoO₂ with a charge capacity of 219.2 mAh/g is in a state of being charged with a high voltage, and a positive electrode active material from which more than or equal to 197.3 mAh/g, which is 90% of the charge capacity, is discharged is a sufficiently discharged positive electrode active material. In addition, LiCoO₂ that is subjected to constant current discharging in an environment at 25° C. until the battery voltage becomes lower than or equal to 3 V (in the case of a lithium counter electrode) is also referred to as a sufficiently discharged positive electrode active material.

In addition, in this specification and the like, a non-equilibrium phase change refers to a phenomenon that causes a nonlinear change in physical quantity. For example, a non-equilibrium phase change might occur before and after peaks in a dQ/dV curve obtained by differentiating capacitance (Q) with voltage (V) (dQ/dV); the crystal structure is presumably changed to a great extent.

### Embodiment 1

In this embodiment, a positive electrode active material of one embodiment of the present invention is described.

### [Structure of Positive Electrode Active Material]

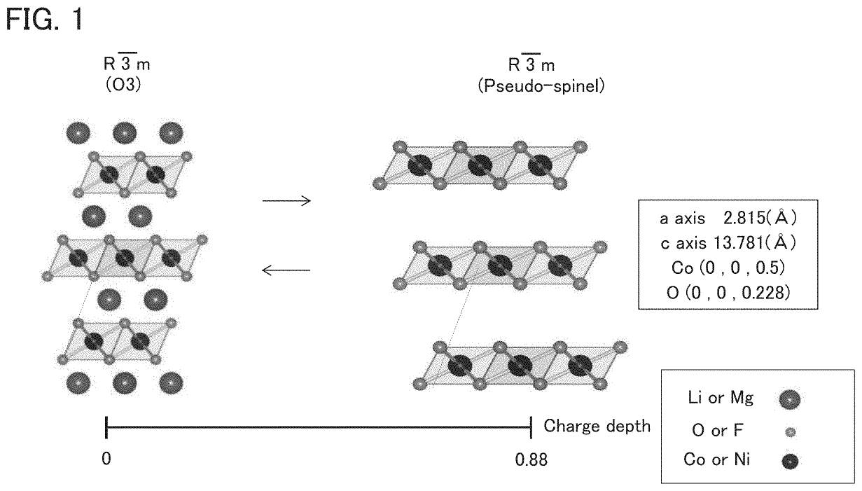

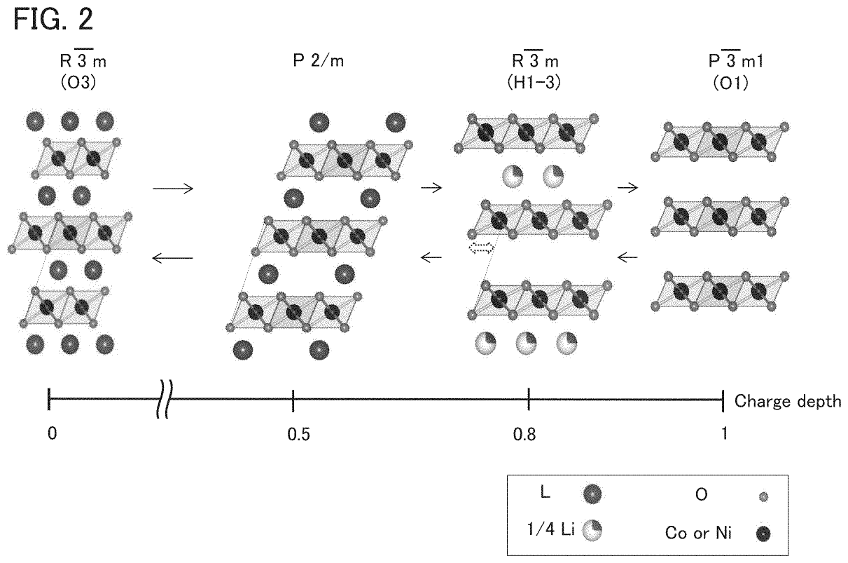

A positive electrode active material 100 of one embodiment of the present invention and a conventional positive electrode active material are explained with reference to FIG. 1 and FIG. 2, and differences between the materials are described. In FIG. 1 and FIG. 2, the case where cobalt is used as a transition metal contained in the positive electrode active material is described. The conventional positive electrode active material described in FIG. 2 is simple lithium cobaltate (LiCoO₂) in which an element other than lithium, cobalt, or oxygen is neither added to an inner portion nor applied to a superficial portion, for example.

### <Conventional Positive Electrode Active Material>

As described in Non-Patent Document 1, Non-Patent Document 2, and the like, the crystal structure of lithium cobaltate LiCoO₂, which is one of the conventional positive electrode active materials, changes depending on its charge depth. FIG. 2 shows typical crystal structures of lithium cobaltate.

As shown in FIG. 2, lithium cobaltate with a charge depth of 0 (discharged state) includes a region having a crystal structure of the space group R-3m, and includes three CoO₂ layers in a unit cell. Thus, this crystal structure is referred to as an O₃-type crystal structure in some cases. Note that the CoO₂ layer has a structure in which octahedral geometry with oxygen atoms hexacoordinated to cobalt continues on a plane in the edge-sharing state.

Furthermore, when a charge depth is 1, LiCoO₂ has a crystal structure of the space group P-3m1, and one CoO₂ layer exists in a unit cell. Thus, this crystal structure is referred to as an O1-type crystal structure in some cases.

Moreover, lithium cobaltate when a charge depth is approximately 0.88 has the crystal structure of the space group R-3m. This structure can also be regarded as a structure in which CoO₂ structures such as P-3m1 (O1) and LiCoO₂ structures such as R-3m (O3) are alternately stacked. Thus, this crystal structure is referred to as an H1-3 type crystal structure in some cases. Actually, the number of cobalt atoms per unit cell in the H1-3 type crystal structure is twice as many as that of cobalt atoms per unit cell in other structures. However, in this specification including FIG. 2, the c-axis of the H1-3 type crystal structure is half that of the unit cell for easy comparison with the other structures.

When high-voltage charging with a charge depth of approximately 0.88 or more and discharging are repeated, the crystal structure of lithium cobaltate repeatedly changes between the H1-3 type crystal structure and the R-3m(O3) structure in the discharged state (i.e., a non-equilibrium phase change).

However, there is a large shift in the position of the CoO₂ layer between these two crystal structures. As indicated by dotted lines and an arrow in FIG. 2, the CoO₂ layer in the H1-3 type crystal structure greatly shifts from that in the R-3m(O3) structure. Such a dynamic structural change might cause bad effects on the stability of the crystal structure.

The difference in volume is also large. The difference in volume in comparison with the same number of cobalt atoms between the H1-3 type crystal structure and the O3-type crystal structure in the discharged state is 3.5% or more.

In addition, a structure in which CoO₂ layers are continuous, such as P-3m1 (O1), included in the H1-3 type crystal structure is highly likely to be unstable.

Thus, repetitions of high-voltage charging and discharging cause breaking of the crystal structure of lithium cobaltate. The break of the crystal structure degrades the cycle performance. This is probably because the break of the crystal structure reduces sites where lithium can stably exist and makes it difficult to insert and extract lithium.

### <Positive Electrode Active Material of One Embodiment of the Present Invention>

### <<Inner Portion>>

By contrast, in the positive electrode active material 100 of one embodiment of the present invention, there is a small difference in change in the crystal structure and volume in comparison with the same number of transition metal atoms between the sufficiently discharged state and the high-voltage charged state.

FIG. 1 shows the crystal structures of the positive electrode active material 100 before and after being charged and discharged. The positive electrode active material 100 is a composite oxide containing lithium, cobalt, and oxygen. In addition to the above, the positive electrode active material 100 preferably contains magnesium. Furthermore, the positive electrode active material 100 preferably contains halogen such as fluorine or chlorine.

The crystal structure with a charge depth of 0 (in the discharged state) in FIG. 1 is R-3m(O3) as in FIG. 2. By contrast, the positive electrode active material 100 of one embodiment of the present invention has a different crystal structure from that in FIG. 2 when it is sufficiently charged and has a charge depth of approximately 0.88. The crystal structure of the space group R-3m is referred to as a pseudo-spinel crystal structure in this specification and the like. Although the indication of lithium is omitted in the diagram of the pseudo-spinel crystal structure shown in FIG. 1 for explaining the symmetry of cobalt atoms and the symmetry of oxygen atoms, lithium practically exists between CoO₂ layers at approximately 12 atomic % with respect to cobalt. In addition, in both the O3-type crystal structure and the pseudo-spinel crystal structure, magnesium preferably exists between the CoO₂ layers, i.e., in lithium sites, at a slight concentration. In addition, a slight amount of halogen such as fluorine preferably exists in oxygen sites at random.

In the positive electrode active material 100, a change in the crystal structure when the positive electrode active material 100 is charged with a high voltage and a large amount of lithium is reduced is inhibited as compared with conventional LiCoO₂. As shown by a dotted line in FIG. 1, for example, CoO₂ layers hardly deviate in the crystal structure.

In addition, in the positive electrode active material 100, a difference in the volume per unit cell between the O3-type crystal structure with a charge depth of 0 and the pseudo-spinel crystal structure with a charge depth of 0.88 is less than or equal to 2.5%, specifically, less than or equal to 2.2%.

Thus, the crystal structure is difficult to break by repetitions of high-voltage charging and discharging.

In the unit cell of the pseudo-spinel crystal structure, coordinates of cobalt and oxygen can be represented by Co (0, 0, 0.5) and O (0, 0, x) within the range of 0.20≤x≤0.25.

A slight amount of magnesium randomly existing between the CoO₂ layers, i.e., in lithium sites, has an effect of suppressing a difference in the CoO₂ layers. Thus, when magnesium exists between the CoO₂ layers, the pseudo-spinel crystal structure is likely to be formed. Therefore, magnesium is preferably distributed over an entire particle of the positive electrode active material 100. In addition, to distribute magnesium over the entire particle, heat treatment is preferably performed in a manufacturing process of the positive electrode active material 100.

However, cation mixing occurs when the heat treatment temperature is excessively high, so that magnesium is highly likely to enter the cobalt sites. When the magnesium is in the cobalt site, the effect of maintaining the R-3m structure is lost. Furthermore, when the heat treatment temperature is too high, it can be thought that adverse effects happen such as reduction of cobalt to have divalence and transpiration of lithium.

In view of the above, a halogen compound such as a fluorine compound is preferably added to lithium cobaltate before the heat treatment for distributing magnesium over the entire particle. The addition of the halogen compound decreases the melting point of lithium cobaltate. The decrease in the melting point makes it easier to distribute magnesium over the entire particle at a temperature at which the cation mixing is unlikely to occur. Furthermore, when a fluorine compound exists, it is expected that corrosion resistance to hydrofluoric acid generated by decomposition of an electrolyte solution is improved.

Note that although the case where the positive electrode active material 100 is a composite oxide containing lithium, cobalt, and oxygen is described so far, nickel may be contained in addition to cobalt. In that case, the proportion of nickel atoms (Ni) in the sum of cobalt atoms and nickel atoms (Co+Ni), that is, Ni/(Co+Ni) is preferably less than 0.1, further preferably less than or equal to 0.075.

When a high-voltage charged state is held for a long time, a transition metal dissolves in the electrolyte solution from the positive electrode active material, and the crystal structure might be broken. However, when nickel is contained at the above proportion, dissolution of the transition metal from the positive electrode active material 100 can be inhibited in some cases.

The addition of nickel decreases charge-and-discharge voltages, and thus, charging and discharging can be executed at a lower voltage in the case of the same capacity. As a result, dissolution of the transition metal and decomposition of the electrolyte solution might be inhibited. Here, the charge-and-discharge voltages are, for example, voltages within the range from a charge depth of 0 to a predetermined charge depth.

### <<Superficial Portion>>

Magnesium is preferably distributed over the entire particle of the positive electrode active material 100, and further preferably, the magnesium concentration in the superficial portion of the particle is higher than the average in the entire particle. In other words, magnesium concentrations in the superficial portion of the particle that are measured with XPS or the like are preferably higher than the average magnesium concentration in the entire particle measured with ICP-MS or the like. The surface of the particle is a kind of crystal defects and lithium is extracted from the surface during charging; thus, the lithium concentration in the surface of the particle tends to be lower than that inside the particle. Therefore, the surface of the particle tends to be unstable and its crystal structure is likely to break. The higher the magnesium concentration in the superficial portion is, the more effectively the change in the crystal structure can be inhibited. In addition, when a magnesium concentration in the superficial portion is high, it is expected that the corrosion resistance to hydrofluoric acid generated by the decomposition of the electrolyte solution is improved.

In addition, the concentration of halogen such as fluorine in the superficial portion of the positive electrode active material 100 is preferably higher than the average concentration of halogen such as fluorine in the entire particle. When halogen exists in the superficial portion that is a region in contact with the electrolyte solution, the corrosion resistance to hydrofluoric acid can be effectively improved.

In this manner, the superficial portion of the positive electrode active material 100 preferably has the higher magnesium concentration and the higher fluorine concentration than those in the inner portion and a composition different from that in the inner portion. In addition, the composition preferably has a crystal structure stable at normal temperature. Thus, the superficial portion may have a crystal structure different from that of the inner portion. For example, at least part of the superficial portion of the positive electrode active material 100 may have a rock-salt crystal structure. Furthermore, in the case where the superficial portion and the inner portion have different crystal structures, the orientations of crystals in the superficial portion and the inner portion are preferably substantially aligned.

Only with the structure where the superficial portion includes only MgO or MgO and CoO(II) forms a solid solution, it is difficult to insert and extract lithium. Thus, the superficial portion should contain at least cobalt, and further contain lithium in the discharged state to have a path through which lithium is inserted and extracted. In addition, the cobalt concentration is preferably higher than the magnesium concentration.

### <<Grain Boundary>>

A slight amount of magnesium or halogen contained in the positive electrode active material 100 may randomly exist in the inner portion, but part of the element is further preferably segregated at a grain boundary.

In other words, the magnesium concentration in the crystal grain boundary and its vicinity of the positive electrode active material 100 is preferably higher than that in the other regions in the inner portion. In addition, the halogen concentration in the crystal grain boundary and its vicinity is also preferably higher than that in the other regions in the inner portion.

Like a particle surface, a crystal grain boundary is also a plane defect. Thus, the crystal grain boundary tends to be unstable and its crystal structure easily starts to change. Therefore, the higher the magnesium concentrations in the crystal grain boundary and its vicinity are, the more effectively the change in the crystal structure can be inhibited.

Furthermore, when the magnesium concentration and the halogen concentration are high in the crystal grain boundary and its vicinity, the magnesium concentration and the halogen concentration in the vicinity of a surface generated by a crack are also high even when the crack is generated along the crystal grain boundary of the particle of the positive electrode active material 100. Thus, the positive electrode active material after the crack is generated can also have increased corrosion resistance to hydrofluoric acid.

Note that in this specification and the like, the vicinity of the crystal grain boundary refers to a region of approximately 10 nm from the grain boundary.

### <<Particle Size>>

A too large particle diameter of the positive electrode active material 100 causes problems such as difficulty in lithium diffusion and too much surface roughness of an active material layer in coating a current collector. By contrast, a too small particle size causes problems such as difficulty in loading of the active material layer in coating the current collector and overreaction with an electrolyte solution. Therefore, D50 is preferably greater than or equal to 1 μm and less than or equal to 100 μm, further preferably greater than or equal to 2 μm and less than or equal to 40 μm, and still further preferably greater than or equal to 5 μm and less than or equal to 30 μm.

### <Analysis Method>

Whether or not a positive electrode active material is the positive electrode active material 100 of one embodiment of the present invention that has a pseudo-spinel crystal structure when charged with high voltage can be determined by analyzing a high-voltage charged positive electrode using XRD, electron diffraction, neutron diffraction, electron spin resonance (ESR), nuclear magnetic resonance (NMR), or the like. The XRD is particularly preferable because the symmetry of a transition metal such as cobalt contained in the positive electrode active material can be analyzed with high resolution, the degrees of crystallinity and the crystal orientations can be compared, the distortion of lattice periodicity and the crystallite size can be analyzed, and a positive electrode obtained by disassembling a secondary battery can be measured without any change with sufficient accuracy, for example.

As described so far, the positive electrode active material 100 of one embodiment of the present invention has a feature of a small change in the crystal structure between the high-voltage charged state and the discharged state. A material where 50 wt % or more of the crystal structure greatly changes between the high-voltage charged state and the discharged state is not preferable because the material cannot withstand a high-voltage charging and discharging. In addition, it should be noted that a target crystal structure is not obtained in some cases only by adding impurity elements. For example, although the positive electrode active material that is lithium cobaltate containing magnesium and fluorine is a commonality, the positive electrode active material has 60 wt % or more of the pseudo-spinel crystal structure in some cases, and has 50 wt % or more of the H1-3 type crystal structure in other cases, when charged with a high voltage. Furthermore, at a certain voltage, the positive electrode active material has almost 100 wt % of the pseudo-spinel crystal structure, and when the voltage is increased, the H1-3 type crystal structure is generated in some cases. Thus, analysis of the crystal structure, including XRD, is needed to determine whether or not the positive electrode active material is the positive electrode active material 100 of one embodiment of the present invention.

A positive electrode active material in the high-voltage charged state or the discharged state sometimes suffers a change in the crystal structure when exposed to air. For example, the pseudo-spinel crystal structure changes into the H1-3 type crystal structure in some cases. Thus, all samples are preferably handled in an inert atmosphere such as an argon atmosphere.

### <<Charge Method>>

High-voltage charging for determining whether or not a composite oxide is the positive electrode active material 100 of one embodiment of the present invention can be performed on a coin cell (CR2032 type with a diameter of 20 mm and a height of 3.2 mm) with a lithium counter electrode, for example.

Specifically, a positive electrode current collector made of aluminum foil that is coated with slurry in which a positive electrode active material, a conductive additive, and a binder are mixed can be used as a positive electrode.

Lithium metal can be used as the counter electrode. Note that when a material other than lithium metal is used as the counter electrode, the potential of a secondary battery differs from the potential of the positive electrode. Unless otherwise specified, voltages and potentials in this specification and the like refer to the potentials of a positive electrode.

As an electrolyte contained in an electrolyte solution, 1 mol/L lithium hexafluorophosphate (LiPF₆) can be used. As the electrolyte solution, a solution in which ethylene carbonate (EC) and diethyl carbonate (DEC) at EC:DEC=3:7 (volume ratio) and vinylene carbonate (VC) at 2 wt % are mixed can be used.

As a separator, 25-μm-thick polypropylene can be used.

A positive electrode can and a negative electrode can that are formed using stainless steel (SUS) can be used as a positive electrode can and a negative electrode can.

The coin cell formed under the above conditions is charged with a constant current at 4.6 V and 0.5 C and then charged with a constant voltage until the current value reaches 0.01 C. Note that here, 1 C is set to 137 mA/g, and a temperature is set to 25° C. After charging is performed in this manner, the coin cell is disassembled in a glove box under an argon atmosphere and the positive electrode is taken out, whereby a high-voltage charged positive electrode active material can be obtained. In order to inhibit reaction with components in the external world, the positive electrode active material is preferably hermetically sealed in an argon atmosphere when performing various analyses later. For example, XRD can be performed on the positive electrode enclosed in an airtight container with an argon atmosphere.

The above charging voltage is for the case where lithium metal is used as a counter electrode. When using graphite, for example, as the negative electrode of the secondary battery, charging can be performed using a charging voltage which is approximately 0.1 V lower than the charging voltage when lithium metal is used as a negative electrode.

In this specification, in the case where lithium metal is used as a counter electrode, for example, when a graphite negative electrode is used in the secondary battery, the charging voltage can be lower than the charging voltage by greater than or equal to 0.05 V and less than or equal to 0.3 V, preferably by 0.1 V.

### <<XRD>>

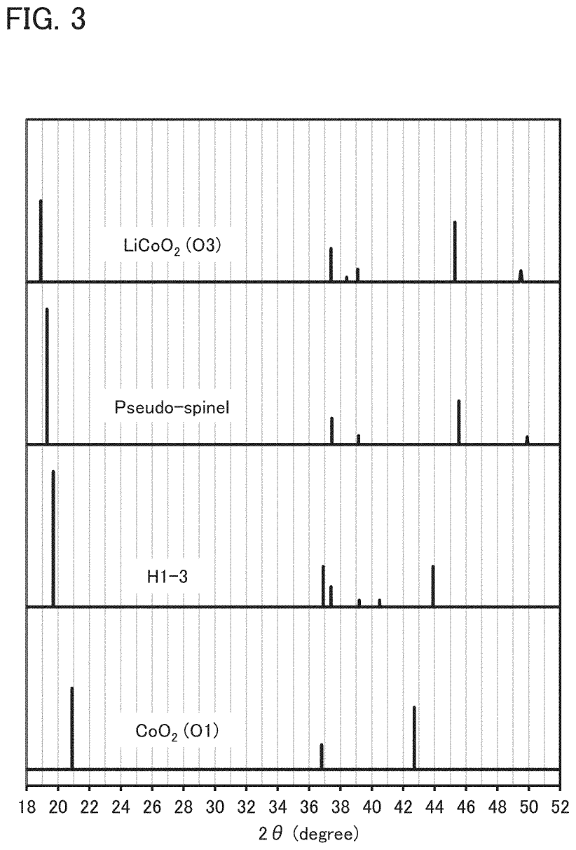

FIG. 3 shows ideal powder XRD patterns with the CuKα1 line calculated from models of a pseudo-spinel crystal structure and an H1-3 type crystal structure. For comparison, FIG. 3 also shows ideal XRD patterns calculated from the crystal structures of LiCoO₂ (O3) with a charge depth of 0 and CoO₂ (O1) with a charge depth of 1. Note that the patterns of LiCoO₂ (O3) and CoO₂ (O1) are made from crystal structure data obtained from ICSD (Inorganic Crystal Structure Database) (Non-Patent Document 5) using Reflex Powder Diffraction, which is a module of Materials Studio (BIOVIA). The range of 2θ is from 15° to 75°, Step size is 0.01, the wavelength λ1 is 1.540562×10⁻¹⁰ m, λ2 is not set, and Monochromator is a single monochromator. The pattern of the H1-3 type crystal structure is made from the crystal structure data disclosed in Non-Patent Document 3 in a similar manner. The pattern of the pseudo-spinel crystal structure is estimated from the XRD pattern of the positive electrode active material of one embodiment of the present invention, the crystal structure is fitted with TOPAS ver. 3 (crystal structure analysis software manufactured by Bruker Corporation), and XRD patterns are made in a manner similar to those of other structures.

As shown in FIG. 3, the pseudo-spinel crystal structure has diffraction peaks at 2θ of 19.30±0.20° (greater than or equal to 19.10° and less than or equal to 19.50°) and 2θ of 45.55±0.10° (greater than or equal to 45.45° and less than or equal to 45.65°). Specifically, sharp diffraction peaks appear at 2θ of 19.30±0.10° (greater than or equal to 19.20° and less than or equal to 19.40°) and 2θ of 45.55±0.05° (greater than or equal to 45.50° and less than or equal to) 45.60°. However, in the H1-3 type crystal structure and CoO₂ (P-3m1, O1), peaks at these positions do not appear. Thus, the peaks at 2θ of 19.30±0.20° and 2θ of 45.55±0.10° in the high-voltage charged state can be the features of the positive electrode active material 100 of one embodiment of the present invention.

It can also be said that the positions where the diffraction peaks of XRD of the crystal structure with a charge depth of 0 appear and the positions where the diffraction peaks of XRD of the crystal structure in charged with a high voltage appear are close to each other. Specifically, differences in the positions of two or more, preferably three or more of the main diffraction peaks between both of the crystal structures is 2θ of less than or equal to 0.7, preferably 2θ of less than or equal to 0.5.

The positive electrode active material 100 of one embodiment of the present invention has the pseudo-spinel crystal structure when being charged with a high voltage; the entire particle does not necessarily have the pseudo-spinel crystal structure. The particle may have another crystal structure, or may be partly amorphous. Note that when the XRD patterns are analyzed with the Rietveld analysis, the pseudo-spinel crystal structure preferably accounts for more than or equal to 50 wt %, further preferably more than or equal to 60 wt %, still further preferably more than or equal to 66 wt %. The positive electrode active material in which the pseudo-spinel crystal structure accounts for more than or equal to 50 wt %, further preferably more than or equal to 60 wt %, still further preferably more than or equal to 66 wt % can have sufficiently good cycle performance.

Furthermore, even after 100 or more cycles of charging and discharging, the pseudo-spinel crystal structure preferably accounts for more than or equal to 35 wt %, further preferably more than or equal to 40 wt %, still further preferably more than or equal to 43 wt % when the Rietveld analysis is performed.

In addition, the crystallite size of the pseudo-spinel structure included in the positive electrode active material particle decreases to approximately one-tenth that of LiCoO₂(O3) at most in the discharged state. Thus, a clear peak of the pseudo-spinel crystal structure can be observed after high-voltage charging even under the same XRD measurement conditions as those of a positive electrode before the charging and discharging. By contrast, simple LiCoO₂ has a small crystallite size and a peak becomes broad and small even when it can have a structure part of which is similar to the pseudo-spinel crystal structure. The crystallite size can be calculated from the half width of the XRD peak.

In addition, the layered rock-salt crystal structure included in the positive electrode active material particle in the discharged state, which can be estimated from the XRD patterns, preferably has a small lattice constant of the c-axis. The lattice constant of the c-axis increases when a foreign element is substituted at the lithium site or cobalt enters an oxygen-tetracoordinated site (A site), for example. For this reason, the positive electrode active material with excellent cycle performance probably can be manufactured by forming a composite oxide having a layered rock-salt crystal structure with few defects such as foreign element substitutions and Co₃O₄ having the spinel crystal structure and then mixing a magnesium source and a fluorine source with the composite oxide and inserting magnesium into the lithium site.

The lattice constant of the c-axis in the crystal structure of the positive electrode active material in the discharged state before annealing is preferably less than or equal to 14.060×10⁻¹⁰ m, further preferably less than or equal to 14.055×10⁻¹⁰ m, still further preferably less than or equal to 14.051×10⁻¹⁰ m. The lattice constant of the c-axis after annealing is preferably less than or equal to 14.065×10⁻¹⁰ m.

In order to set the lattice constant of the c-axis within the above range, the amount of impurities is preferably as small as possible. In particular, the amount of addition of transition metals other than cobalt, manganese, and nickel is preferably as small as possible; specifically, preferably less than or equal to 3000 ppm wt, further preferably less than or equal to 1500 ppm wt. In addition, cation mixing between lithium and cobalt, manganese, and nickel is preferably less likely to occur.

The lattice constant of the a-axis is preferably less than or equal to 2.818×10⁻¹⁰ m.

The lattice constant of the c-axis is, for example, greater than or equal to 14.05×10⁻¹⁰ m and less than or equal to 14.30×10⁻¹⁰ m in the charged state. The charging voltage is preferably lower than 4.5 V.

When the charging voltage is higher than or equal to 4.5 V, which is a voltage with reference to lithium metal, the lattice constant of the c-axis can be lower than or equal to 13.8×10⁻¹⁰ m.

Features that are apparent from the XRD pattern are features of the inner structure of the positive electrode active material. In a positive electrode active material with an average particle diameter (D50) of approximately 1 μm to 100 μm, the volume of a superficial portion is negligible compared with that of an inner portion; therefore, even when the superficial portion of the positive electrode active material 100 has a crystal structure different from that of the inner portion, the crystal structure of the superficial portion is highly unlikely to appear in the XRD pattern.

When the charged positive electrode using the positive electrode active material of one embodiment of the present invention has a peak at 2θ=18.70±0.20° in XRD, the half width thereof is less than or equal to 10 times, preferably less than or equal to 5 times, further preferably less than or equal to 4.3 times, and yet further preferably less than or equal to 3.8 times the half width before charging or after discharging to 2.5 V. When the charged positive electrode has a peak at 2θ=45.2±0.30° in XRD, the half width thereof is less than or equal to 4 times, preferably less than or equal to 3.3 times, and further preferably less than or equal to 2.8 times the half width before charging or after discharging to 2.5 V. The peak at 2θ=18.70±0.20° seems to correspond to the plane (0 0 3) of the O3-type crystal structure and the peak at 2θ=45.2±0.30° seems to correspond to the plane (1 0 4) of the O3-type crystal structure.

The half width in the above description is preferably in the above-described ranges even when the charging voltage is more than or equal to 4.5 V and preferably more than or equal to 4.45 V, which are voltages with reference to lithium metal.

When the charged positive electrode has a peak at 2θ=19.30±0.20° in XRD, the half width thereof is less than or equal to 10 times, preferably less than or equal to 5 times, further preferably less than or equal to 4.3 times, and yet further preferably less than or equal to 3.8 times the half width of the peak at 2θ=18.70±0.20° appearing before charging or after discharging to 2.5 V. When the charged positive electrode has a peak at 2θ=45.55±0.10° in XRD, the half width thereof is less than or equal to 5 times, preferably less than or equal to 4.3 times, and further preferably less than or equal to 3.8 times the half width of the peak at 2θ=45.2±0.30° appearing before charging or after discharging to 2.5 V.

The half width in the above description is preferably in the above-described ranges even when the charging voltage is more than or equal to 4.5 V, preferably more than or equal to 4.55 V, and further preferably more than or equal to 4.6 V, which are voltages with reference to lithium metal.

The XRD of the charged positive electrode has a peak at 2θ=19.28±0.6° or at 2θ=19.32±0.4°, for example.

A small increase in the half width shows that a crystal structure distortion caused by lithium release in charging can be small. Thus, in charge-and-discharge cycle performance of the secondary battery using the positive electrode active material of one embodiment of the present invention, a decrease in discharge capacity can be suppressed, for example.

In addition, as described in the following example, when the charge depth is deep, i.e., approximately 4.5 V, which is a voltage with reference to lithium metal, the lattice constant of the a-axis in the positive electrode using the positive electrode active material of one embodiment of the present invention becomes small after discharging, that is, compared to that after discharging to 2.5 V, for example. Then, the deeper the charge depth becomes, the larger the lattice constant of the a-axis becomes. It seems that the lattice constant of the a-axis preferably becomes closer to the value after discharging, for example.

The change in the lattice constant of the a-axis seems to correspond to a Co—O bond, for example. It seems that the Co—O bond is a strong covalent bond. When the charge depth is deep, the lattice constant of the a-axis becomes closer to the value after discharging, whereby charge is performed with a stable crystal structure.

In charge with more than or equal to 4.55 V, which is a voltage with reference to lithium metal, the lattice constant of the a-axis is preferably more than or equal to 2.813×10⁻¹⁰ m, for example.

Carrier ions, here lithium ions, for example, are repeatedly inserted in and extracted from the positive electrode active material with a few cycles of charging and discharging. The repetitions of insertion and extraction of carrier ions relax the structure as each atom moves, whereby lithium can be stably extracted in some cases. In such a case, the discharge capacity becomes much high, which is preferable. This structure relaxing means that each atom moves to a more stable position, for example.

### <<ESR>>

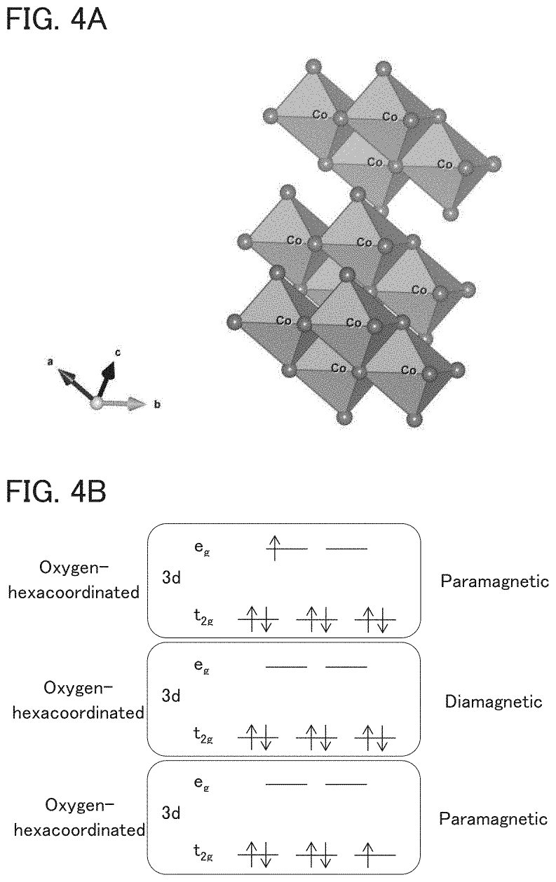

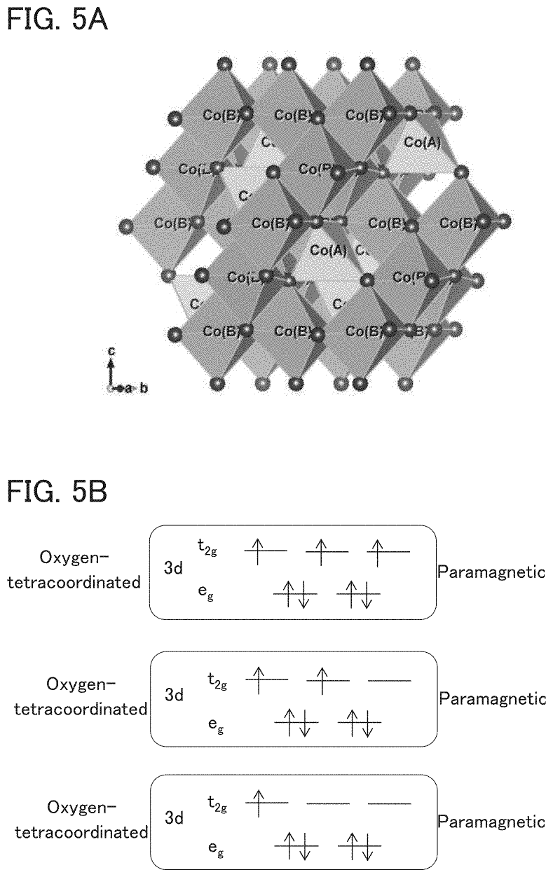

Here, the case in which the difference between the pseudo-spinel crystal structure and other crystal structures is determined using ESR is described using FIG. 4 and FIG. 5. In the pseudo-spinel crystal structure, cobalt exists in the oxygen-hexacoordinated site, as shown in FIG. 1 and FIG. 4A. In oxygen-hexacoordinated cobalt, a 3d orbital is divided into an e_{g} orbital and a t_{2g} orbital as shown in FIG. 4B, and the energy of the t_{2g} orbital located aside from the direction in which oxygen exists is low. Part of cobalt that exists in the oxygen-hexacoordinated site is cobalt of diamagnetic Co³⁺ in which the entire t_{2g} orbital is filled. However, part of cobalt that exists in the oxygen-hexacoordinated site may be cobalt of paramagnetic Co²⁺ or Co⁴⁺. Although both Co²⁺ and Co⁴⁺ have one unpaired electron and thus cannot be distinguished with ESR, paramagnetic cobalt may have either valence depending on the valences of surrounding elements.

By contrast, some documents report that a conventional positive electrode active material can have a spinel crystal structure that does not contain lithium in the superficial portion in the charged state. In that case, the positive electrode active material contains Co₃O₄ having a spinel crystal structure shown in FIG. 5A.

When the spinel is represented by a general formula A[B₂]O₄, the element A is oxygen-tetracoordinated and the element B is oxygen-hexacoordinated. Thus, in this specification and the like, the oxygen-tetracoordinated site is referred to as an A site, and the oxygen-hexacoordinated site is referred to as a B site in some cases.

In Co₃O₄ having the spinel crystal structure, cobalt exists not only in the oxygen-hexacoordinated B site but also in the oxygen-tetracoordinated A site. In oxygen-tetracoordinated cobalt, between the divided e_{g} orbital and t_{2g} orbital, the e_{g} orbital has lower energy as shown in FIG. 5B. Thus, each of oxygen-tetracoordinated Co²⁺, Co³⁺, and Co⁴⁺ includes an unpaired electron and therefore is paramagnetic. Accordingly, when the particles that sufficiently contain Co₃O₄ having the spinel crystal structure are analyzed with ESR or the like, peaks attributed to paramagnetic cobalt, oxygen-tetracoordinated Co²⁺, Co³⁺, or Co⁴⁺, should be detected.

However, in the positive electrode active material 100 of one embodiment of the present invention, peaks attributed to paramagnetic cobalt in the tetracoordinated oxygen site are too small to observe. Thus, unlike the spinel crystal structure, the pseudo-spinel crystal structure in this specification and the like does not contain an enough amount of oxygen-tetracoordinated cobalt to be detected with ESR. Therefore, peaks that are attributed to Co₃O₄ having the spinel crystal structure and can be analyzed with ESR or the like in the positive electrode active material of one embodiment of the present invention are lower than those in a conventional example, or too small to observe, in some cases. Spinel-type Co₃O₄ does not contribute to charge-and-discharge reaction; thus, the amount of spinel-type Co₃O₄ is preferably as small as possible. It can be determined also from the ESR analysis that the positive electrode active material 100 is different from the conventional example.

### <<XPS>>

A region from the surface to a depth of approximately 2 to 8 nm (normally, approximately 5 nm) can be analyzed with X-ray photoelectron spectroscopy (XPS); thus, the concentration of each element in approximately half the depth of the superficial portion can be quantitatively analyzed. In addition, the bonding states of the elements can be analyzed with narrow scanning analysis. Note that the quantitative accuracy of XPS is approximately ±1 atomic % in many cases. The lower detection limit depends on the element but is approximately 1 atomic %.

When the positive electrode active material 100 is analyzed with XPS and the cobalt concentration is set to 1, the relative value of the magnesium concentration is preferably greater than or equal to 0.4 and less than or equal to 1.5, further preferably greater than or equal to 0.45 and less than 1.00. Furthermore, the relative value of the concentration of halogen such as fluorine is preferably greater than or equal to 0.05 and less than or equal to 1.5, further preferably greater than or equal to 0.3 and less than or equal to 1.00.

In addition, when the positive electrode active material 100 is analyzed with XPS, a peak indicating the bonding energy of fluorine with another element is preferably higher than or equal to 682 eV and lower than 685 eV, further preferably approximately 684.3 eV. This value is different from both of the bonding energy of lithium fluoride, which is 685 eV, and the bonding energy of magnesium fluoride, which is 686 eV. That is, when the positive electrode active material 100 contains fluorine, bonding other than bonding of lithium fluoride and magnesium fluoride is preferable.

Furthermore, when the positive electrode active material 100 is analyzed with XPS, a peak indicating the bonding energy of magnesium with another element is preferably higher than or equal to 1302 eV and lower than 1304 eV, further preferably approximately 1303 eV. This value is different from the bonding energy of magnesium fluoride, which is 1305 eV, and is close to the bonding energy of magnesium oxide. That is, when the positive electrode active material 100 contains magnesium, bonding other than bonding of magnesium fluoride is preferable.

### <<EDX>>

In the EDX measurement, to measure a region while scanning the region and evaluate two-dimensionally is referred to as EDX area analysis in some cases. In addition, to extract data of a linear region from EDX area analysis and evaluate the atomic concentration distribution in a positive electrode active material particle is referred to as linear analysis in some cases.

The magnesium concentration and the fluorine concentration in the inner portion, the superficial portion, and the vicinity of the crystal grain boundary can be quantitatively analyzed with the EDX area analysis (e.g., element mapping). In addition, peaks of the magnesium concentration and the fluorine concentration can be analyzed with the EDX linear analysis.

When the positive electrode active material 100 is analyzed with the EDX linear analysis, a peak of the magnesium concentration in the superficial portion preferably exists in a region from the surface of the positive electrode active material 100 to a depth of 3 nm toward the center, further preferably to a depth of 1 nm, still further preferably to a depth of 0.5 nm.

In addition, the distribution of fluorine contained in the positive electrode active material 100 preferably overlaps with the distribution of magnesium. Thus, when the EDX line analysis is performed, a peak of the fluorine concentration in the superficial portion preferably exists in a region from the surface of the positive electrode active material 100 to a depth of 3 nm toward the center, further preferably to a depth of 1 nm, still further preferably to a depth of 0.5 nm.

When the linear analysis or the area analysis is performed on the positive electrode active material 100, the atomic ratio of magnesium to cobalt (Mg/Co) in the vicinity of the crystal grain boundary is preferably greater than or equal to 0.020 and less than or equal to 0.50. It is preferably greater than or equal to 0.025 and less than or equal to 0.30. It is more preferably greater than or equal to 0.030 and less than or equal to 0.20.

<<dQ/dV vs V Curve>>

Moreover, when the positive electrode active material of one embodiment of the present invention is discharged at a low rate of, for example, 0.2 C or less after high-voltage charging, a characteristic change in voltage appears just before the end of discharge, in some cases. This change can be clearly observed by the fact that, when lithium metal is used as a counter electrode, at least one peak appears within the range of 3.5 V to 3.9 V in a dQ/dV vs V curve calculated from a discharge curve.

The positive electrode active material of one embodiment of the present invention can have, in the charging dQ/dV vs V curve, the first peak greater than or equal to 4.05 V and less than 4.15 V, the second peak greater than or equal to 4.15 V and less than 4.25 V, and the third peak greater than or equal to 4.5 V and less than or equal to 4.58 V.

When the positive electrode active material of one embodiment of the present invention is charged with a rate greater than or equal to 0.1 C and less than or equal to 1.0 C, specifically 0.5 C, for example, and with a measurement temperature greater than or equal to 10° C. and less than or equal to 35° C., specifically 25° C., for example, the dQ/dV vs V curve preferably has the following three peaks: the first peak within the range greater than or equal to 4.08 V and less than or equal to 4.18 V of the charging voltage using a lithium metal counter electrode, the second peak within the range greater than or equal to 4.18 V and less than or equal to 4.25 V thereof, and the third peak within the range greater than or equal to 4.54 V and less than or equal to 4.58 V thereof.

Alternatively, in the above, when the positive electrode active material is charged with a rate greater than or equal to 0.01 C and less than 0.1 C, specifically 0.05 C, for example, and with a measurement temperature greater than or equal to 10° C. and less than or equal to 35° C., specifically 25° C., for example, the dQ/dV vs V curve preferably has the following three peaks: the first peak within the range greater than or equal to 4.03 V and less than or equal to 4.13 V of the charging voltage using a lithium metal counter electrode, the second peak within the range greater than or equal to 4.14 V and less than or equal to 4.21 V thereof, and the third peak within the range greater than or equal to 4.50 V and less than or equal to 4.60 V thereof.

At the charging voltage at which the first peak is observed, the positive electrode active material preferably has a crystal structure shown by the space group P2/m. At the charging voltage at which the third peak is observed, the positive electrode active material preferably has a crystal structure corresponding to the space group R-3m.

The third peak preferably has a shape with a flattened top compared to the Lorentz function or a shape shown by sum of two or more Lorentz functions of the same peak height and of different peak positions. The reason why the third peak has such a shape seems, for example, the coexistence of the O3-type crystal structure and the pseudo-spinel crystal structure.

In the secondary battery including a positive electrode having the positive electrode active material of one embodiment of the present invention and a negative electrode, the negative electrode preferably includes graphite and the dQ/dV vs V curve of the secondary battery preferably includes at least two peaks of the first peak to the third peak within the voltage range 0.1 V lower than the above-described lithium metal voltage. In such a case, a charge and discharge cycle is repeated and the dQ/dV vs V curve is calculated from charging curves; when the dQ/dV vs V curve of the secondary battery includes the third peak in the 1st to the 10th measurement of the charge and discharge cycle, the peak intensity preferably increases; when the dQ/dV vs V curve of the secondary battery includes the third peak in the 30th to the 100th measurement of the charge and discharge cycle, the peak intensity decreases, for example, and when the dQ/dV vs V curve of the secondary battery includes the first peak, the voltage at the peak position increases, for example.

### Structure Example of Positive Electrode Active Material

An example of LiCoO₂ in which magnesium is substituted for a lithium atom position and a cobalt atom position is described below.

### <First-Principles Calculation>

Of LiCoO₂ in which magnesium is substituted for a lithium atom position and a cobalt atom position, a stabilization energy before the substitution and a stabilization energy after the substitution are calculated using the first-principles calculation, and effect of magnesium is considered.

Using the first-principles calculation, lattices and atomic positions are optimized with a layered rock-salt crystal structure and the R-3m space group to calculate the energies.

An example of a result of the first-principles calculation is shown below.

As software, VASP (The Vienna Ab initio simulation package) was used. As a functional, GGA (Generalized-Gradient-Approximation)+U was used. The U potential of cobalt was 4.91. A potential generated by a PAW (Projector Augmented Wave) method was used for pseudopotential of electronic states. The cut-off energy was set to 520 eV. Here, Non-Patent Document 6 and Non-Patent Document 7 can be referred to for the U potential.

In this specification and the like, the energy calculated in this manner is called stabilization energy.

First, a 4×4×1 supercell was formed to optimize the crystal structure of LiCoO₂, and the stabilization energy was calculated. At this time, the lattice constant was optimized. K-points were set to 3×3×3. The number of atoms were the following: 48 lithium atoms, 48 cobalt atoms, and 96 oxygen atoms.

Next, one lithium atom or one cobalt atom was substituted for a magnesium atom; optimization is performed without changing the lattice constant, and the stabilization energy was calculated.

Next, for each structure whose stabilization energy was calculated, the stabilization energy with one lithium atom extracted was calculated, and the difference ΔE between before and after the lithium extraction was calculated. ΔE can be represented by the following formula. The following formula shows the energy difference between before and after (48−x) lithium atoms of LiCoO₂ was/were extracted. Eₜₒₜₐₗ(Li₄₈Co₄₈O₉₆) is the stabilization energy of LiCoO₂, Eₜₒₜₐₗ(LiₓCo₄₈O₉₆) is the stabilization energy after (48−x) lithium atoms was/were extracted from LiCoO₂, and Eₘₑₜₐₗ(Li) is the stabilization energy of a lithium atom. The stabilization energy of a lithium atom was calculated using a body-centered cubic structure.

$$\begin{matrix}[ Formula 1 ] & \\ Δ E = {E}_{total} ( {Li}_{48} {Co}_{48} {O}_{96} ) - {E}_{total} ( {Li}_{x} {Co}_{48} {O}_{96} ) + ( 48 - x ) {E}_{metal} ( Li ) & ( Formula 1 )\end{matrix}$$

Like LiCoO₂, of the structure in which one lithium atom in Li₄₈Co₄₈O₉₆ was substituted with magnesium and (48−x) lithium atoms was/were extracted (Li₍ₓ₋₁₎Mg₁Co₄₈O₉₆), and of the structure in which one cobalt atom in Li₄₈Co₄₈O₉₆ was substituted with magnesium and (48−x) lithium atoms was/were extracted (LiₓMg₁Co₄₇O₉₆), the differences in the stabilization energy between before and after the lithium extraction was calculated like the above.

Next, a voltage Va when lithium was extracted was calculated. The voltage Va can be calculated with the following formula. Here, n is the number of moles of extracted lithium and F is the Faraday constant.

$$\begin{matrix}[ Formula 2 ] & \\ Va = \frac{Δ G}{nF} & ( Formula 2 )\end{matrix}$$

Here, the following formula can be obtained using the difference of the stabilization energy ΔE as the Gibbs free energy ΔG.

$$\begin{matrix}[ Formula 3 ] & \\ Va = \frac{Δ E}{nF} & ( Formula 3 )\end{matrix}$$

The voltage Va calculated with the above formula is shown in the table below. In the table, (ortho) means extraction of lithium atoms at the ortho positions, (para) means extraction of lithium atoms at the para positions, and (meta) means extraction of lithium atoms at the meta positions.

TABLE 1

| Before lithium extraction | After lithium extraction | Va [V] |
|---|---|---|
| Li₄₈Co₄₈O₉₆ | Li₄₇Co₄₈O₉₆ | 4.24 |
| Li₄₇Mg₁Co₄₈O₉₆ | Li₄₆Mg₁Co₄₈O₉₆ | 1.95 |
| | Li₄₅Mg₁Co₄₈O₉₆ (ortho) | 2.97 |
| | Li₄₅Mg₁Co₄₈O₉₆ (para) | 3.01 |
| | Li₄₄Mg₁Co₄₈O₉₆ (meta) | 3.44 |
| Li₄₈Mg₁Co₄₇O₉₆ | Li₄₇Mg₁Co₄₇O₉₆ | 3.75 |
| | Li₄₆Mg₁Co₄₇O₉₆ | 3.84 |

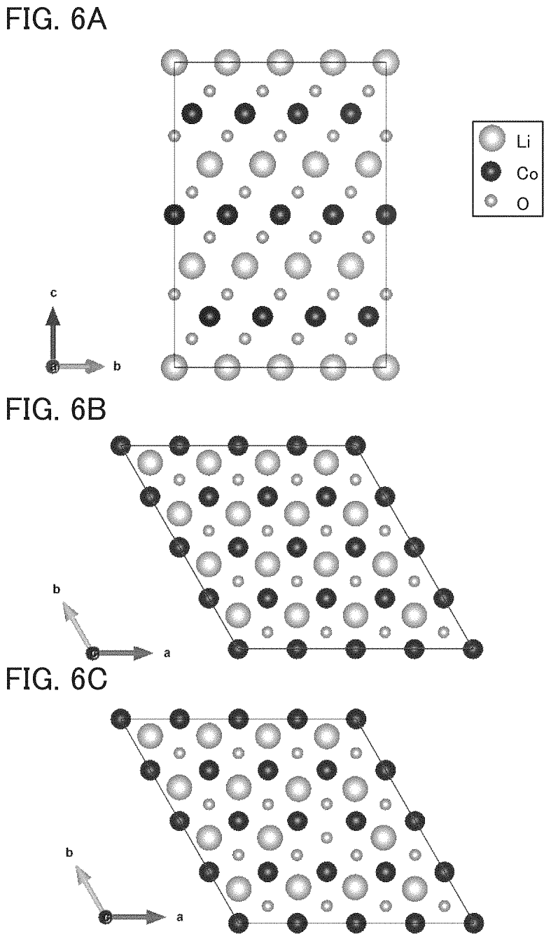

FIG. 6A shows a crystal structure of LiCoO₂ seen in the a-axis direction, and FIG. 6B shows a crystal structure of LiCoO₂ seen in the c-axis direction.

FIG. 6C shows a crystal structure in which one lithium atom is removed from the crystal structure of FIG. 6A.

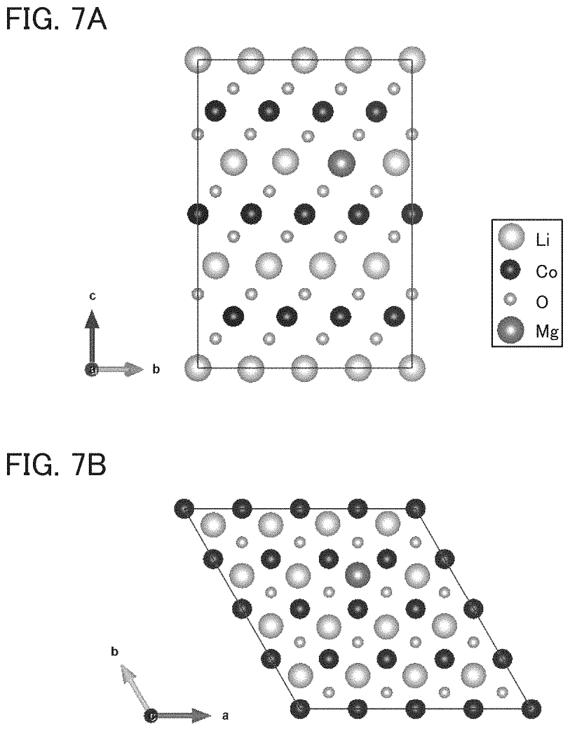

FIG. 7A shows a crystal structure in which a magnesium atom is substituted for a lithium position in the crystal structure of FIG. 6A and which is seen in the a-axis direction, and FIG. 7B shows that seen in the c-axis direction.

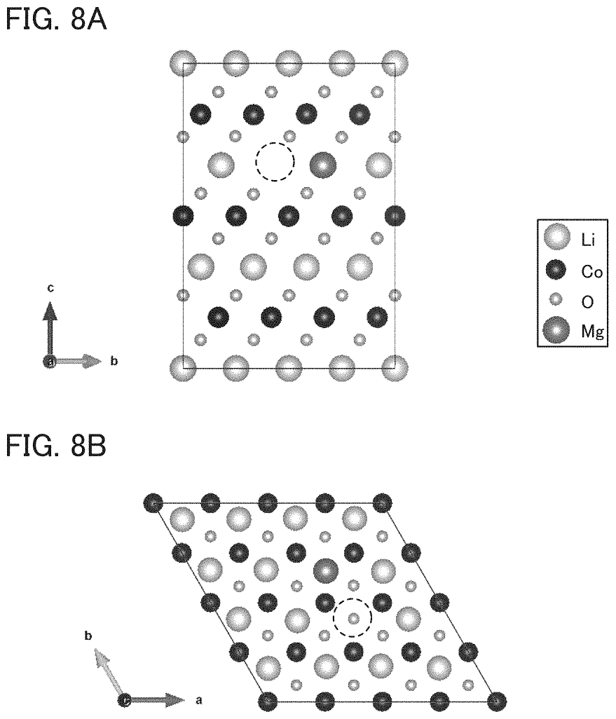

FIG. 8A shows a crystal structure in which one lithium atom is removed from the crystal structure of FIG. 7A, and FIG. 8B shows FIG. 8A seen in the c-axis direction.

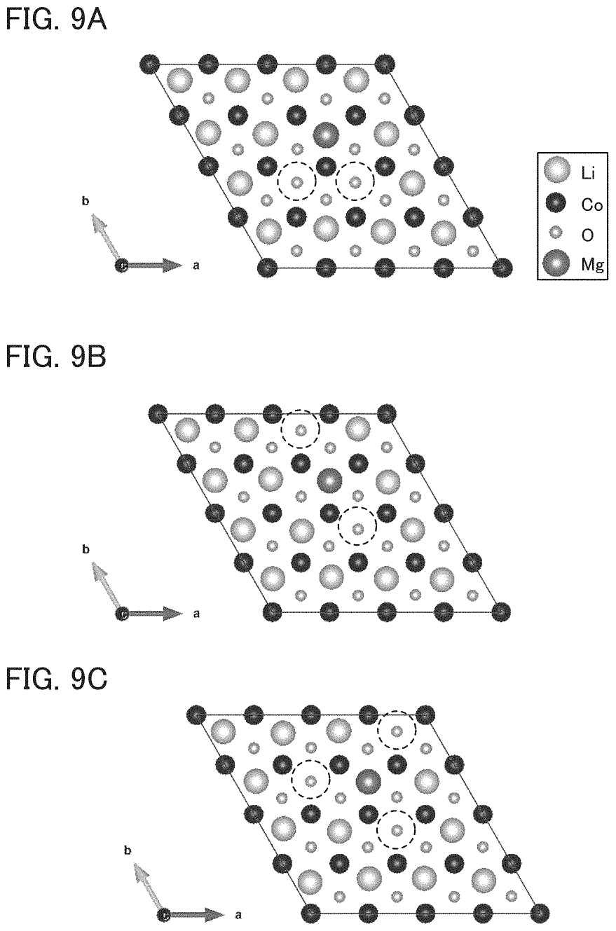

FIG. 9A shows a crystal structure in which two lithium atoms corresponding to the ortho positions are removed in the crystal structure of FIG. 7B, FIG. 9B shows a crystal structure in which two lithium atoms corresponding to the para positions are removed in the crystal structure of FIG. 7B, and FIG. 9C shows a crystal structure in which three lithium atoms corresponding to the meta positions are removed in the crystal structure of FIG. 7B.

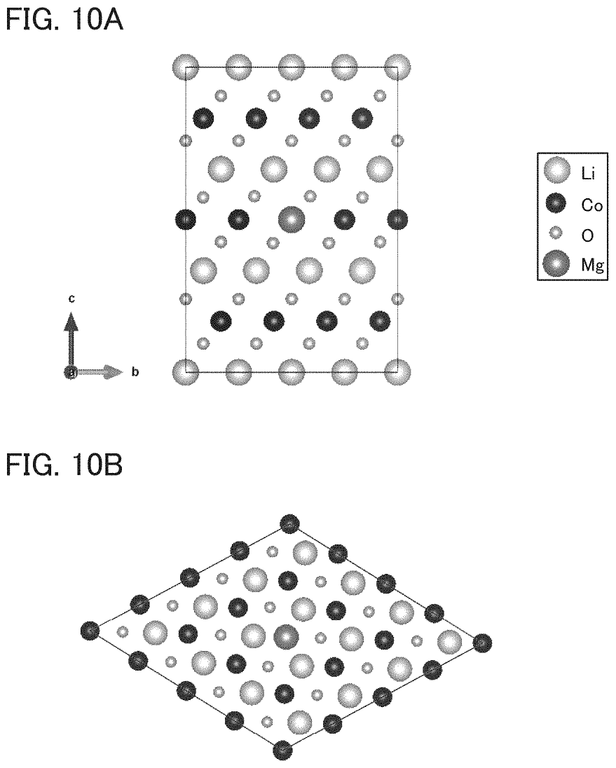

FIG. 10A shows a crystal structure in which a magnesium atom is substituted for a cobalt position in the crystal structure of FIG. 6A and which is seen in the a-axis direction, and FIG. 10B shows that seen in the c-axis direction.

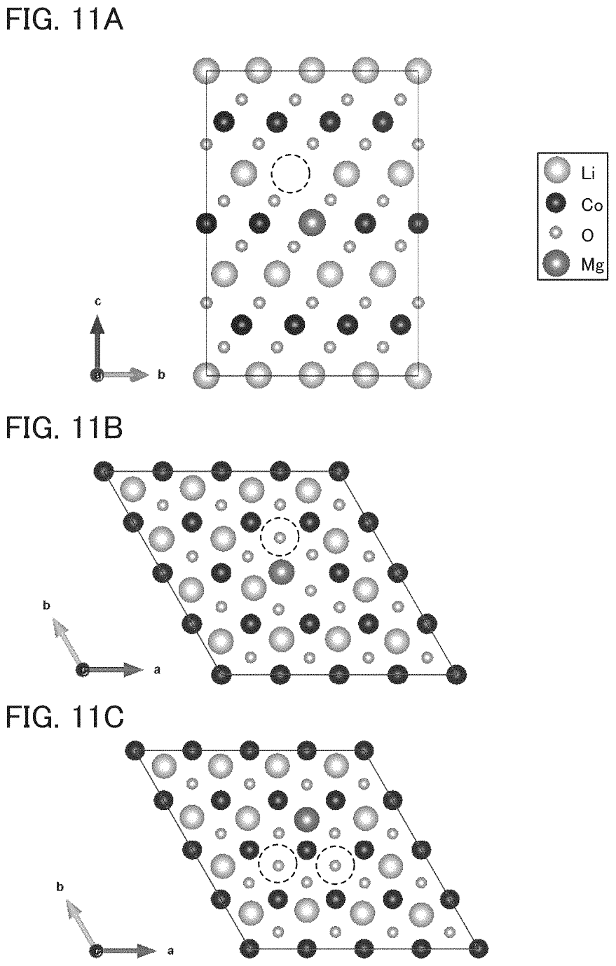

FIG. 11A shows a crystal structure in which one lithium atom is removed from the crystal structure of FIG. 10A, and FIG. 11B shows FIG. 11A seen in the c-axis direction.

FIG. 11C shows a crystal structure in which two lithium atoms are removed from the crystal structure of FIG. 10B.

When a magnesium atom was substituted for a cobalt position, Va became 3.7 V or more, which was approximately 0.5 V lower than that in the case where a magnesium atom was not substituted. Va became much lower when a magnesium atom was substituted for a lithium position.

Thus, it was suggested that the decreases in voltage were caused in either case where a magnesium atom was substituted for a lithium position or a cobalt position, which may cause a hump of a discharge curve. The voltage difference is relatively small between when a magnesium atom is substituted for a cobalt position and when it is not substituted; when a magnesium atom is substituted for a lithium position, a hump can be clearly observed. When the voltage is too low, the extracted lithium atom may not be inserted in discharging.

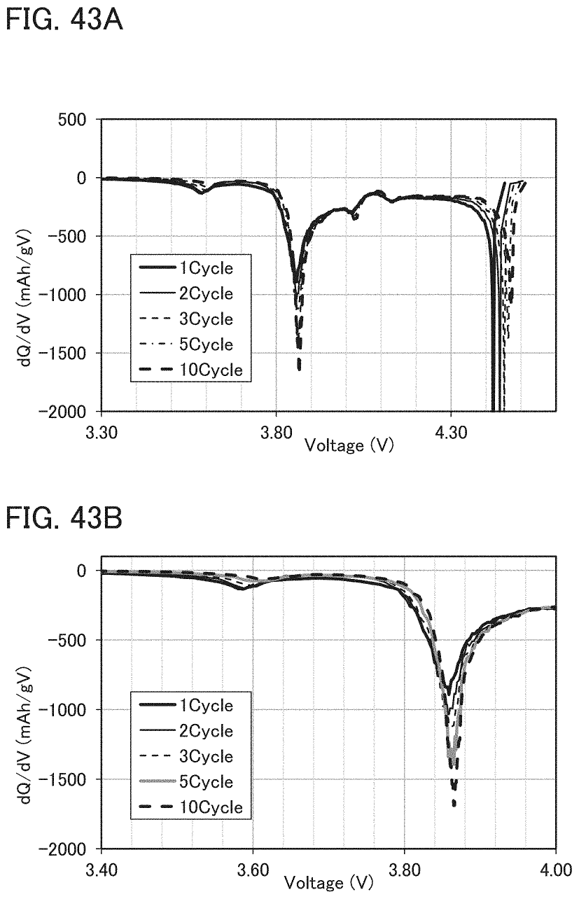

The following show examples of dQ/dV vs V curves calculated from discharge curves of a secondary battery whose positive electrode uses a positive electrode active material including lithium, magnesium, cobalt, oxygen, and fluorine as the positive electrode active material of one embodiment of the present invention. Lithium metal was used for a counter electrode. Charge-and-discharge cycle measurements were performed; dQ/dV vs V curves were calculated from the 1st, 2nd, 3rd, 5th, and 10th cycle discharge curves. FIG. 43A shows the results. FIG. 43B shows a magnified figure in the range of 3.4 V to 4.0 V. Downwardly projected peaks were obviously observed in FIG. 43A and FIG. 43B. The largest peak appeared at approximately 3.9 V. As indicated in the graph, at least one peak appeared in the range of 3.5 V to 3.9 V.

It is confirmed that the positive electrode active material of one embodiment of the present invention shows a characteristic change in voltage just before the end of discharge when the positive electrode active material of one embodiment of the present invention is charged with a high voltage and then discharged at a low rate of, for example, 0.2 C or less. This change can be clearly observed by the fact that at least one peak appears within the range of 3.5 V to 3.9 V in a dQ/dV vs V curve.

The results of Table 1 shows that the peaks observed in the range of 3.5 V to 3.9 V may be caused by substitution of magnesium for a cobalt position or a lithium position, though there are slight differences among the values of the voltage.

This embodiment can be implemented in appropriate combination with the other embodiments.

### Embodiment 2

In this embodiment, an example of a method of making the positive electrode active material of one embodiment of the present invention is described.

### [Method of Forming Positive Electrode Active Material]

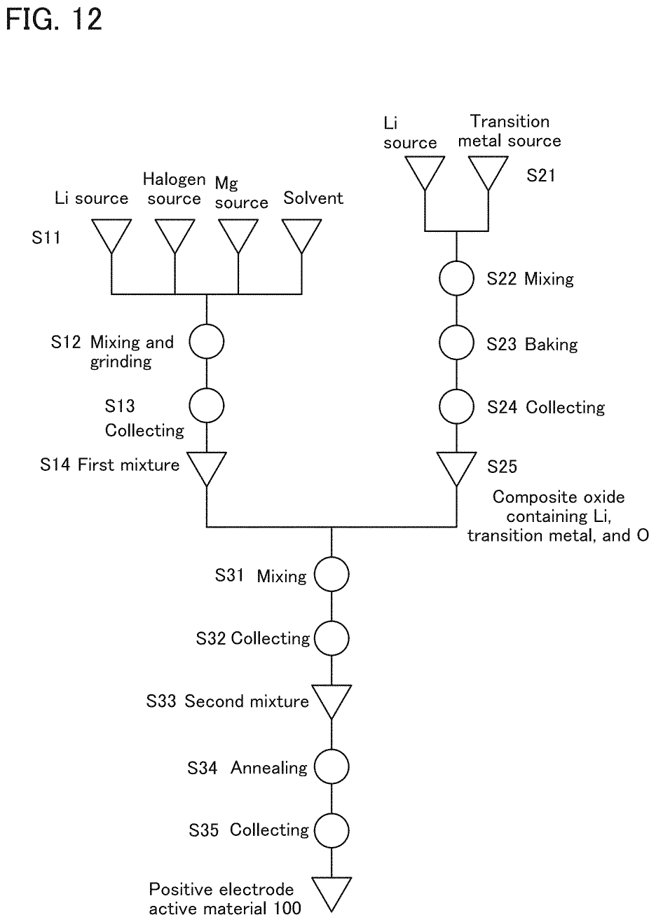

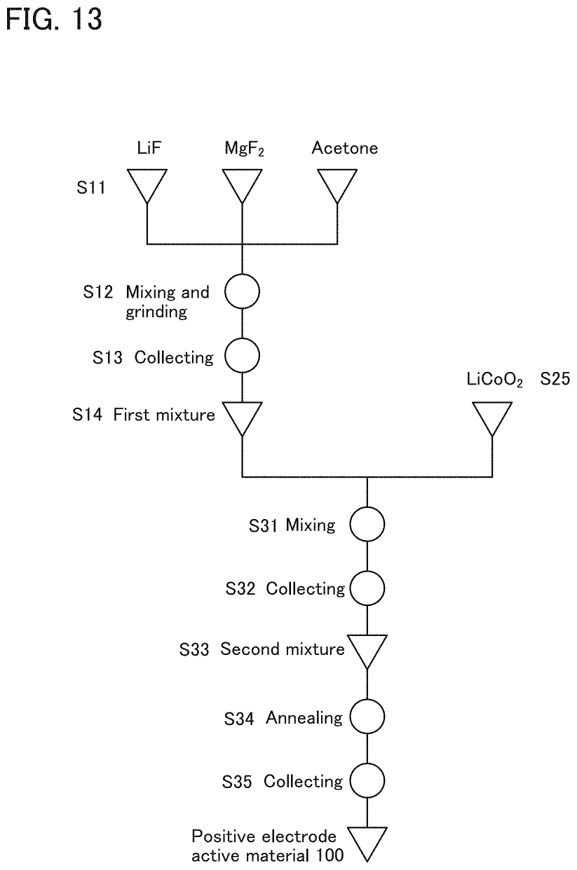

First, an example of a method of making a positive electrode active material 100, which is one embodiment of the present invention, is described using FIG. 12. In addition, FIG. 13 shows another more specific example of a forming method.

### <Step S11>

First, a halogen source such as a fluorine source or a chlorine source and a magnesium source are prepared as materials of a first mixture as shown in Step S11 in FIG. 12. In addition, a lithium source is preferably prepared as well.

As the fluorine source, for example, lithium fluoride, magnesium fluoride, or the like can be used. Among them, lithium fluoride, which has a relatively low melting point of 848° C., is preferable because it is easily melted in an annealing process described later. As the chlorine source, for example, lithium chloride, magnesium chloride, or the like can be used. As the magnesium source, for example, magnesium fluoride, magnesium oxide, magnesium hydroxide, magnesium carbonate, or the like can be used. As the lithium source, for example, lithium fluoride, lithium carbonate, or the like can be used. Thus, lithium fluoride can be used as the lithium source and as the fluorine source. Magnesium fluoride can be used as the fluorine source and as the magnesium source.

In this embodiment, lithium fluoride LiF is prepared as the fluorine source and the lithium source, and magnesium fluoride MgF₂ is prepared as the fluorine source and the magnesium source (Step S11 in FIG. 13). When lithium fluoride LiF and magnesium fluoride MgF₂ are mixed at a molar ratio of approximately LiF:MgF₂=65:35, the effect of reducing the melting point becomes the highest (Non-Patent Document 4). On the other hand, when the amount of lithium fluoride increases, cycle performance might deteriorate because of a too large amount of lithium. Therefore, the molar ratio of lithium fluoride LiF to magnesium fluoride MgF₂ is preferably LiF:MgF₂=x:1 (0≤x≤1.9), further preferably LiF:MgF₂=x:1 (0.1≤x≤0.5), still further preferably LiF:MgF₂=x:1 (x=0.33 or a value close thereto). Note that in this specification and the like, the vicinity means a value greater than 0.9 times and smaller than 1.1 times a certain value.

In addition, in the case where the following mixing and grinding steps are performed by a wet process, a solvent is prepared. As the solvent, ketone such as acetone; alcohol such as ethanol or isopropanol; ether; dioxane; acetonitrile; N-methyl-2-pyrrolidone (NMP); or the like can be used. An aprotic solvent that hardly reacts with lithium is further preferably used. In this embodiment, acetone is used (see Step S11 in FIG. 13).

### <Step S12>

Next, the materials of the first mixture are mixed and ground (Step S12 in FIG. 12 and FIG. 13). Although the mixing can be performed by a dry process or a wet process, the wet process is preferable because the materials can be ground to a smaller size. For example, a ball mill, a bead mill, or the like can be used for mixing. When a ball mill is used, a zirconia ball is preferably used as media, for example. The mixing step and the grinding step are preferably performed sufficiently to pulverize the first mixture.

### <Step S13 and Step S14>

The materials mixed and ground in the above manner are collected (Step S13 in FIG. 12 and FIG. 13), whereby the first mixture is obtained (Step S14 in FIG. 12 and FIG. 13).

The first mixture preferably has an average particle diameter (D50: also referred to as a median diameter) of greater than or equal to 600 nm and less than or equal to 20 μm, further preferably greater than or equal to 1 μm and less than or equal to 10 μm. When mixed with a composite oxide containing lithium, transition metal, and oxygen in a later step, the first mixture pulverized to such a small size is easily attached to surfaces of composite oxide particles uniformly. The first mixture is preferably attached to the surface of the composite oxide particles uniformly because both halogen and magnesium are easily distributed to the superficial portion of the composite oxide particles after heating. When there is a region containing neither halogen nor magnesium in the superficial portion, a pseudo-spinel crystal structure, which is described later, might be less likely to be obtained, in the charged state.

### <Step S21>

Next, as shown in Step S21 in FIG. 12, a lithium source and a transition metal source are prepared as the materials of a composite oxide containing lithium, transition metal, and oxygen.

As the lithium source, for example, lithium carbonate, lithium fluoride, or the like can be used.

As the transition metal, at least one of cobalt, manganese, and nickel can be used. A composite oxide containing lithium, transition metal, and oxygen preferably has a layered rock-salt crystal structure, and thus cobalt, manganese, and nickel preferably have a mixing ratio at which the composite oxide can have a layered rock-salt crystal structure. In addition, aluminum may be added to the transition metal as long as the positive electrode active material can have a layered rock-salt crystal structure.

As the transition metal source, oxide or hydroxide of the transition metal, or the like can be used. As the cobalt source, for example, cobalt oxide, cobalt hydroxide, or the like can be used. As the manganese source, manganese oxide, manganese hydroxide, or the like can be used. As the nickel source, nickel oxide, nickel hydroxide, or the like can be used. As an aluminum source, aluminum oxide, aluminum hydroxide, or the like can be used.

### <Step S22>

Next, the lithium source and the transition metal source are mixed (Step S22 in FIG. 12). Mixing can be performed by a dry process or a wet process. For example, a ball mill, a bead mill, or the like can be used for mixing. When the ball mill is used, a zirconia ball is preferably used as media, for example.

### <Step S23>

Next, the materials mixed in the above are heated. This step is sometimes referred to as baking or first heating to distinguish this step from a heating step performed later. Heating is preferably performed at higher than or equal to 800° C. and lower than 1100° C., further preferably at higher than or equal to 900° C. and lower than or equal to 1000° C., still further preferably at approximately 950° C. Too low temperature might result in insufficient decomposition and melting of starting materials. Too high temperature, on the other hand, might cause a defect due to excessive reduction of the transition metal, evaporation of lithium, or the like. For example, a defect in which cobalt has divalence might be caused.

The heating time is preferably longer than or equal to 2 hours and shorter than or equal to 20 hours. Baking is preferably performed in an atmosphere with little moisture, such as dry air (e.g., a dew point is lower than or equal to −50° C., preferably lower than or equal to −100° C.). For example, it is preferable that heating be performed at 1000° C. for 10 hours, the temperature rise be 200° C./h, and the flow rate of a dry atmosphere be 10 L/min. After that, the heated materials can be cooled to room temperature. The temperature decreasing time from the specified temperature to room temperature is preferably longer than or equal to 10 hours and shorter than or equal to 50 hours, for example.

Note that cooling to room temperature in Step S23 is not essential. As long as later steps of Step S24, Step S25, and Step S31 to Step S34 are performed without problems, cooling may be performed to a temperature higher than room temperature.

### <Step S24 and Step S25>

The materials baked in the above manner are collected (Step S24 in FIG. 12), whereby the composite oxide containing lithium, the transition metal, and oxygen is obtained (Step S25 in FIG. 12). Specifically, lithium cobaltate, lithium manganese oxide, lithium nickel oxide, lithium cobaltate in which manganese is substituted for part of cobalt, or lithium nickel-manganese-cobalt oxide is obtained.

A composite oxide including lithium, transition metal, and oxygen that is synthesized in advance may be used as Step S25 (see FIG. 13). In this case, Step S21 to Step S24 can be skipped.

In the case where the composite oxide including lithium, the transition metal, and oxygen that is synthesized in advance is used, a composite oxide with few impurities is preferably used. In this specification and the like, lithium, cobalt, nickel, manganese, aluminum, and oxygen are the main components of the composite oxide including lithium, the transition metal, and oxygen and the positive electrode active material, and elements other than the main components are regarded as impurities. For example, when analyzed with a glow discharge mass spectroscopy method, the total impurity concentration is preferably less than or equal to 10,000 ppm wt, more preferably less than or equal to 5,000 ppm wt. In particular, the total impurity concentration of transition metals such as titanium and arsenic is preferably less than or equal to 3,000 ppm wt, further preferably less than or equal to 1,500 ppm wt.

For example, as lithium cobaltate synthesized in advance, a lithium cobaltate particle (product name: CELLSEED C-10N) manufactured by NIPPON CHEMICAL INDUSTRIAL CO., LTD. can be used. This is lithium cobaltate in which the average particle diameter (D50) is approximately 12 μm, and in the impurity analysis with a glow discharge mass spectroscopy method (GD-MS), the magnesium concentration and the fluorine concentration are less than or equal to 50 ppm wt, the calcium concentration, the aluminum concentration, and the silicon concentration are less than or equal to 100 ppm wt, the nickel concentration is less than or equal to 150 ppm wt, the sulfur concentration is less than or equal to 500 ppm wt, the arsenic concentration is less than or equal to 1,100 ppm wt, and the concentrations of elements other than lithium, cobalt, and oxygen are less than or equal to 150 ppm wt.

Alternatively, a lithium cobaltate particle (product name: CELLSEED C-5H) manufactured by NIPPON CHEMICAL INDUSTRIAL CO., LTD. can be used. This is lithium cobaltate in which the average particle diameter (D50) is approximately 6.5 μm, and the concentrations of elements other than lithium, cobalt, and oxygen are approximately equal to or less than those of C-10N in the impurity analysis with GD-MS.

In this embodiment, cobalt is used as the transition metal, and the lithium cobaltate particle (CELLSEED C-10N manufactured by NIPPON CHEMICAL INDUSTRIAL CO., LTD.) is used (see FIG. 13).

The composite oxide including lithium, the transition metal, and oxygen in Step S25 preferably has a layered rock-salt crystal structure with few defects and distortions. Therefore, the composite oxide is preferably a composite oxide that includes few impurities. In the case where the composite oxide including lithium, the transition metal, and oxygen includes a lot of impurities, the crystal structure is highly likely to have a lot of defects or distortions.

### <Step S31>

Next, the first mixture and the composite oxide containing lithium, the transition metal, and oxygen are mixed (Step S31 in FIG. 12 and FIG. 13). The atomic ratio of the transition metal TM in the composite oxide containing lithium, the transition metal, and oxygen to magnesium Mg_{Mix1} contained in the first mixture Mix1 is preferably TM:Mg_{Mix1}=1:y (0.0005≤y≤0.03), further preferably TM:Mg_{Mix1}=1:y (0.001≤y≤0.01), still further preferably approximately TM:Mg_{Mix1}=1:0.005.

The condition of mixing in Step S31 is preferably milder than that of mixing in Step S12 not to damage the particles of the composite oxide. For example, a condition with a lower rotation frequency or shorter time than mixing in Step S12 is preferable. In addition, it can be said that the dry process has a milder condition than the wet process. For example, a ball mill, a bead mill, or the like can be used for mixing. When the ball mill is used, a zirconia ball is preferably used as media, for example.

### <Step S32 and Step S33>

The materials mixed in the above manner are collected (Step S32 in FIG. 12 and FIG. 13), whereby a second mixture is obtained (Step S33 in FIG. 12 and FIG. 13).

Note that this embodiment describes a method of adding the mixture of lithium fluoride and magnesium fluoride to lithium cobaltate with few impurities; however, one embodiment of the present invention is not limited thereto. Mixture obtained through baking after addition of a magnesium source and a fluorine source to the starting material of lithium cobaltate may be used instead of the second mixture in Step S33. In that case, there is no need to separate steps Step S11 to Step S14 and steps Step S21 to Step S25, which is simple and productive.

Alternatively, lithium cobaltate to which magnesium and fluorine are added in advance may be used. When lithium cobaltate to which magnesium and fluorine are added is used, the process can be simpler because the steps up to Step S32 can be omitted.

In addition, a magnesium source and a fluorine source may be further added to the lithium cobaltate to which magnesium and fluorine are added in advance.

### <Step S34>

Next, the second mixture is heated. This step can be referred to as annealing or second heating to distinguish this step from the heating step performed before.

Annealing is preferably performed at an appropriate temperature for an appropriate time. The appropriate temperature and time depend on the conditions such as the particle size and the composition of the composite oxide including lithium, the transition metal, and oxygen in Step S25. In the case where the particle size is small, annealing is preferably performed at a lower temperature or for a shorter time than the case where the particle size is large, in some cases.

When the average particle diameter (D50) of the particles in Step S25 is approximately 12 μm, for example, an annealing temperature is preferably higher than or equal to 600° C. and lower than or equal to 950° C., for example. An annealing time is preferably longer than or equal to 3 hours, further preferably longer than or equal to 10 hours, still further preferably longer than or equal to 60 hours, for example.

On the other hand, when the average particle diameter (D50) of the particles in Step S25 is approximately 5 μm, an annealing temperature is preferably higher than or equal to 600° C. and lower than or equal to 950° C., for example. An annealing time is preferably longer than or equal to 1 hour and shorter than or equal to 10 hours, further preferably approximately 2 hours, for example.

A temperature decreasing time after annealing is, for example, preferably longer than or equal to 10 hours and shorter than or equal to 50 hours.

It is considered that when the second mixture is annealed, a material having a low melting point (e.g., lithium fluoride, whose melting point is 848° C.) in the first mixture is melted first and distributed to the superficial portion of the composite oxide particle. Next, the existence of the melted material decreases the melting points of other materials, probably resulting in melting of the other materials. For example, magnesium fluoride (melting point: 1263° C.) is probably melted and distributed to the superficial portion of the composite oxide particle.

Then, the elements that are included in the first mixture and are distributed to the superficial portion are probably entered into a solid solution in the composite oxide containing lithium, the transition metal, and oxygen.

The elements included in the first mixture diffuse faster in the superficial portion and the vicinity of the grain boundary than inside the composite oxide particles. Therefore, the magnesium concentration and the halogen concentration in the superficial portion and the vicinity of the grain boundary are higher than those inside the composite oxide particles. As described later, the higher the magnesium concentration in the superficial portion and the vicinity of the grain boundary is, the more effectively change in the crystal structure can be suppressed.

### <Step S35>

The materials annealed in the above manner are collected, whereby the positive electrode active material 100 of one embodiment of the present invention is obtained.

When made with a method like that in FIG. 12 and FIG. 13, the positive electrode active material having the pseudo-spinel crystal structure with few defects in high-voltage charging can be made. A positive electrode active material in which the pseudo-spinel crystal structure accounts for more than or equal to 50% when analyzed with Rietveld analysis has excellent cycle performance and rate characteristics.

To include magnesium and fluorine in the positive electrode active material and to anneal the second mixture at an appropriate temperature for an appropriate time are effective in making the positive electrode active material having the pseudo-spinel crystal structure after high-voltage charging. A magnesium source and a fluorine source may be added to the starting material of the composite oxide. However, when the melting points of the magnesium source and the fluorine source are higher than the baking temperature, the magnesium source and the fluorine source added to the starting material of the composite oxide might not be melted, resulting in insufficient diffusion. This highly causes a lot of defects or distortions in the layered rock-salt crystal structure. As a result, the pseudo-spinel crystal structure after high-voltage charging also might have defects or distortions.

Thus, it is preferable that a composite oxide having a layered rock-salt crystal structure with few impurities, defects, or distortions be obtained first. Then, the composite oxide, a magnesium source, and a fluorine source are preferably mixed and annealed in a later step to form a solid solution of magnesium and fluorine in the superficial portion of the composite oxide. In this matter, the positive electrode active material having the pseudo-spinel crystal structure with few defects or distortions after high-voltage charging can be manufactured.

In addition, the positive electrode active material 100 made through the above steps may be further covered with another material. In addition, heating may be further performed.

For example, the positive electrode active material 100 and a compound containing phosphoric acid can be mixed. Heat treatment can be performed after mixing. When the compound containing phosphoric acid is mixed, it is possible to obtain the positive electrode active material 100 where elution of a transition metal such as cobalt is inhibited even when a state being charged with a high voltage is held for a long time. Moreover, heating after mixing enables more uniform coverage with phosphoric acid.

As a compound containing phosphoric acid, for example, lithium phosphate, ammonium dihydrogen phosphate, or the like can be used. Mixing can be performed with a solid phase method, for example. Heating can be performed at higher than or equal to 800° C. for two hours, for example.

This embodiment can be implemented in appropriate combination with the other embodiments.

### Embodiment 3

In this embodiment, examples of materials that can be used for a secondary battery containing the positive electrode active material 100 described in the above embodiment are described. In this embodiment, a secondary battery in which a positive electrode, a negative electrode, and an electrolyte solution are wrapped in an exterior body is described as an example.

### [Positive Electrode]

The positive electrode includes a positive electrode active material layer and a positive electrode current collector.

### <Positive Electrode Active Material Layer>

The positive electrode active material layer contains at least a positive electrode active material. The positive electrode active material layer may contain, in addition to the positive electrode active material, other materials such as a coating film of the active material surface, a conductive additive, and a binder.

As the positive electrode active material, the positive electrode active material 100 described in the above embodiment can be used. A secondary battery including the positive electrode active material 100 described in the above embodiment can have high capacity and excellent cycle performance.

Examples of the conductive additive include a carbon material, a metal material, and a conductive ceramic material. A fiber material may be used as the conductive additive. The content of the conductive additive in the active material layer is preferably greater than or equal to 1 wt % and less than or equal to 10 wt %, further preferably greater than or equal to 1 wt % and less than or equal to 5 wt %.

A network for electric conduction can be formed in the active material layer by the conductive additive. The conductive additive can also maintain a path for electric conduction between the positive electrode active materials. The addition of the conductive additive to the active material layer increases the electric conductivity of the active material layer.

Examples of the conductive additive include natural graphite, artificial graphite such as mesocarbon microbeads, and carbon fiber. As carbon fiber, mesophase pitch-based carbon fiber and isotropic pitch-based carbon fiber can be used. Furthermore, as carbon fiber, carbon nanofiber and carbon nanotube can be used. Carbon nanotube can be formed with, for example, a vapor deposition method. Other examples of the conductive additive include carbon materials such as carbon black (e.g., acetylene black (AB)), graphite (black lead) particles, graphene, and fullerene. For example, metal powder or metal fibers of copper, nickel, aluminum, silver, gold, or the like, a conductive ceramic material, or the like can be used.

A graphene compound may be used as the conductive additive.

A graphene compound has excellent electrical characteristics of high conductivity and excellent physical properties of high flexibility and high mechanical strength in some cases. Furthermore, a graphene compound has a planar shape. A graphene compound enables low-resistance surface contact. Furthermore, a graphene compound has extremely high conductivity even with a small thickness in some cases and thus allows a conductive path to be formed in an active material layer efficiently even with a small amount. Thus, a graphene compound is preferably used as the conductive additive, in which case the area where the active material and the conductive additive are in contact with each other can be increased. The graphene compound that is the conductive additive is preferably formed using a spray dry apparatus as a coating film to cover the entire surface of the active material. In addition, the graphene compound is preferable because electrical resistance can be reduced in some cases. Here, it is particularly preferable to use, for example, graphene, multilayer graphene, or RGO as a graphene compound. Note that RGO refers to a compound obtained by reducing graphene oxide (GO), for example.

In the case where an active material with a small particle size (e.g., 1 μm or less) is used, the specific surface area of the active material is large and thus more conductive paths for the active material particles are needed. Thus, the amount of conductive additive tends to increase and the loaded amount of active material tends to decrease relatively. When the loaded amount of active material decreases, the capacity of the secondary battery also decreases. In such a case, a graphene compound that can efficiently form a conductive path even with a small amount is particularly preferably used as the conductive additive because the loaded amount of active material does not decrease.

A cross-sectional structure example of an active material layer 200 containing a graphene compound as a conductive additive is described below.

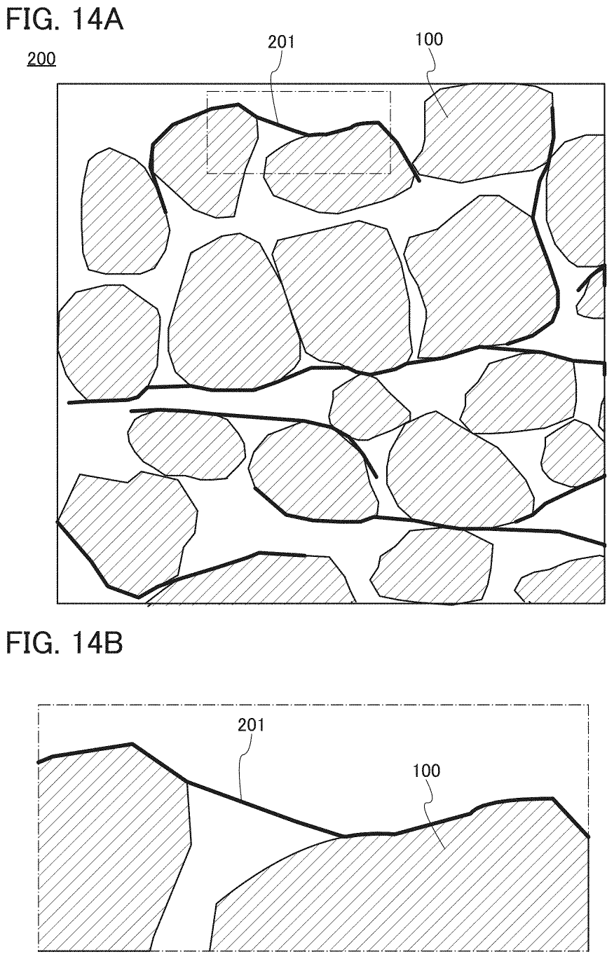

FIG. 14A is a longitudinal cross-sectional view of the active material layer 200. The active material layer 200 includes particles of the positive electrode active material 100, a graphene compound 201 serving as a conductive additive, and a binder (not shown). Here, graphene or multilayer graphene may be used as the graphene compound 201, for example. The graphene compound 201 preferably has a sheet-like shape. The graphene compound 201 may have a sheet-like shape formed of a plurality of sheets of multilayer graphene and/or a plurality of sheets of graphene that partly overlap with each other.

The longitudinal cross section of the active material layer 200 in FIG. 14B shows substantially uniform dispersion of the sheet-like graphene compounds 201 in the active material layer 200. The graphene compounds 201 are schematically shown by thick lines in FIG. 14B but are actually thin films each having a thickness corresponding to the thickness of a single layer or a multi-layer of carbon molecules. The plurality of graphene compounds 201 are formed to partly coat or adhere to the surfaces of the plurality of particles of the positive electrode active material 100, so that the graphene compounds 201 make surface contact with the particles of the positive electrode active material 100.

Here, the plurality of graphene compounds are bonded to each other to form a net-like graphene compound sheet (hereinafter, referred to as a graphene compound net or a graphene net). The graphene net covering the active material can function as a binder for bonding active materials. The amount of binder can thus be reduced, or the binder does not have to be used. This can increase the proportion of the active material in the electrode volume or weight. That is, the capacity of the secondary battery can be increased.

Here, it is preferable to perform reduction after a layer to be the active material layer 200 is formed in such a manner that graphene oxide is used as the graphene compound 201 and mixed with an active material. When graphene oxide with extremely high dispersibility in a polar solvent is used for the formation of the graphene compounds 201, the graphene compounds 201 can be substantially uniformly dispersed in the active material layer 200. The solvent is removed by volatilization from a dispersion medium in which graphene oxide is uniformly dispersed, and the graphene oxide is reduced; hence, the graphene compounds 201 remaining in the active material layer 200 partly overlap with each other and are dispersed such that surface contact is made, thereby forming a three-dimensional conduction path. Note that graphene oxide can be reduced either by heat treatment or with the use of a reducing agent, for example.

Unlike a conductive additive in the form of particles, such as acetylene black, which makes point contact with an active material, the graphene compound 201 is capable of making low-resistance surface contact; accordingly, the electrical conduction between the particulate positive electrode active material 100 and the graphene compound 201 can be improved with a smaller amount of the graphene compound 201 than that of a normal conductive additive. This increases the proportion of the positive electrode active material 100 in the active material layer 200. This increases discharge capacity of the secondary battery.

With a spray dry apparatus, a graphene compound serving as a conductive additive as a coating film can be formed to cover the entire surface of the active material in advance and a conductive path can be formed between the active materials using the graphene compound.

As the binder, a rubber material such as styrene-butadiene rubber (SBR), styrene-isoprene-styrene rubber, acrylonitrile-butadiene rubber, butadiene rubber, or ethylene-propylene-diene copolymer can be used, for example. Fluororubber can be used as the binder.

As the binder, for example, water-soluble polymers are preferably used. As the water-soluble polymers, for example, a polysaccharide can be used. As the polysaccharide, for example, a cellulose derivative such as carboxymethyl cellulose (CMC), methyl cellulose, ethyl cellulose, hydroxypropyl cellulose, diacetyl cellulose, and regenerated cellulose or starch can be used. It is further preferred that such water-soluble polymers be used in combination with any of the above rubber materials.

As the binder, a material such as polystyrene, poly(methyl acrylate), poly(methyl methacrylate) (polymethyl methacrylate, PMMA), sodium polyacrylate, polyvinyl alcohol (PVA), polyethylene oxide (PEO), polypropylene oxide, polyimide, polyvinyl chloride, polytetrafluoroethylene, polyethylene, polypropylene, polyisobutylene, polyethylene terephthalate, nylon, polyvinylidene fluoride (PVDF), polyacrylonitrile (PAN), ethylene-propylene-diene polymer, polyvinyl acetate, or nitrocellulose is preferably used.

A plurality of the above materials may be used in combination for the binder.

For example, a material having a significant viscosity modifying effect and another material may be used in combination. For example, a rubber material or the like has high adhesion or high elasticity but may have difficulty in viscosity modification when mixed in a solvent. In such a case, a rubber material or the like is preferably mixed with a material having a significant viscosity modifying effect, for example. As a material having a significant viscosity modifying effect, for example, a water-soluble polymer is preferably used. An example of a water-soluble polymer having an especially significant viscosity modifying effect is the above-mentioned polysaccharide; for example, a cellulose derivative such as carboxymethyl cellulose (CMC), methyl cellulose, ethyl cellulose, hydroxypropyl cellulose, diacetyl cellulose, or regenerated cellulose, or starch can be used.

Note that a cellulose derivative such as carboxymethyl cellulose obtains a higher solubility when converted into a salt such as a sodium salt or an ammonium salt of carboxymethyl cellulose, and accordingly, easily exerts an effect as a viscosity modifier. The high solubility can also increase the dispersibility of an active material and other components in the formation of slurry for an electrode. In this specification, cellulose and a cellulose derivative used as a binder of an electrode include salts thereof.

A fluorine-based resin has advantages such as high mechanical strength, high chemical resistance, and high thermal resistance. Among such fluorine-based resins, PVDF has especially excellent properties such as high mechanical strength, good processability, and high thermal resistance.

However, PVDF gels in some cases when the slurry made for coating the active material layer becomes alkaline. PVDF is also insolubilized in some cases. Gelation or insolubilization of the binder causes decrease of adhesiveness between a current collector and an active material layer in some cases. Using the positive electrode active material of one embodiment of the present invention can decrease pH of the slurry and inhibit gelation or insolubilization in some cases, which is preferable.

The thickness of the positive electrode active material layer is greater than or equal to 10 μm and less than or equal to 200 μm. Alternatively, the thickness of the positive electrode active material layer is greater than or equal to 50 μm and less than or equal to 150 μm. The loaded amount of the positive electrode active material layer is, when the positive electrode active material includes a material having a layered rock-salt crystal structure containing cobalt, greater than or equal to 1 mg/cm² and less than or equal to 50 mg/cm². Alternatively, the loaded amount of the positive electrode active material layer is greater than or equal to 5 mg/cm² and less than or equal to 30 mg/cm². The density of the positive electrode active material layer is, for example, when the positive electrode active material includes a material having a layered rock-salt crystal structure containing cobalt, greater than or equal to 2.2 g/cm³ and less than or equal to 4.9 g/cm³. Alternatively, the density of the positive electrode active material layer is greater than or equal to 3.8 g/cm³ and less than or equal to 4.5 g/cm³.

### <Positive Electrode Current Collector>

The positive electrode current collector can be formed using a material that has high conductivity, such as a metal like stainless steel, gold, platinum, aluminum, and titanium, or an alloy thereof. It is preferred that a material used for the positive electrode current collector not dissolve at the potential of the positive electrode. The positive electrode current collector can be formed using an aluminum alloy to which an element that improves heat resistance, such as silicon, titanium, neodymium, scandium, or molybdenum, is added. A metal element that forms silicide by reacting with silicon may be used. Examples of the metal element that forms silicide by reacting with silicon include zirconium, titanium, hafnium, vanadium, niobium, tantalum, chromium, molybdenum, tungsten, cobalt, and nickel. The current collector can have any of a foil-like shape, a plate-like shape (sheet-like shape), a net-like shape, a punching-metal shape, an expanded-metal shape, and the like as appropriate. The current collector preferably has a thickness of greater than or equal to 5 μm and less than or equal to 30 μm.

### [Negative Electrode]

The negative electrode includes a negative electrode active material layer and a negative electrode current collector. In addition, the negative electrode active material layer may contain a conductive additive and a binder.

### <Negative Electrode Active Material>

As a negative electrode active material, for example, an alloy-based material or a carbon-based material can be used.

For the negative electrode active material, an element that enables charge and discharge reaction by alloying and dealloying reactions with lithium can be used. For example, a material containing at least one of silicon, tin, gallium, aluminum, germanium, lead, antimony, bismuth, silver, zinc, cadmium, indium, and the like can be used. Such elements have higher capacity than carbon, and silicon in particular has a high theoretical capacity of 4200 mAh/g. For this reason, silicon is preferably used as the negative electrode active material. A compound including any of the above elements may be used. Examples of the compound include SiO, Mg₂Si, Mg₂Ge, SnO, SnO₂, Mg₂Sn, SnS₂, V₂Sn₃, FeSn₂, CoSn₂, Ni₃Sn₂, Cu₆Sn₅, Ag₃Sn, Ag₃Sb, Ni₂MnSb, CeSb₃, LaSn₃, La₃Co₂Sn₇, CoSb₃, InSb, and SbSn. Here, an element that enables charge and discharge reactions by an alloying reaction and a dealloying reaction with lithium and a compound including the element, for example, may be referred to as an alloy-based material.

In this specification and the like, SiO refers, for example, to silicon monoxide. Note that SiO can alternatively be expressed as SiOₓ. Here, x preferably has an approximate value of 1. For example, x is preferably 0.2 or more and 1.5 or less, further preferably 0.3 or more and 1.2 or less.

As the carbon-based material, graphite, graphitizing carbon (soft carbon), non-graphitizing carbon (hard carbon), carbon nanotube, graphene, carbon black, and the like may be used.

Examples of graphite include artificial graphite and natural graphite. Examples of artificial graphite include meso-carbon microbeads (MCMB), coke-based artificial graphite, and pitch-based artificial graphite. As artificial graphite, spherical graphite having a spherical shape can be used. For example, MCMB is preferably used because it may have a spherical shape. Moreover, MCMB may preferably be used because it is relatively easy to have a small surface area. Examples of natural graphite include flake graphite and spherical natural graphite.

Graphite has a low potential substantially equal to that of a lithium metal (higher than or equal to 0.05 V and lower than or equal to 0.3 V vs. Li/Li⁺) when lithium ions are intercalated into graphite (when a lithium-graphite intercalation compound is formed). For this reason, a lithium-ion secondary battery can have a high operating voltage. In addition, graphite is preferred because of its advantages such as a relatively high capacity per unit volume, relatively small volume expansion, low cost, and higher level of safety than that of a lithium metal.

For the negative electrode active material, oxide such as titanium dioxide (TiO₂), lithium titanium oxide (Li₄Ti₅O₁₂), lithium-graphite intercalation compound (LiₓC₆), niobium pentoxide (Nb₂O₅), tungsten oxide (WO₂), or molybdenum oxide (MoO₂) can be used.

For the negative electrode active material, Li₃₋ₓMₓN (M=Co, Ni, or Cu) with a Li₃N structure, which is a nitride containing lithium and a transition metal, can be used. For example, Li₂₆Co_{0.4}N₃ is preferable because of high charge and discharge capacity (900 mAh/g and 1890 mAh/cm³).

A nitride containing lithium and a transition metal is preferably used, in which case lithium ions are contained in the negative electrode active material and thus the negative electrode active material can be used in combination with a material for a positive electrode active material which does not contain lithium ions, such as V₂O₅ or Cr₃O₈. Note that in the case of using a material containing lithium ions as a positive electrode active material, the nitride containing lithium and a transition metal can be used for the negative electrode active material by extracting the lithium ions contained in the positive electrode active material in advance.

In addition, a material which causes conversion reaction can also be used as the negative electrode active material. For example, a transition metal oxide which does not form an alloy with lithium, such as cobalt oxide (CoO), nickel oxide (NiO), or iron oxide (FeO), may be used for the negative electrode active material. Other examples of the material that causes a conversion reaction include oxides such as Fe₂O₃, CuO, Cu₂O, RuO₂, and Cr₂O₃, sulfides such as CoS_{0.89}, NiS, and CuS, nitrides such as Zn₃N₂, Cu₃N, and Ge₃N₄, phosphides such as NiP₂, FeP₂, and CoP₃, and fluorides such as FeF₃ and BiF₃.

For the conductive additive and the binder that can be included in the negative electrode active material layer, materials similar to those of the conductive additive and the binder that can be included in the positive electrode active material layer can be used.

### <Negative Electrode Current Collector>

For the negative electrode current collector, a material similar to that of the positive electrode current collector can be used. Note that a material which is not alloyed with carrier ions such as lithium is preferably used as the negative electrode current collector.

### [Electrolyte Solution]

The electrolyte solution contains a solvent and an electrolyte. As the solvent of the electrolyte solution, an aprotic organic solvent is preferably used. For example, one of ethylene carbonate (EC), propylene carbonate (PC), butylene carbonate, chloroethylene carbonate, vinylene carbonate, γ-butyrolactone, γ-valerolactone, dimethyl carbonate (DMC), diethyl carbonate (DEC), ethyl methyl carbonate (EMC), methyl formate, methyl acetate, ethyl acetate, methyl propionate, ethyl propionate, propyl propionate, methyl butyrate, 1,3-dioxane, 1,4-dioxane, dimethoxyethane (DME), dimethyl sulfoxide, diethyl ether, methyl diglyme, acetonitrile, benzonitrile, tetrahydrofuran, sulfolane, and sultone can be used, or two or more of these solvents can be used in an appropriate combination in an appropriate ratio.

The use of one or more ionic liquids (room temperature molten salts) that are less likely to burn and volatize as the solvent of the electrolyte solution can prevent a secondary battery from exploding or catching fire even when the secondary battery internally shorts out or the internal temperature increases owing to overcharge or the like. An ionic liquid contains a cation and an anion, specifically, an organic cation and an anion. Examples of the organic cation used for the electrolyte solution include aliphatic onium cations such as a quaternary ammonium cation, a tertiary sulfonium cation, and a quaternary phosphonium cation, and aromatic cations such as an imidazolium cation and a pyridinium cation. Examples of the anion used for the electrolyte solution include a monovalent amide-based anion, a monovalent methide-based anion, a fluorosulfonate anion, a perfluoroalkylsulfonate anion, a tetrafluoroborate anion, a perfluoroalkylborate anion, a hexafluorophosphate anion, and a perfluoroalkylphosphate anion.

As an electrolyte dissolved in the above-described solvent, one of lithium salts such as LiPF₆, LiClO₄, LiAsF₆, LiBF₄, LiAlCl₄, LiSCN, LiBr, LiI, Li₂SO₄, Li₂B₁₀Cl₁₀, Li₂Bi₂Cl₁₂, LiCF₃SO₃, LiC₄F₉SO₃, LiC(CF₃SO₂)₃, LiC(C₂F₅SO₂)₃, LiN(CF₃SO₂)₂, LiN(C₄F₉SO₂) (CF₃SO₂), and LiN(C₂F₅SO₂)₂ can be used, or two or more of these lithium salts can be used in an appropriate combination in an appropriate ratio.

The electrolyte solution used for a secondary battery is preferably highly purified and contains small numbers of dust particles and elements other than the constituent elements of the electrolyte solution (hereinafter, also simply referred to as impurities). Specifically, the weight ratio of impurities to the electrolyte solution is less than or equal to 1%, preferably less than or equal to 0.1%, and further preferably less than or equal to 0.01%.

Furthermore, an additive agent such as vinylene carbonate, propane sultone (PS), tert-butylbenzene (TBB), fluoroethylene carbonate (FEC), lithium bis(oxalate)borate (LiBOB), or a dinitrile compound such as succinonitrile or adiponitrile may be added to the electrolyte solution. The concentration of a material to be added in the whole solvent is, for example, higher than or equal to 0.1 wt % and lower than or equal to 5 wt %.

A polymer gelled electrolyte obtained in such a manner that a polymer is swelled with an electrolyte solution may be used.

When a polymer gel electrolyte is used, safety against liquid leakage and the like is improved. Furthermore, a secondary battery can be thinner and more lightweight.

As a polymer that undergoes gelation, a silicone gel, an acrylic gel, an acrylonitrile gel, a polyethylene oxide-based gel, a polypropylene oxide-based gel, a fluorine-based polymer gel, or the like can be used.

Examples of the polymer include a polymer having a polyalkylene oxide structure, such as polyethylene oxide (PEO); PVDF; polyacrylonitrile; and a copolymer containing any of them. For example, PVDF-HFP, which is a copolymer of PVDF and hexafluoropropylene (HFP) can be used. The formed polymer may be porous.

Instead of the electrolyte solution, a solid electrolyte including an inorganic material such as a sulfide-based inorganic material or an oxide-based inorganic material, or a solid electrolyte including a high-molecular material such as a PEO (polyethylene oxide)-based high-molecular material may be used. When the solid electrolyte is used, a separator and a spacer are not necessary. Furthermore, the battery can be entirely solidified; therefore, there is no possibility of liquid leakage and thus the safety of the battery is dramatically increased.

### [Separator]

The secondary battery preferably includes a separator. As a separator, for example, paper; nonwoven fabric; glass fiber; ceramics; or synthetic fiber containing nylon (polyamide), vinylon (polyvinyl alcohol-based fiber), polyester, acrylic, polyolefin, or polyurethane can be used. A separator is preferably formed to have an envelope-like shape to wrap one of the positive electrode and the negative electrode.

A separator may have a multilayer structure. For example, an organic material film such as polypropylene or polyethylene can be coated with a ceramic-based material, a fluorine-based material, a polyamide-based material, a mixture thereof, or the like. Examples of the ceramic-based material include aluminum oxide particles and silicon oxide particles. Examples of the fluorine-based material include PVDF and polytetrafluoroethylene. Examples of the polyamide-based material include nylon and aramid (meta-based aramid and para-based aramid).

Deterioration of the separator in charge and discharge at high voltage can be suppressed and thus the reliability of the secondary battery can be improved because oxidation resistance is improved when a separator is coated with the ceramic-based material. In addition, when the separator is coated with the fluorine-based material, the separator is easily brought into close contact with an electrode, resulting in high output characteristics. When the separator is coated with the polyamide-based material, in particular, aramid, the safety of the secondary battery is improved because heat resistance is improved.

For example, both surfaces of a polypropylene film may be coated with a mixed material of aluminum oxide and aramid. A surface of the polypropylene film that is in contact with the positive electrode may be coated with the mixed material of aluminum oxide and aramid, and a surface of the polypropylene film that is in contact with the negative electrode may be coated with the fluorine-based material.

With the use of a separator having a multilayer structure, the capacity per volume of the secondary battery can be increased because the safety of the secondary battery can be maintained even when the total thickness of the separator is small.

### [Exterior Body]

As an exterior body included in the secondary battery, a metal material such as aluminum or a resin material can be used, for example. An exterior body in the form of a film can also be used. As the film, for example, a film having a three-layer structure in which a highly flexible metal thin film of aluminum, stainless steel, copper, nickel, or the like is provided over a film formed of a material such as polyethylene, polypropylene, polycarbonate, ionomer, or polyamide, and an insulating synthetic resin film of a polyamide-based resin, a polyester-based resin, or the like is provided as the outer surface of the exterior body over the metal thin film can be used.

### [Charging and Discharging Methods]

The secondary battery can be charged and discharged in the following manner, for example.

### <<CC Charging>>

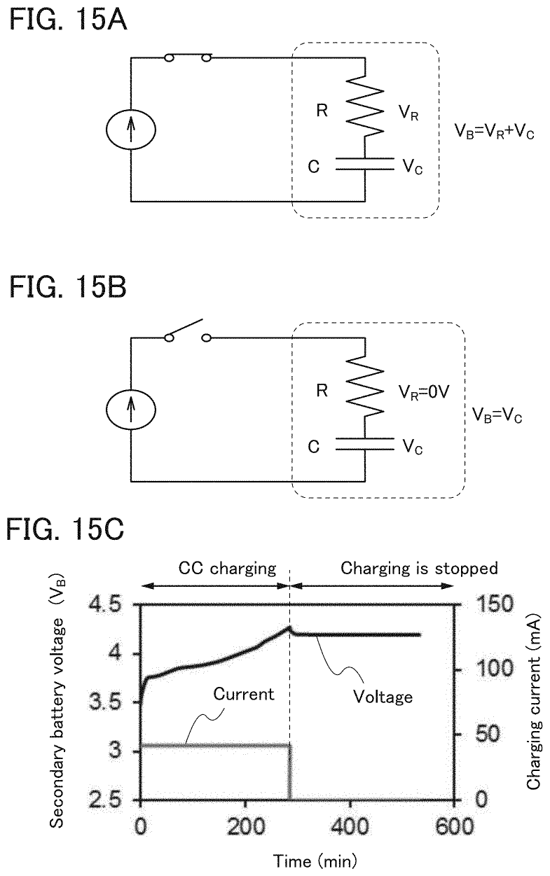

First, CC charging is described as a charging method. CC charging is a charging method in which a constant current is made to flow to a secondary battery in the whole charging period and charging is stopped when the voltage reaches a predetermined voltage. A secondary battery is assumed to be an equivalent circuit with internal resistance R and secondary battery capacitance C as shown in FIG. 15A. In this case, a secondary battery voltage V_{B} is the sum of a voltage V_{R} applied to the internal resistance R and a voltage V_{C} applied to the secondary battery capacitance C.

While CC charging is performed, a switch is on as shown in FIG. 15A, so that a constant current I flows to the secondary battery. During this period, the current I is constant; thus, in accordance with the Ohm's law (V_{R}=R×I), the voltage V_{R} applied to the internal resistance R is also constant. In contrast, the voltage V_{C} applied to the secondary battery capacitance C increases over time. Accordingly, the secondary battery voltage V_{B} increases over time.

When the secondary battery voltage V_{B} reaches a predetermined voltage, e.g., 4.3 V, charging is stopped. When CC charging is stopped, the switch is turned off as shown in FIG. 15B, and the current I becomes 0. Thus, the voltage V_{R} applied to the internal resistance R becomes 0 V. Consequently, the secondary battery voltage V_{B} is decreased.

FIG. 15C shows an example of the secondary battery voltage V_{B} and charging current during a period in which CC charging is performed and after CC charging is stopped. The secondary battery voltage V_{B} increases while CC charging is performed, and slightly decreases after the CC charging is stopped.

### <<CCCV Charge>>

Next, CCCV charging, which is a charging method different from the above-described method, is described. CCCV charging is a charging method in which CC charging is performed until the voltage reaches a predetermined voltage and then CV (constant voltage) charging is performed until the amount of current flow becomes small, specifically, a termination current value.

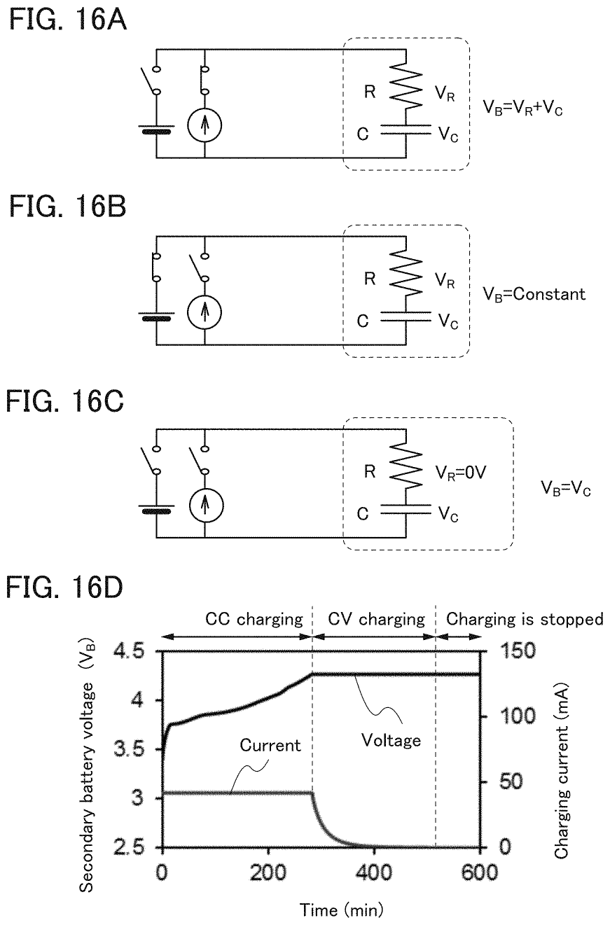

While CC charging is performed, a switch of a constant current power source is on and a switch of a constant voltage power source is off as shown in FIG. 16A, so that the constant current I flows to the secondary battery. During this period, the current I is constant; thus, in accordance with the Ohm's law (V_{R}=R×I), the voltage V_{R} applied to the internal resistance R is also constant. In contrast, the voltage V_{C} applied to the secondary battery capacitance C increases over time. Accordingly, the secondary battery voltage V_{B} increases over time.

When the secondary battery voltage V_{B} reaches a predetermined voltage, e.g., 4.3 V, CC charging is changed to CV charging. While CV charging is performed, the switch of the constant voltage power source is on and the switch of the constant current power source is off as shown in FIG. 16B; thus, the secondary battery voltage V_{B} is constant. In contrast, the voltage V_{C} applied to the secondary battery capacitance C increases over time. Since V_{B}=V_{R} V_{C} is satisfied, the voltage V_{R} applied to the internal resistance R decreases over time. As the voltage V_{R} applied to the internal resistance R decreases, the current I flowing to the secondary battery also decreases in accordance with the Ohm's law (V_{R}=R×I).

When the current I flowing to the secondary battery becomes a predetermined current, e.g., approximately 0.01 C, the charging is stopped. When CCCV charging is stopped, all the switches are turned off as shown in FIG. 16C, so that the current I becomes 0. Thus, the voltage V_{R} applied to the internal resistance R becomes 0 V. However, the voltage V_{R} applied to the internal resistance R becomes sufficiently small by CV charging; thus, even when a voltage drop no longer occurs in the internal resistance R, the secondary battery voltage V_{B} hardly decreases.

FIG. 16D shows an example of the secondary battery voltage V_{B} and charge current while CCCV charging is performed and after the CCCV charging is stopped. It is shown that the secondary battery voltage V_{B} hardly decreases even after CCCV charging is stopped.

### <<CC Discharging>>

Next, CC discharging, which is a discharging method, is described. CC discharging is a discharging method in which a constant current is made to flow from the secondary battery in the whole discharging period, and discharging is stopped when the secondary battery voltage V_{B} reaches a predetermined voltage, e.g., 2.5 V.

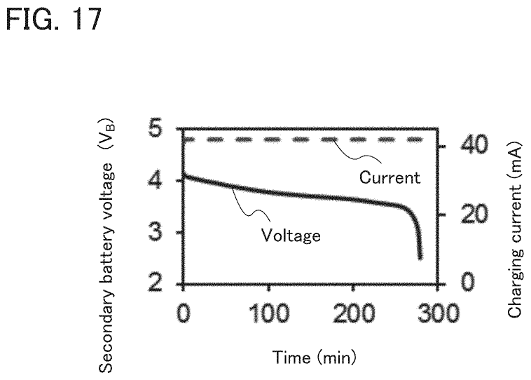

FIG. 17 shows an example of the secondary battery voltage V_{B} and a discharge current while CC discharging is performed. As discharging proceeds, the secondary battery voltage V_{B} decreases.

Next, a discharging rate and a charging rate are described. The discharging rate refers to the relative ratio of a discharging current to a battery capacity and is expressed with a unit C. A current corresponding to 1 C in a battery with a rated capacity X (Ah) is X (A). The case where discharging is performed at a current of 2X (A) is rephrased as to perform discharging at 2 C, and the case where discharging is performed at a current of X/5 (A) is rephrased as to perform discharging at 0.2 C. The same applies to the charging rate; the case where charging is performed at a current of 2X (A) is rephrased as to perform charging at 2 C, and the case where charging is performed at a current of X/5 (A) is rephrased as to perform charging at 0.2 C.

The above embodiments show a charging voltage when a lithium metal is used as a counter electrode. When graphite is used as the negative electrode of the secondary battery, for example, charging can be performed using a charging voltage which is approximately 0.1 V lower than the charging voltage when lithium metal is used as a negative electrode.

In this specification, in the case where lithium metal is used as a counter electrode, for example, when a graphite negative electrode is used in the secondary battery, the charging voltage can be lower than the charging voltage in which lithium metal is used as a negative electrode by greater than or equal to 0.05 V and less than or equal to 0.3 V, preferably by 0.1 V.

### <<Charge-and-Discharge Cycle Performance>>

In the secondary battery of one embodiment of the present invention, decrease in discharge capacity due to charge-and-discharge cycles can be suppressed. In particular, in the secondary battery of one embodiment of the present invention, decrease in discharge capacity due to charge-and-discharge cycles conducted with a high charging voltage can be suppressed.

The discharge capacity of the positive electrode of one embodiment of the present invention becomes, in charge-and-discharge cycles repeating CCCV charging and CC discharging using lithium metal as a counter electrode, more than or equal to 75% of the discharge capacity at the first charge-and-discharge cycle, preferably more than or equal to 80% thereof, more preferably more than or equal to 85% thereof, further more preferably more than or equal to 90% thereof after the 30th to the 150th charge-and-discharge cycles; the maximum charging voltage is more than or equal to 4.4 V, preferably greater than or equal to 4.5 V and less than or equal to 5 V, further preferably greater than or equal to 4.6 V and less than or equal to 5 V; the maximum voltage is the voltage with lithium metal as a counter electrode; the rate of CC charging is, for example, greater than or equal to 0.05 C and less than or equal to 3 C, preferably greater than or equal to 0.1 C and less than or equal to 2 C; a termination current of CV charging is, for example, greater than or equal to 0.001 C and less than or equal to 0.05 C; the rate of CC discharging is, for example, greater than or equal to 0.01 C and less than or equal to 3 C; the measurement temperature is greater than or equal to 10° C. and less than or equal to 50° C.

Alternatively, the secondary battery of one embodiment of the present invention includes the positive electrode of one embodiment of the present invention and a negative electrode; the negative electrode includes graphite; the discharge capacity of the positive electrode of one embodiment of the present invention becomes, in charge-and-discharge cycles repeating CCCV charging and CC discharging, more than or equal to 75% of the discharge capacity at the first charge-and-discharge cycle, preferably more than or equal to 80% thereof, more preferably more than or equal to 85% thereof, further more preferably more than or equal to 90% thereof after the 30th to the 150th charge-and-discharge cycles; the maximum charging voltage is more than or equal to 4.3 V, preferably greater than or equal to 4.4 V and less than or equal to 4.9 V, further preferably greater than or equal to 4.5 V and less than or equal to 4.9 V; the maximum voltage is the voltage with a lithium metal as a counter electrode; the rate of CC charging is, for example, greater than or equal to 0.05 C and less than or equal to 3 C, preferably greater than or equal to 0.1 C and less than or equal to 2 C; a termination current of CV charging is, for example, greater than or equal to 0.001 C and less than or equal to 0.05 C; the rate of CC discharging is, for example, greater than or equal to 0.01 C and less than or equal to 3 C; the measurement temperature is greater than or equal to 10° C. and less than or equal to 50° C.

In the above, after the 30th to the 150th charge-and-discharge cycles, the discharge capacity is more than or equal to 1.3 times, preferably more than or equal to 1.45 times, further preferably more than or equal to 1.6 times higher than that of the comparative secondary battery including a material of a conventional example as a positive electrode active material.

This embodiment can be implemented in appropriate combination with the other embodiments.

### Embodiment 4

In this embodiment, examples of a shape of a secondary battery containing the positive electrode active material 100 described in the above embodiment are described. For the materials used for the secondary battery described in this embodiment, the description of the above embodiment can be referred to.

### [Coin-Type Secondary Battery]

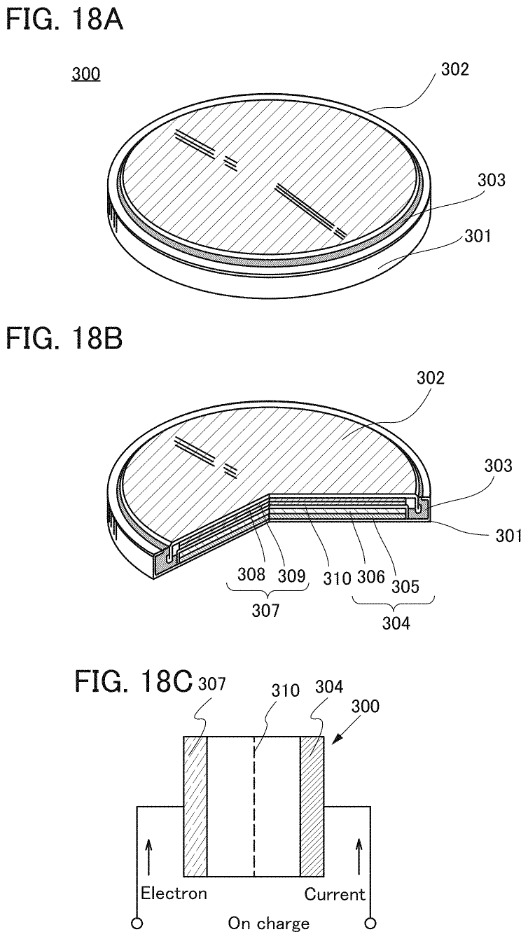

First, an example of a coin-type secondary battery is described. FIG. 18A is an external view of a coin-type (single-layer flat type) secondary battery, and FIG. 18B is a cross-sectional view thereof.

In a coin-type secondary battery 300, a positive electrode can 301 doubling as a positive electrode terminal and a negative electrode can 302 doubling as a negative electrode terminal are insulated from each other and sealed by a gasket 303 made of polypropylene or the like. A positive electrode 304 includes a positive electrode current collector 305 and a positive electrode active material layer 306 provided in contact with the positive electrode current collector 305. A negative electrode 307 includes a negative electrode current collector 308 and a negative electrode active material layer 309 provided in contact with the negative electrode current collector 308.

Note that only one surface of each of the positive electrode 304 and the negative electrode 307 used for the coin-type secondary battery 300 is provided with an active material layer.

For the positive electrode can 301 and the negative electrode can 302, a metal having corrosion resistance to an electrolyte solution, such as nickel, aluminum, or titanium, an alloy of such a metal, or an alloy of such a metal and another metal (e.g., stainless steel) can be used. The positive electrode can 301 and the negative electrode can 302 are preferably covered with nickel, aluminum, or the like to prevent corrosion due to an electrolyte solution. The positive electrode can 301 and the negative electrode can 302 are electrically connected to the positive electrode 304 and the negative electrode 307, respectively.

The negative electrode 307, the positive electrode 304, and a separator 310 are immersed in the electrolyte solution. Then, as shown in FIG. 18B, the positive electrode 304, the separator 310, the negative electrode 307, and the negative electrode can 302 are stacked in this order with the positive electrode can 301 positioned at the bottom, and the positive electrode can 301 and the negative electrode can 302 are subjected to pressure bonding with the gasket 303 located therebetween. In such a manner, the coin-type secondary battery 300 can be made.

When the positive electrode active material described in the above embodiment is used in the positive electrode 304, the coin-type secondary battery 300 with high capacity and excellent cycle performance can be obtained.

Here, a current flow in charging a secondary battery is described with reference to FIG. 18C. When a secondary battery using lithium is regarded as a closed circuit, lithium ions transfer in the same direction with a current flow. Note that in the secondary battery using lithium, an anode and a cathode change places in charge and discharge, and an oxidation reaction and a reduction reaction occur on the corresponding sides; hence, an electrode with a high reaction potential is called a positive electrode and an electrode with a low reaction potential is called a negative electrode. For this reason, in this specification, the positive electrode is referred to as a “positive electrode” or a “+ electrode (plus electrode)” and the negative electrode is referred to as a “negative electrode” or a “− electrode (minus electrode)” in any of the case where charging is performed, the case where discharging is performed, the case where a reverse pulse current is made to flow, and the case where charging current is made to flow. The use of terms such as anode (positive electrode) and cathode (negative electrode) related to oxidation reaction and reduction reaction might cause confusion because the anode and the cathode are reversed in charging and in discharging. Thus, the terms anode and cathode are not used in this specification. If the term anode or cathode is used, whether it is at the time of charging or discharging is noted and whether it corresponds to a positive electrode or a negative electrode is also noted.

Two terminals in FIG. 18C are connected to a charger, and the secondary battery 300 is charged. As the secondary battery 300 is charged, a potential difference between electrodes increases.

### [Cylindrical Secondary Battery]

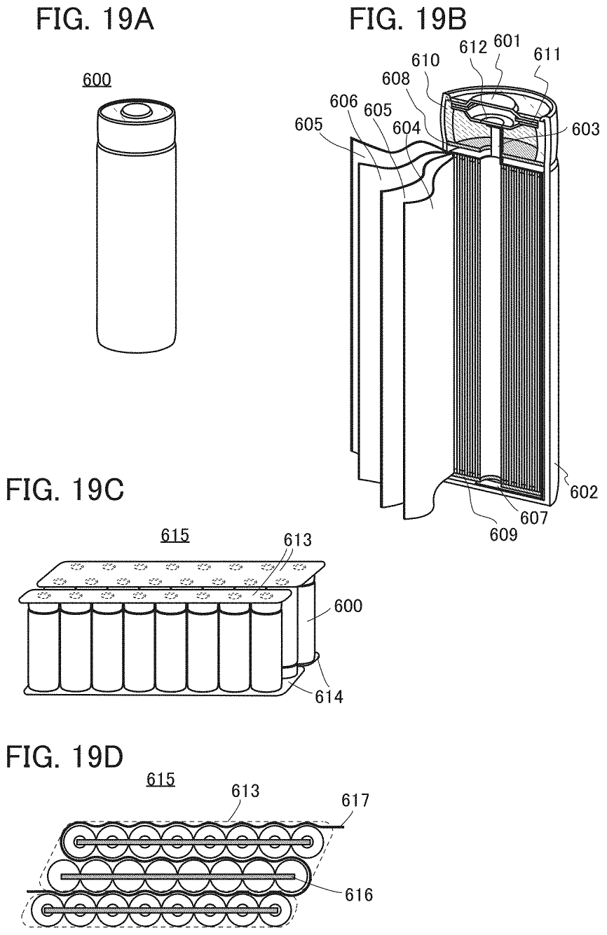

Next, examples of a cylindrical secondary battery are described with reference to FIG. 19A, FIG. 19B, FIG. 19C, and FIG. 19D. An external view of a cylindrical secondary battery 600 is shown in FIG. 19A. FIG. 19B is a schematic cross-sectional view of the cylindrical secondary battery 600. The cylindrical secondary battery 600 includes, as shown in FIG. 19B, a positive electrode cap (battery lid) 601 on the top surface and a battery can (outer can) 602 on the side and bottom surfaces. The positive electrode cap and the battery can (outer can) 602 are insulated from each other by a gasket (insulating packing) 610.

Inside the battery can 602 having a hollow cylindrical shape, a battery element in which a belt-like positive electrode 604 and a belt-like negative electrode 606 are wound with a separator 605 located therebetween is provided. Although not shown, the battery element is wound centering around a center pin. One end of the battery can 602 is closed and the other end thereof is open. As the battery can 602, a metal having a corrosion-resistant property to an electrolyte solution, such as nickel, aluminum, or titanium, an alloy of such a metal, or an alloy of such a metal and another metal (e.g., stainless steel) can be used. Alternatively, the battery can 602 is preferably covered with nickel, aluminum, or the like in order to prevent corrosion due to the electrolyte solution. Inside the battery can 602, the battery element in which the positive electrode, the negative electrode, and the separator are wound is sandwiched between a pair of insulating plates 608 and 609 that face each other. Furthermore, a nonaqueous electrolyte (not shown) is injected inside the battery can 602 provided with the battery element. As the nonaqueous electrolyte, a nonaqueous electrolyte that is similar to that for the coin-type secondary battery can be used.

Since a positive electrode and a negative electrode that are used to a cylindrical storage battery are wound, active materials are preferably formed on both surfaces of a current collector. A positive electrode terminal (positive electrode current collector lead) 603 is connected to the positive electrode 604, and a negative electrode terminal (negative electrode current collector lead) 607 is connected to the negative electrode 606. As both the positive electrode terminal 603 and the negative electrode terminal 607, a metal material such as aluminum can be used. The positive electrode terminal 603 and the negative electrode terminal 607 are resistance-welded to a safety valve mechanism 612 and the bottom of the battery can 602, respectively. The safety valve mechanism 612 is electrically connected to the positive electrode cap 601 through a positive temperature coefficient (PTC) element 611. The safety valve mechanism 612 cuts off electrical connection between the positive electrode cap 601 and the positive electrode 604 when the internal pressure of the battery exceeds a predetermined threshold value. In addition, the PTC element 611 is a thermally sensitive resistor whose resistance increases as temperature rises, and limits the amount of current by increasing the resistance to prevent abnormal heat generation. Barium titanate (BaTiO₃)-based semiconductor ceramics or the like can be used as the PTC element.

As shown in FIG. 19C, a plurality of secondary batteries 600 may be provided between a conductive plate 613 and a conductive plate 614 to form a module 615. The plurality of secondary batteries 600 may be connected in parallel, connected in series, or connected in series after being connected in parallel. With the module 615 including the plurality of secondary batteries 600, large electric power can be extracted.

FIG. 19D is a top view of the module 615. The conductive plate 613 is shown by a dotted line for clarity of the drawing. As shown in FIG. 19D, the module 615 may include a wiring 616 electrically connecting the plurality of secondary batteries 600 with each other. It is possible to provide the conductive plate over the wiring 616 to overlap with each other. In addition, a temperature control device 617 may be provided between the plurality of secondary batteries 600. The secondary batteries 600 can be cooled with the temperature control device 617 when overheated, whereas the secondary batteries 600 can be heated with the temperature control device 617 when cooled too much. Thus, the performance of the module 615 is less likely to be influenced by the outside temperature. A heating medium included in the temperature control device 617 preferably has an insulating property and incombustibility.

When the positive electrode active material described in the above embodiment is used in the positive electrode 604, the cylindrical secondary battery 600 with high capacity and excellent cycle performance can be obtained.

### Structure Examples of Secondary Battery

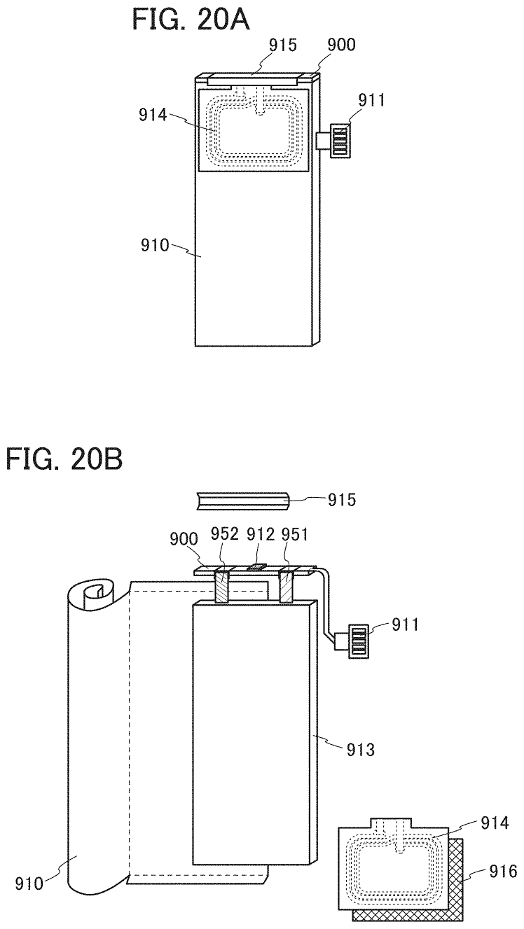

Other structure examples of secondary batteries are described using FIG. 20 to FIG. 24.

FIG. 20A and FIG. 20B are external views of a battery pack. The battery pack includes a circuit board 900 and a secondary battery 913. A label 910 is attached to the secondary battery 913. In addition, as shown in FIG. 20B, the secondary battery 913 includes a terminal 951 and a terminal 952.

The circuit board 900 includes a circuit 912. The terminals 911 are connected to the terminal 951, the terminal 952, an antenna 914, an antenna 915, and the circuit 912 via the circuit board 900. Note that a plurality of terminals 911 serving as a control signal input terminal, a power supply terminal, and the like may be provided.

The circuit 912 may be provided on the rear surface of the circuit board 900. Note that the shapes of the antenna 914 and the antenna 915 are not limited to coil shapes, and may be linear shapes or plate shapes, for example. An antenna such as a planar antenna, an aperture antenna, a traveling-wave antenna, an EH antenna, a magnetic-field antenna, or a dielectric antenna may be used.

Alternatively, the antenna 914 may be a flat-plate conductor. This flat-plate conductor can serve as one of conductors for electric field coupling. That is, the antenna 914 can serve as one of two conductors of a capacitor. Thus, electric power can be transmitted and received not only by an electromagnetic field or a magnetic field but also by an electric field.

The battery pack includes a layer 916 between the secondary battery 913 and the antenna 914. The layer 916 has a function of preventing an influence on an electromagnetic field by the secondary battery 913, for example. As the layer 916, for example, a magnetic body can be used.

Note that the structure of the secondary battery is not limited to that in FIG. 20A or FIG. 20B.

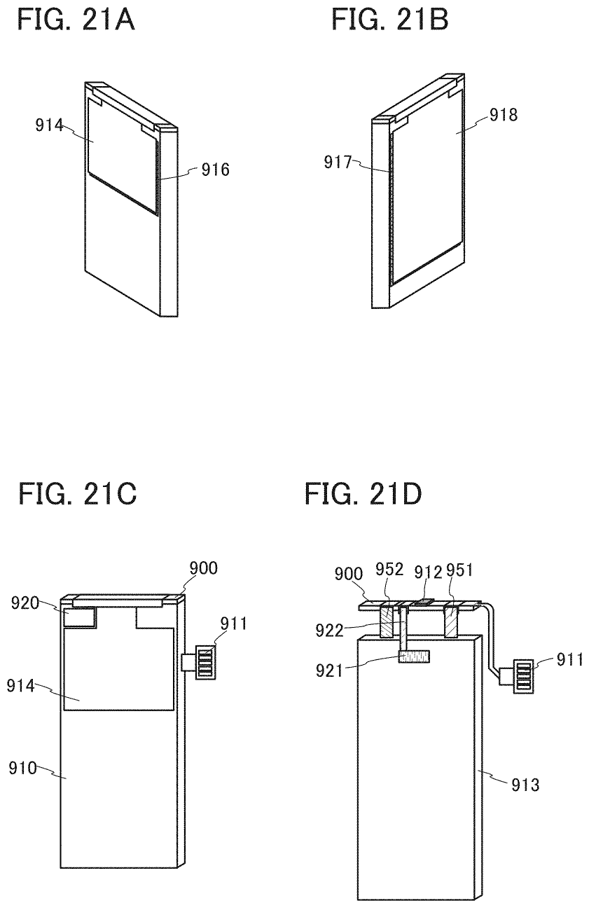

For example, as shown in FIG. 21A and FIG. 21B, opposing surfaces of the battery pack shown in FIG. 20A and FIG. 20B may be provided with antennas. FIG. 21A is an external view seen from one side of the opposing surfaces, and FIG. 21B is an external view seen from the other side of the opposing surfaces. For portions similar to those in FIG. 20A and FIG. 20B, descriptions on the battery pack shown in FIG. 20A and FIG. 20B can be referred to as appropriate.

As shown in FIG. 21A, the antenna 914 is provided on one of the opposing surfaces of the secondary battery 913 with the layer 916 located therebetween, and as shown in FIG. 21B, an antenna 918 is provided on the other of the opposing surfaces of the secondary battery 913 with a layer 917 located therebetween. The layer 917 has a function of preventing an influence on an electromagnetic field by the secondary battery 913, for example. As the layer 917, for example, a magnetic body can be used.

With the above structure, both of the antenna 914 and the antenna 918 can be increased in size. The antenna 918 has a function of communicating data with an external device, for example. An antenna with a shape that can be used as the antenna 914, for example, can be used as the antenna 918. As a system for communication using the antenna 918 between the secondary battery and another device, a communication method that can be used between the secondary battery and another device, such as near field communication (NFC), can be employed.

Alternatively, as shown in FIG. 21C, the battery pack shown in FIG. 20A and FIG. 20B may be provided with a display device 920. The display device 920 is electrically connected to the terminal 911. Note that the label 910 is not necessarily provided in a portion where the display device 920 is provided. For portions similar to those in FIG. 20A and FIG. 20B, descriptions of the battery pack shown in FIG. 20A and FIG. 20B can be referred to as appropriate.

The display device 920 can display, for example, an image showing whether charging is being carried out, an image showing the amount of stored power, or the like. As the display device 920, an electronic paper, a liquid crystal display device, an electroluminescent (EL) display device, or the like can be used. For example, the use of an electronic paper can reduce power consumption of the display device 920.

Alternatively, as shown in FIG. 21D, the battery pack shown in FIG. 20A and FIG. 20B may be provided with a sensor 921. The sensor 921 is electrically connected to the terminal 911 via a terminal 922. For portions similar to the secondary batteries in FIG. 20A and FIG. 20B, descriptions of the battery pack shown in FIG. 20A and FIG. 20B can be referred to as appropriate.

The sensor 921 has a function of measuring, for example, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays. With the sensor 921, for example, data on an environment (e.g., temperature) where the secondary battery is placed can be acquired and stored in a memory inside the circuit 912.

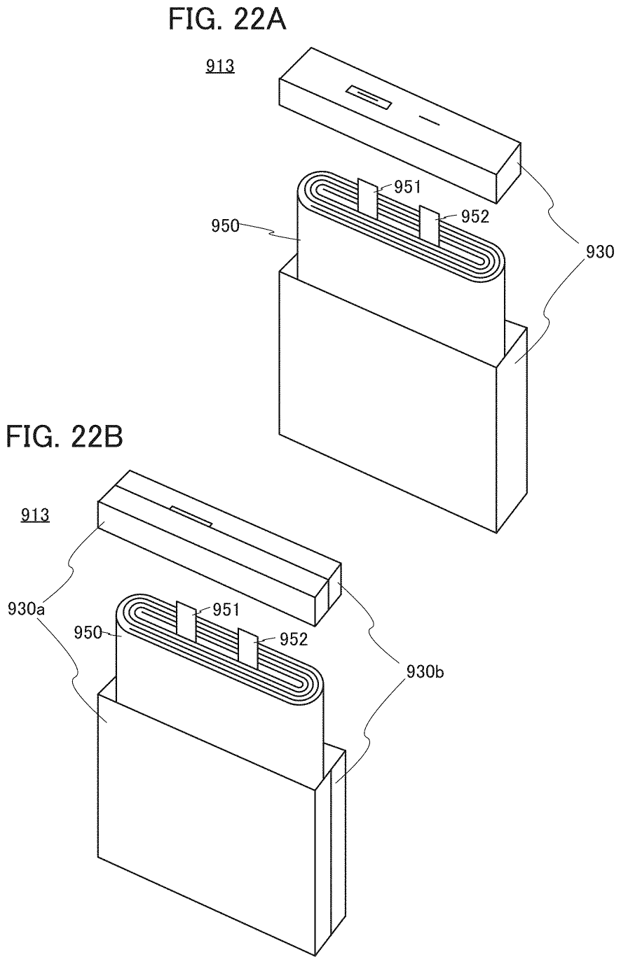

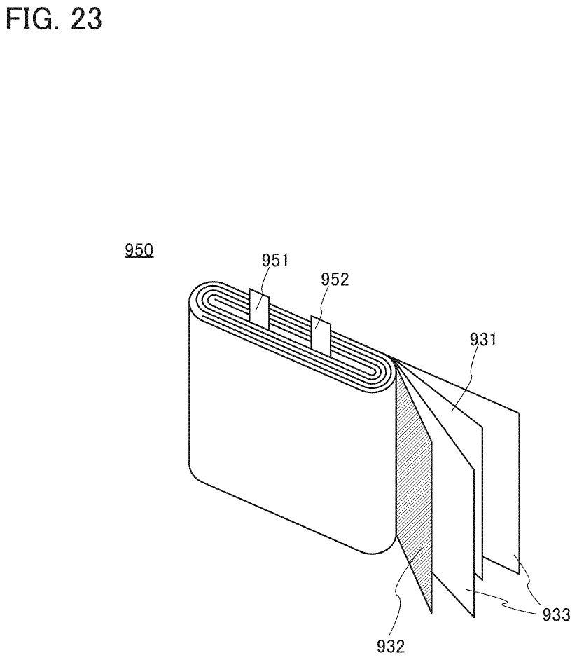

Furthermore, structure examples of the secondary battery 913 are described using FIG. 22 and FIG. 23.

The secondary battery 913 shown in FIG. 22A includes a wound body 950 provided with the terminal 951 and the terminal 952 inside a housing 930. The wound body 950 is soaked with an electrolyte solution inside the housing 930. The terminal 952 is in contact with the housing 930. An insulator or the like inhibits contact between the terminal 951 and the housing 930. In FIG. 22A, the housing 930 divided into two pieces is shown for convenience; in an actual structure, the wound body 950 is covered with the housing 930 and the terminal 951 and the terminal 952 extend to the outside of the housing 930. As the housing 930, a metal material (e.g., aluminum) or a resin material can be used.

As shown in FIG. 22B, the housing 930 shown in FIG. 22A may be formed using a plurality of materials. For example, in the secondary battery 913 in FIG. 22B, a housing 930a and a housing 930b are bonded to each other, and the wound body 950 is provided in a region surrounded by the housing 930a and the housing 930b.

As the housing 930a, an insulating material such as an organic resin can be used. In particular, when a material such as an organic resin is used for the side on which an antenna is formed, blocking of an electric field from the secondary battery 913 can be inhibited. When an electric field is not significantly blocked by the housing 930a, an antenna such as the antenna 914 and the antenna 915 may be provided inside the housing 930a. As the housing 930b, a metal material can be used, for example.

In addition, FIG. 23 shows a structure of the wound body 950. The wound body 950 includes a negative electrode 931, a positive electrode 932, and separators 933. The wound body 950 is obtained by winding a sheet of a stack in which the negative electrode 931 overlaps with the positive electrode 932 with the separator 933 provided therebetween. Note that a plurality of stacks each including the negative electrode 931, the positive electrode 932, and the separator 933 may be stacked.

The negative electrode 931 is connected to the terminal 911 shown in FIG. 20 via one of the terminal 951 and the terminal 952. The positive electrode 932 is connected to the terminal 911 shown in FIG. 20 through the other of the terminal 951 and the terminal 952.

When the positive electrode active material described in the above embodiment is used in the positive electrode 932, the secondary battery 913 with high capacity and excellent cycle performance can be obtained.

### [Laminated Secondary Battery]

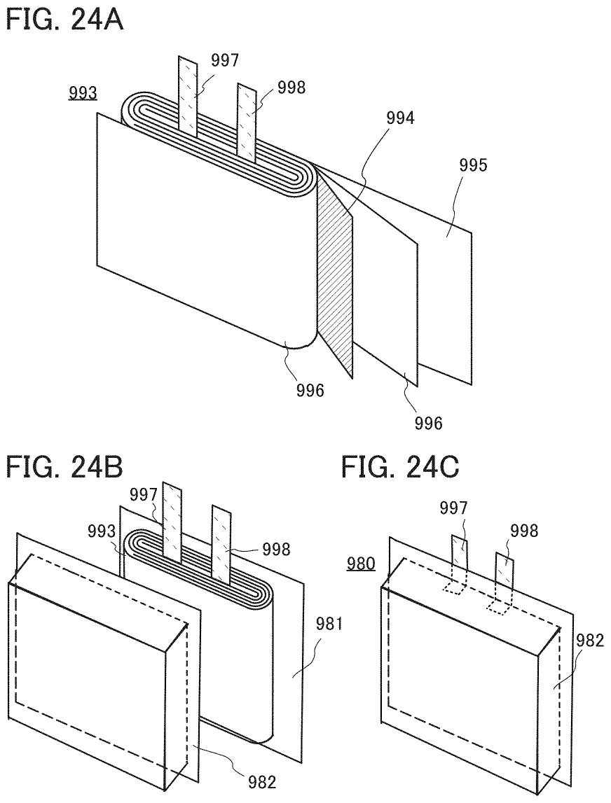

Next, examples of a laminated secondary battery are described with reference to FIG. 24 to FIG. 30. When the laminated secondary battery has flexibility and is used in an electronic device at least part of which is flexible, the secondary battery can be bent as the electronic device is bent.

A laminated secondary battery 980 is described using FIG. 24. The laminated secondary battery 980 includes a wound body 993 shown in FIG. 24A. The wound body 993 includes a negative electrode 994, a positive electrode 995, and separators 996. Like the wound body 950 shown in FIG. 23, the wound body 993 is a wound body where the negative electrode 994 is stacked to overlap with the positive electrode 995 with the separator 996 sandwiched therebetween and the sheet of the stack is wound.

Note that the number of stacks each including the negative electrode 994, the positive electrode 995, and the separator 996 may be determined as appropriate depending on required capacity and element volume. The negative electrode 994 is connected to a negative electrode current collector (not shown) through one of a lead electrode 997 and a lead electrode 998. The positive electrode 995 is connected to a positive electrode current collector (not shown) through the other of the lead electrode 997 and the lead electrode 998.

As shown in FIG. 24B, the wound body 993 is packed in a space formed by bonding a film 981 and a film 982 having a depressed portion that serve as exterior bodies by thermocompression bonding or the like, whereby the secondary battery 980 shown in FIG. 24C can be formed. The wound body 993 includes the lead electrode 997 and the lead electrode 998, and is soaked with an electrolyte solution inside a space surrounded by the film 981 and the film 982 having a depressed portion.

As the film 981 and the film 982 having a depressed portion, a metal material such as aluminum or a resin material can be used, for example. With the use of a resin material as the film 981 and the film 982 having a depressed portion, the film 981 and the film 982 having a depressed portion can be changed in their forms when external force is applied; thus, a flexible storage battery can be formed.

Although FIG. 24B and FIG. 24C show an example where a space is formed by two films, the wound body 993 may be placed in a space formed by bending one film.

When the positive electrode active material described in the above embodiment is used in the positive electrode 995, the secondary battery 980 with high capacity and excellent cycle performance can be obtained.

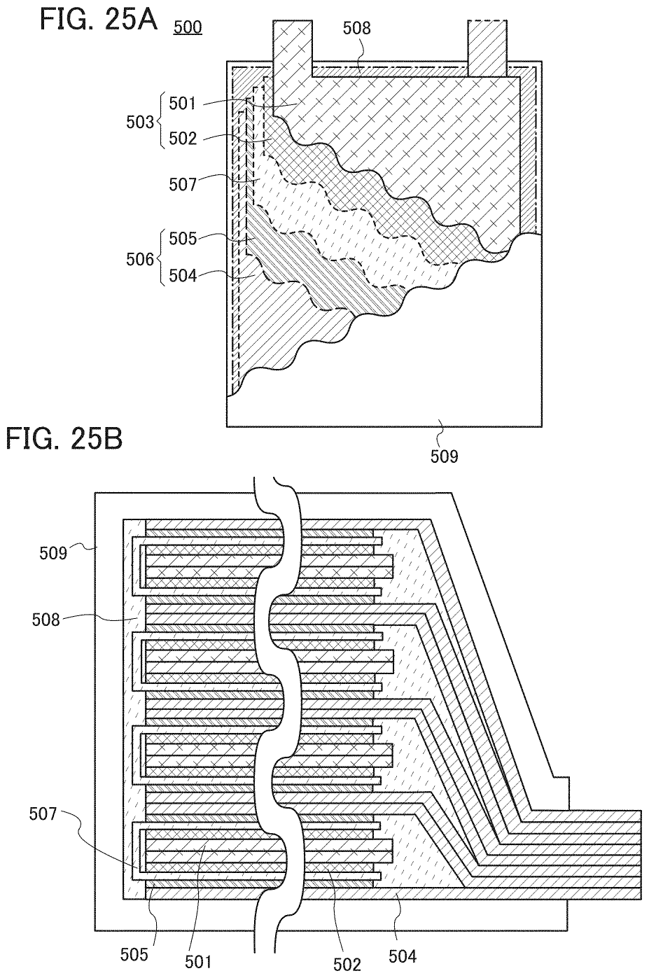

In FIG. 24B and FIG. 24C, an example in which the secondary battery 980 includes a wound body in a space formed by films serving as exterior bodies is described; however, as shown in FIG. 25A and FIG. 25B, a secondary battery may include a plurality of strip-shaped positive electrodes, a plurality of strip-shaped separators, and a plurality of strip-shaped negative electrodes in a space formed by films serving as exterior bodies, for example.

A laminated secondary battery 500 shown in FIG. 25A includes a positive electrode 503 including a positive electrode current collector 501 and a positive electrode active material layer 502, a negative electrode 506 including a negative electrode current collector 504 and a negative electrode active material layer 505, a separator 507, an electrolyte solution 508, and an exterior body 509. The separator 507 is provided between the positive electrode 503 and the negative electrode 506 in the exterior body 509. The exterior body 509 is filled with the electrolyte solution 508. The electrolyte solution described in Embodiment 2 can be used as the electrolyte solution 508.

In the laminated secondary battery 500 shown in FIG. 25A, the positive electrode current collector 501 and the negative electrode current collector 504 also serve as terminals for electrical contact with the outside. For this reason, the positive electrode current collector 501 and the negative electrode current collector 504 may be arranged so that part of the positive electrode current collector 501 and part of the negative electrode current collector 504 are exposed to the outside of the exterior body 509. Alternatively, a lead electrode and the positive electrode current collector 501 or the negative electrode current collector 504 may be bonded to each other by ultrasonic welding, and instead of the positive electrode current collector 501 and the negative electrode current collector 504, the lead electrode may be exposed to the outside of the exterior body 509.

As the exterior body 509 of the laminated secondary battery 500, for example, a laminate film having a three-layer structure can be employed in which a highly flexible metal thin film of aluminum, stainless steel, copper; nickel, or the like is provided over a film formed of a material such as polyethylene, polypropylene, polycarbonate, ionomer, or polyamide, and an insulating synthetic resin film of a polyamide-based resin, a polyester-based resin, or the like is provided over the metal thin film as the outer surface of the exterior body.

FIG. 25B shows an example of a cross-sectional structure of the laminated secondary battery 500. FIG. 25A shows an example in which only two current collectors are included for simplicity; an actual battery includes a plurality of electrode layers as shown in FIG. 25B.

In FIG. 25B, the number of electrode layers is 16, for example. The laminated secondary battery 500 has flexibility even though including 16 electrode layers. FIG. 25B shows a structure including 8 layers of negative electrode current collectors 504 and 8 layers of positive electrode current collectors 501, i.e., 16 layers in total. Note that FIG. 25B shows a cross section of the negative electrode extraction portion, and the 8 layers of the negative electrode current collectors 504 are bonded to each other by ultrasonic welding. The number of electrode layers is not limited to 16, and may be more than 16 or less than 16. With a large number of electrode layers, the secondary battery can have high capacity. With a small number of electrode layers, the secondary battery can have small thickness and high flexibility.

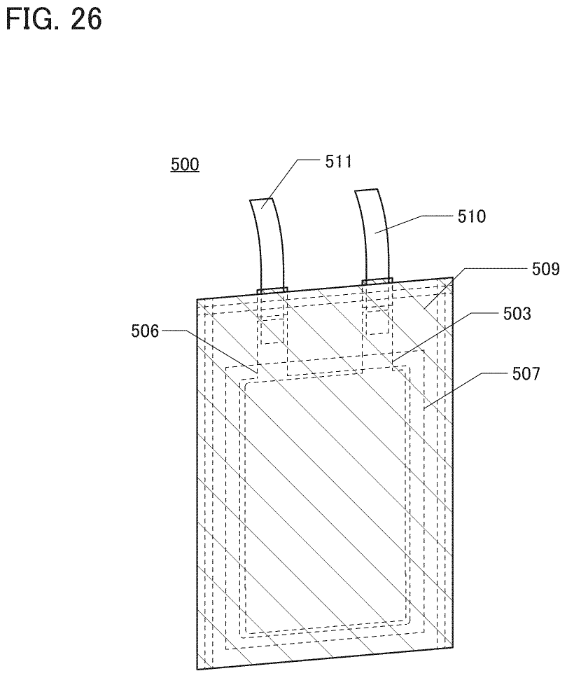

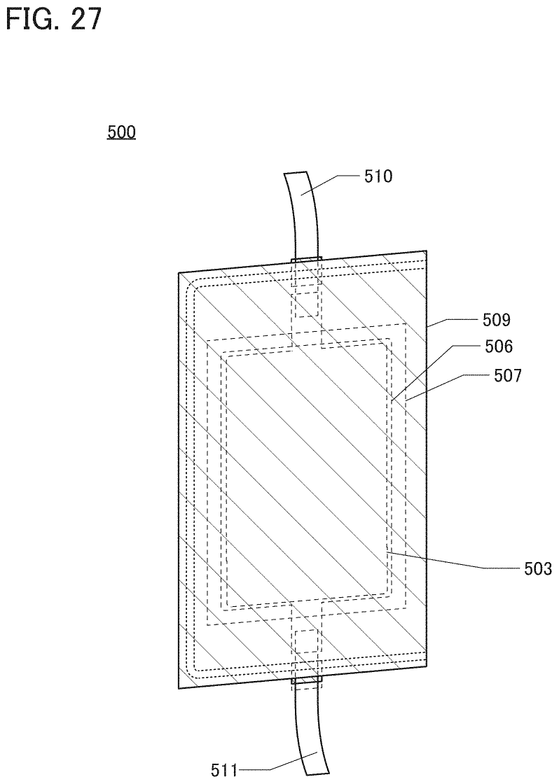

FIG. 26 and FIG. 27 each show examples of the external views of the laminated secondary battery 500. In FIG. 26 and FIG. 27, the laminated secondary battery 500 includes the positive electrode 503, the negative electrode 506, the separator 507, the exterior body 509, a positive electrode lead electrode 510, and a negative electrode lead electrode 511.

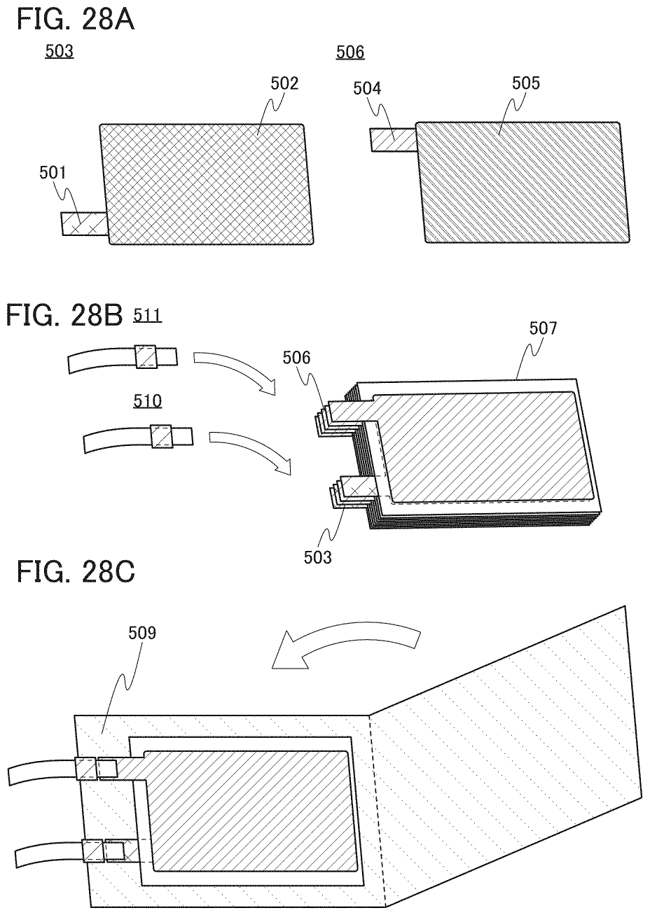

FIG. 28A shows external views of the positive electrode 503 and the negative electrode 506. The positive electrode 503 includes the positive electrode current collector 501, and the positive electrode active material layer 502 is formed on a surface of the positive electrode current collector 501. The positive electrode 503 also includes a region where the positive electrode current collector 501 is partly exposed (hereinafter, referred to as a tab region). The negative electrode 506 includes the negative electrode current collector 504, and the negative electrode active material layer 505 is formed on a surface of the negative electrode current collector 504. The negative electrode 506 also includes a region where the negative electrode current collector 504 is partly exposed, that is, a tab region. The areas and the shapes of the tab regions included in the positive electrode and the negative electrode are not limited to those shown in FIG. 28A.

### [Method for Making Laminated Secondary Battery]

Here, an example of a method for making the laminated secondary battery whose external view is shown in FIG. 26 is described with reference to FIG. 28B and FIG. 28C.

First, the negative electrode 506, the separator 507, and the positive electrode 503 are stacked. FIG. 28B shows a stack including the negative electrode 506, the separator 507, and the positive electrode 503. The secondary battery described here as an example includes 5 negative electrodes and 4 positive electrodes. Next, the tab regions of the positive electrodes 503 are bonded to each other, and the tab region of the positive electrode on the outermost surface and the positive electrode lead electrode 510 are bonded to each other. The bonding can be performed by ultrasonic welding, for example. Similarly, the tab regions of the negative electrodes 506 are bonded to each other, and the tab region of the negative electrode on the outermost surface and the negative electrode lead electrode 511 are bonded to each other.

After that, the negative electrode 506, the separator 507, and the positive electrode 503 are placed over the exterior body 509.

Subsequently, the exterior body 509 is folded along a dashed line as shown in FIG. 28C. Then, the outer edges of the exterior body 509 are bonded to each other. The bonding can be performed by thermocompression, for example. At this time, a part (or one side) of the exterior body 509 is left unbonded (to provide an inlet) so that the electrolyte solution 508 can be introduced later.

Next, the electrolyte solution 508 (not shown) is introduced into the exterior body 509 from the inlet of the exterior body 509. The electrolyte solution 508 is preferably introduced in a reduced pressure atmosphere or in an inert gas atmosphere. Lastly, the inlet is sealed by bonding. In the above manner, the laminated secondary battery 500 can be made.

When the positive electrode active material described in the above embodiment is used in the positive electrode 503, the secondary battery 500 with high capacity and excellent cycle performance can be obtained.

### [Bendable Secondary Battery]

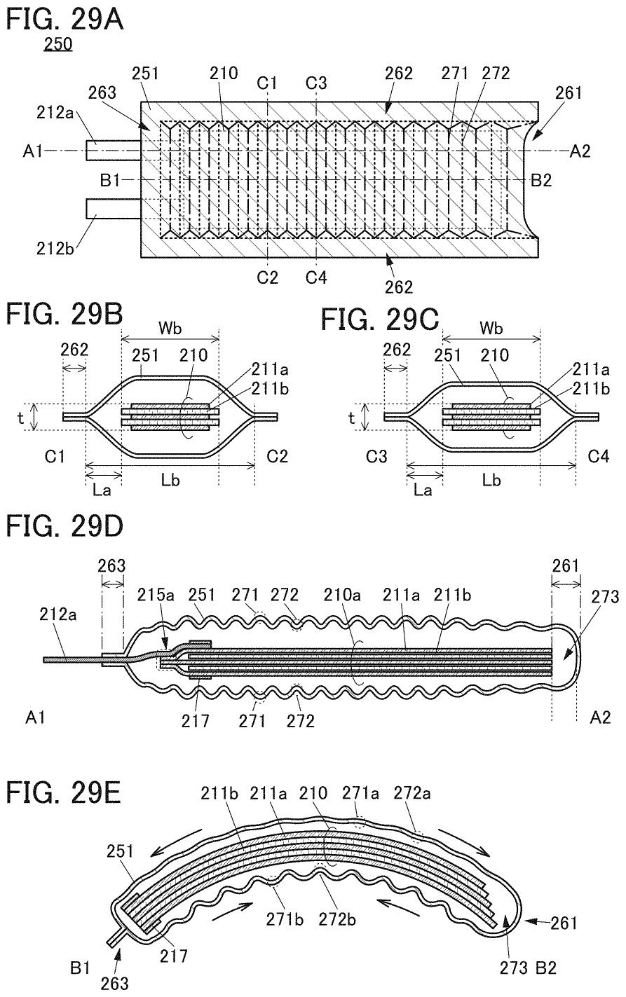

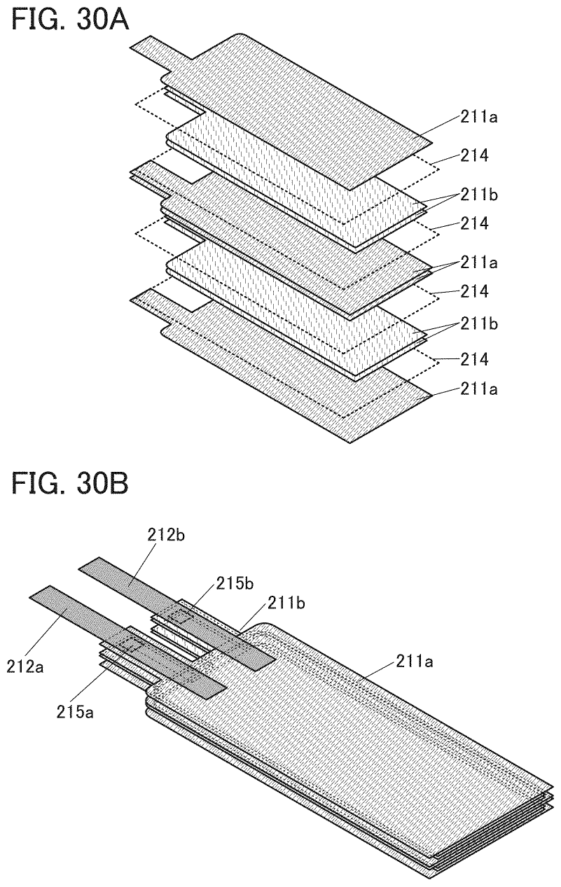

Next, an example of a bendable secondary battery is described with reference to FIG. 29 and FIG. 30.

FIG. 29A is a schematic top view of a bendable secondary battery 250. FIG. 29B, FIG. 29C, and FIG. 29D are schematic cross-sectional views taken along the cutting line C1-C2, the cutting line C3-C4, and the cutting line A1-A2, respectively, in FIG. 29A. The secondary battery 250 includes an exterior body 251 and a positive electrode 211a and a negative electrode 211b held in the exterior body 251. A lead 212a electrically connected to the positive electrode 211a and a lead 212b electrically connected to the negative electrode 211b are extended to the outside of the exterior body 251. In addition to the positive electrode 211a and the negative electrode 211b, an electrolyte solution (not shown) is enclosed in a region surrounded by the exterior body 251.

The positive electrode 211a and the negative electrode 211b that are included in the secondary battery 250 are described using FIG. 30. FIG. 30A is a perspective view showing the stacking order of the positive electrode 211a, the negative electrode 211b, and a separator 214. FIG. 30B is a perspective view showing the lead 212a and the lead 212b in addition to the positive electrode 211a and the negative electrode 211b.

As shown in FIG. 30A, the secondary battery 250 includes a plurality of strip-shaped positive electrodes 211a, a plurality of strip-shaped negative electrodes 211b, and a plurality of separators 214. The positive electrode 211a and the negative electrode 211b each include a projected tab portion and a portion other than the tab portion. A positive electrode active material layer is formed on one surface of the positive electrode 211a other than the tab portion, and a negative electrode active material layer is formed on one surface of the negative electrode 211b other than the tab portion.

The positive electrodes 211a and the negative electrodes 211b are stacked so that surfaces of the positive electrodes 211a on each of which the positive electrode active material layer is not formed are in contact with each other and that surfaces of the negative electrodes 211b on each of which the negative electrode active material is not formed are in contact with each other.

Furthermore, the separator 214 is provided between the surface of the positive electrode 211a on which the positive electrode active material is formed and the surface of the negative electrode 211b on which the negative electrode active material is formed. In FIG. 30, the separator 214 is shown by a dotted line for clarity.

In addition, as shown in FIG. 30B, the plurality of positive electrodes 211a are electrically connected to the lead 212a in a bonding portion 215a. The plurality of negative electrodes 211b are electrically connected to the lead 212b in a bonding portion 215b.

Next, the exterior body 251 is described with reference to FIG. 29B, FIG. 29C, (D), and (E).

The exterior body 251 has a film-like shape and is folded in half to encompass the positive electrodes 211a and the negative electrodes 211b. The exterior body 251 includes a folded portion 261, a pair of seal portions 262, and a seal portion 263. The pair of seal portions 262 is provided with the positive electrodes 211a and the negative electrodes 211b positioned therebetween and thus can also be referred to as side seals. The seal portion 263 includes portions overlapping with the lead 212a and the lead 212b and can also be referred to as a top seal.

Part of the exterior body 251 that overlaps with the positive electrodes 211a and the negative electrodes 211b preferably has a wave shape in which crest lines 271 and trough lines 272 are alternately arranged. The seal portions 262 and the seal portion 263 of the exterior body 251 are preferably flat.

FIG. 29B shows a cross section along a part overlapping with the crest line 271. FIG. 29C shows a cross section along a part overlapping with the trough line 272. FIG. 29B and FIG. 29C correspond to cross sections of the secondary battery 250, the positive electrodes 211a, and the negative electrodes 211b in the width direction.

Here, the distance between end portions of the positive electrode 211a and the negative electrode 211b in the width direction and the seal portion 262, that is, the distance between the end portions of the positive electrode 211a and the negative electrode 211b and the seal portion 262 is referred to as a distance La. When the secondary battery 250 changes in shape, for example, is bent, the positive electrode 211a and the negative electrode 211b change in shape such that the positions thereof are shifted from each other in the length direction as described later. At the time, if the distance La is too short, the exterior body 251 and the positive electrode 211a and the negative electrode 211b are rubbed hard against each other, so that the exterior body 251 is damaged in some cases. In particular, when a metal film of the exterior body 251 is exposed, the metal film might be corroded by the electrolyte solution. Therefore, the distance La is preferably set as long as possible. However, if the distance La is too long, the volume of the secondary battery 250 is increased.

The distance La between the positive electrode 211a and negative electrode 211b and the seal portion 262 is preferably increased as the total thickness of the stacked positive electrodes 211a and negative electrodes 211b is large.

Specifically, when the total thickness of the stacked positive electrodes 211a, negative electrodes 211b, and separators 214 (not shown) is referred to as a thickness t, the distance La is preferably 0.8 times or more and 3.0 times or less, further preferably 0.9 times or more and 2.5 times or less, still further preferably 1.0 times or more and 2.0 times or less as large as the thickness t. When the distance La is in the above range, a compact battery highly reliable for bending can be obtained.

Furthermore, when the distance between the pair of seal portions 262 is referred to as a distance Lb, it is preferred that the distance Lb be sufficiently longer than the widths of the positive electrode 211a and the negative electrode 211b (here, a width Wb of the negative electrode 211b). In that case, even when the positive electrode 211a and the negative electrode 211b come into contact with the exterior body 251 by change in the shape of the secondary battery 250, such as repeated bending, part of the positive electrode 211a and the negative electrode 211b can move in the width direction; thus, the positive and negative electrodes 211a and 211b and the exterior body 251 can be effectively prevented from being rubbed against each other.

For example, the difference between the distance Lb, which is the distance between the pair of seal portions 262, and the width Wb of the negative electrode 211b is preferably 1.6 times or more and 6.0 times or less, further preferably 1.8 times or more and 5.0 times or less, and still further preferably 2.0 times or more and 4.0 times or less as large as the thickness t of the positive electrode 211a and the negative electrode 211b.

In other words, the distance Lb, the width Wb, and the thickness t preferably satisfy the relationship of Formula below.

$$\begin{matrix}[ Formula 4 ] & \\ \frac{Lb - W b}{2 t} \geq a & ( Formula 4 )\end{matrix}$$

In the formula, a is 0.8 or more and 3.0 or less, preferably 0.9 or more and 2.5 or less, further preferably 1.0 or more and 2.0 or less.

FIG. 29D shows a cross section including the lead 212a and corresponds to a cross section of the secondary battery 250, the positive electrode 211a, and the negative electrode 211b in the length direction. As shown in FIG. 29D, a space 273 is preferably provided between the end portions of the positive electrode 211a and the negative electrode 211b in the length direction and the exterior body 251 in the folded portion 261.

FIG. 29E is a schematic cross-sectional view of the secondary battery 250 in a state of being bent. FIG. 29D corresponds to a cross section along the cutting line B1-B2 in FIG. 29A.

When the secondary battery 250 is bent, part of the exterior body 251 positioned on the outer side in bending is stretched and other part positioned on the inner side changes its shape as it is squashed. More specifically, part of the exterior body 251 positioned on the outer side in bending changes its shape such that the wave amplitude becomes smaller and the length of the wave period becomes larger. By contrast, part of the exterior body 251 positioned on the inner side changes its shape such that the wave amplitude becomes larger and the length of the wave period becomes smaller. When the exterior body 251 changes its shape in this manner, stress applied to the exterior body 251 due to bending is relieved, so that a material itself of the exterior body 251 does not need to be stretched and squashed. Thus, the secondary battery 250 can be bent with small force without damage to the exterior body 251.

As shown in FIG. 29E, when the secondary battery 250 is bent, the positive electrode 211a and the negative electrode 211b relatively move. At this time, ends of the stacked positive electrodes 211a and negative electrodes 211b on the seal portion 263 side are fixed by a fixing member 217. Thus, the stacked positive electrodes 211a and negative electrodes 211b move; the closer part of the positive electrodes 211a and the negative electrodes 211b are to the folded portion 261, the bigger the movement becomes. This relieves stress applied to the positive electrodes 211a and the negative electrodes 211b, and the positive electrodes 211a and the negative electrodes 211b themselves do not need to be stretched and squashed. Consequently, the secondary battery 250 can be bent without damage to the positive electrode 211a and the negative electrode 211b.

Furthermore, the space 273 is provided between the positive electrode 211a and the negative electrode 211b and the exterior body 251, whereby the positive electrode 211a and the negative electrode 211b, which are positioned inside at the time of bending, do not touch the exterior body 251 and can relatively move.

Repetitions of being stretched and squashed of the secondary battery 250 shown in FIG. 29 and FIG. 30 are less likely to damage the exterior body, the positive electrode 211a, and the negative electrode 211b, for example; battery characteristics are less likely to deteriorate. When the positive electrode active material described in the above embodiment are used in the positive electrode 211a included in the secondary battery 250, a battery with better cycle performance can be obtained.

This embodiment can be implemented in appropriate combination with the other embodiments.

### Embodiment 5

In this embodiment, examples of electronic devices each including the secondary battery of one embodiment of the present invention are described.

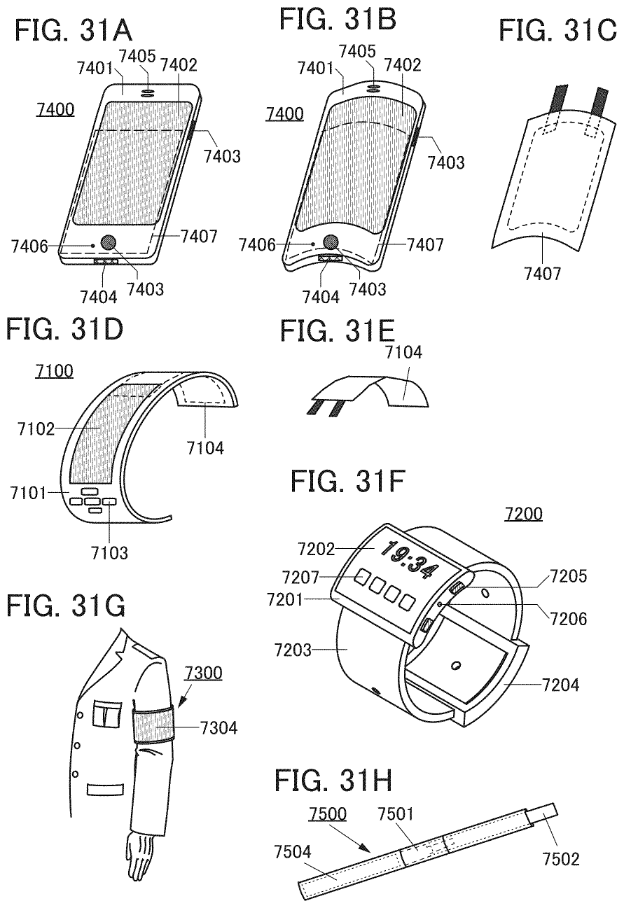

First, FIG. 31A to FIG. 31G show examples of electronic devices each including the bendable secondary battery described in part of Embodiment 3. Examples of electronic devices each including a bendable secondary battery include television sets (also referred to as televisions or television receivers), monitors of computers or the like, digital cameras, digital video cameras, digital photo frames, mobile phones (also referred to as cellular phones or mobile phone devices), portable game machines, portable information terminals, audio reproducing devices, and large game machines such as pachinko machines.

In addition, a flexible secondary battery can be incorporated along a curved inside/outside wall surface of a house or a building or a curved interior/exterior surface of an automobile.

FIG. 31A shows an example of a mobile phone. A mobile phone 7400 includes operation buttons 7403, an external connection port 7404, a speaker 7405, a microphone 7406, and the like in addition to a display portion 7402 incorporated in a housing 7401. Note that the mobile phone 7400 includes a secondary battery 7407. When the secondary battery of one embodiment of the present invention is used as the secondary battery 7407, a lightweight mobile phone with a long lifetime can be provided.

FIG. 31B shows the state where the mobile phone 7400 is curved. When the whole mobile phone 7400 is bent by external force, the secondary battery 7407 included in the mobile phone 7400 is also bent. FIG. 31C shows the bent secondary battery 7407 at that time. The secondary battery 7407 is a thin storage battery. The secondary battery 7407 is fixed in a state of being bent. Note that the secondary battery 7407 includes a lead electrode electrically connected to a current collector. The current collector is, for example, copper foil, and partly alloyed with gallium; thus, adhesion between the current collector and an active material layer in contact with the current collector is improved and the secondary battery 7407 can have high reliability even in a state of being bent.

FIG. 31D shows an example of a bangle-type display device. A portable display device 7100 includes a housing 7101, a display portion 7102, operation buttons 7103, and a secondary battery 7104. In addition, FIG. 31E shows the state of the bent secondary battery 7104. When the display device is worn on a user's arm while the secondary battery 7104 is bent, the housing changes its shape and the curvature of part or the whole of the secondary battery 7104 is changed. Note that the radius of curvature of a curve at a point refers to the radius of the circular arc that best approximates the curve at that point. The reciprocal of the radius of curvature is curvature. Specifically, part of or the whole of the housing or the main surface of the secondary battery 7104 is changed in the range of radius of curvature greater than or equal to 40 mm and less than or equal to 150 mm. When the radius of curvature at the main surface of the secondary battery 7104 is greater than or equal to 40 mm and less than or equal to 150 mm, the reliability can be kept high. When the secondary battery of one embodiment of the present invention is used as the secondary battery 7104, a lightweight portable display device with a long lifetime can be provided.

FIG. 31F shows an example of a watch-type portable information terminal. A portable information terminal 7200 includes a housing 7201, a display portion 7202, a band 7203, a buckle 7204, an operation button 7205, an input output terminal 7206, and the like.

The portable information terminal 7200 is capable of executing a variety of applications such as mobile phone calls, e-mailing, viewing and editing texts, music reproduction, Internet communication, and a computer game.

The display portion 7202 with a curved display surface is provided, and images can be displayed on the curved display surface. The display portion 7202 includes a touch sensor, and operation can be performed by touching the screen with a finger, a stylus, or the like. For example, by touching an icon 7207 displayed on the display portion 7202, application can be started.

With the operation button 7205, a variety of functions such as time setting, power on/off, on/off of wireless communication, setting and cancellation of a silent mode, and setting and cancellation of a power saving mode can be performed. For example, the functions of the operation button 7205 can be set freely by setting the operation system incorporated in the portable information terminal 7200.

The portable information terminal 7200 can employ near field communication that is a communication method based on an existing communication standard. For example, mutual communication with a headset capable of wireless communication enables hands-free calling.

The portable information terminal 7200 includes the input output terminal 7206, and can perform direct data communication with another information terminal via a connector. In addition, charging through the input output terminal 7206 is possible. The charging operation may be performed by wireless power feeding without using the input output terminal 7206.

The display portion 7202 of the portable information terminal 7200 includes the secondary battery of one embodiment of the present invention. When the secondary battery of one embodiment of the present invention is used, a lightweight portable information terminal with a long lifetime can be provided. For example, the secondary battery 7104 shown in FIG. 31E that is in the state of being curved can be provided in the housing 7201. Alternatively, the secondary battery 7104 shown in FIG. 31E can be provided in the band 7203 such that it can be curved.

The portable information terminal 7200 preferably includes a sensor. As the sensor, for example, a human body sensor such as a fingerprint sensor, a pulse sensor, or a temperature sensor; a touch sensor; a pressure sensitive sensor; an acceleration sensor; or the like is preferably mounted.

FIG. 31G shows an example of an armband display device. A display device 7300 includes a display portion 7304 and the secondary battery of one embodiment of the present invention. The display device 7300 can include a touch sensor in the display portion 7304 and can serve as a portable information terminal.

The display surface of the display portion 7304 is curved, and images can be displayed on the curved display surface. A display state of the display device 7300 can be changed by, for example, near field communication, which is a communication method based on an existing communication standard.

The display device 7300 includes an input/output terminal, and data can be directly transmitted to and received from another information terminal through a connector. In addition, charge through the input/output terminal is possible. Note that the charge operation may be performed by wireless power feeding without using the input/output terminal.

When the secondary battery of one embodiment of the present invention is used as the secondary battery included in the display device 7300, a lightweight display device with a long lifetime can be provided.

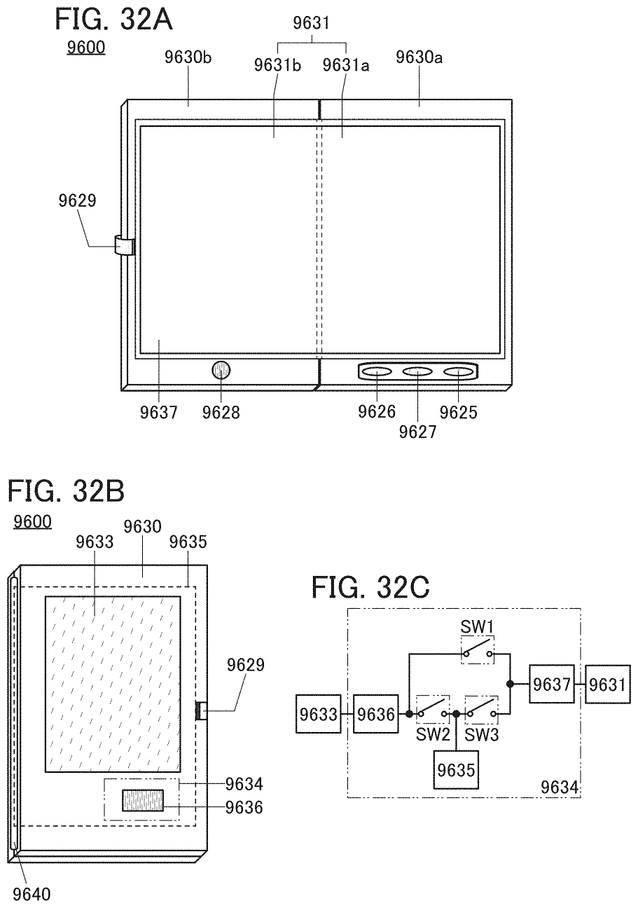

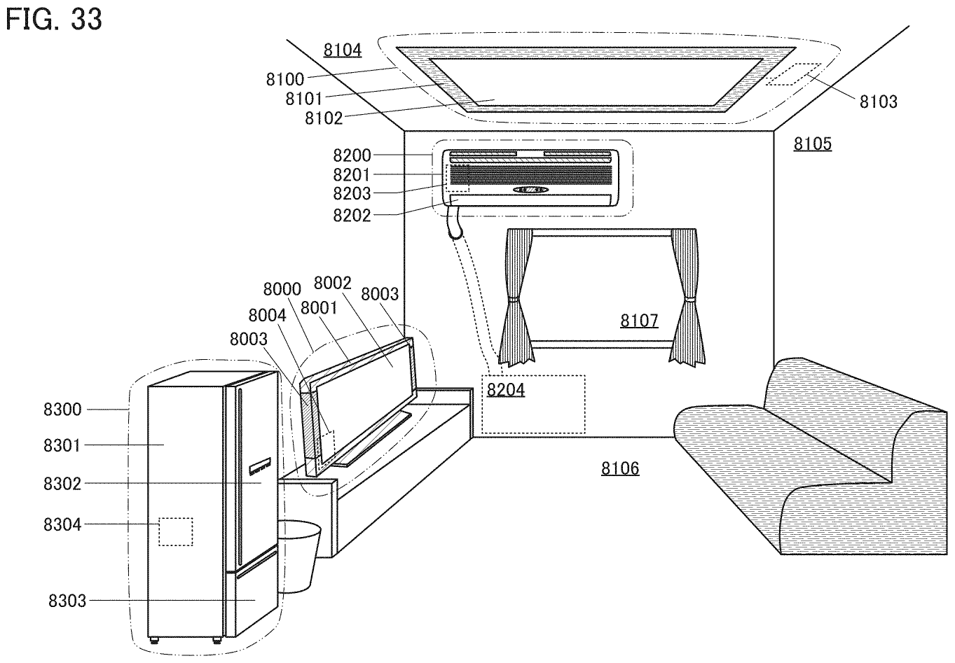

In addition, examples of electronic devices each including the secondary battery with excellent cycle performance described in the above embodiment are described using FIG. 31H, FIG. 32, and FIG. 33.

When the secondary battery of one embodiment of the present invention is used as a secondary battery of a daily electronic device, a lightweight product with a long lifetime can be provided. Examples of the daily electronic device include an electric toothbrush, an electric shaver, and electric beauty equipment. As secondary batteries of these products, small and lightweight stick type secondary batteries with high capacity are desired in consideration of handling ease for users.

FIG. 31H is a perspective view of a device called a vaporizer (electronic cigarette). In FIG. 31H, an electronic cigarette 7500 includes an atomizer 7501 including a heating element, a secondary battery 7504 that supplies power to the atomizer, and a cartridge 7502 including a liquid supply bottle, a sensor, and the like. To improve safety, a protection circuit that prevents overcharge and overdischarge of the secondary battery 7504 may be electrically connected to the secondary battery 7504. The secondary battery 7504 in FIG. 31H includes an external terminal for connection to a charger. When the electronic cigarette 7500 is held by a user, the secondary battery 7504 becomes a tip portion; thus, it is preferred that the secondary battery 7504 have a short total length and be lightweight. With the secondary battery of one embodiment of the present invention, which has high capacity and excellent cycle performance, the small and lightweight electronic cigarette 7500 that can be used for a long time over a long period can be provided.

Next, FIG. 32A and FIG. 32B show an example of a tablet terminal that can be folded in half. A tablet terminal 9600 shown in FIG. 32A and FIG. 32B includes a housing 9630a, a housing 9630b, a movable portion 9640 connecting the housings 9630a and 9630b to each other, a display portion 9631 including a display portion 9631a and a display portion 9631b, a switch 9625 to a switch 9627, a fastener 9629, and an operation switch 9628. By using a flexible panel for the display portion 9631, the tablet terminal can have a larger display portion. FIG. 32A shows the tablet terminal 9600 that is opened, and FIG. 32B shows the tablet terminal 9600 that is closed.

The tablet terminal 9600 includes a power storage unit 9635 inside the housing 9630a and the housing 9630b. The power storage unit 9635 is provided across the housing 9630a and the housing 9630b, passing through the movable portion 9640.

Part of or the entire display portion 9631 can be a touch panel region, and data can be input by touching text, an input form, an image including an icon, and the like displayed on the region. For example, it is possible that keyboard buttons are displayed on the entire display portion 9631a on the housing 9630a side, and data such as text or an image is displayed on the display portion 9631b on the housing 9630b side.

In addition, it is possible that a keyboard is displayed on the display portion 9631b on the housing 9630b side, and data such as text or an image is displayed on the display portion 9631a on the housing 9630a side. Furthermore, it is possible that a switching button for showing/hiding a keyboard on a touch panel is displayed on the display portion 9631 and the button is touched with a finger, a stylus, or the like to display keyboard buttons on the display portion 9631.

In addition, touch input can be performed concurrently in a touch panel region in the display portion 9631a on the housing 9630a side and a touch panel region in the display portion 9631b on the housing 9630b side.

The switch 9625 to the switch 9627 may function not only as an interface for operating the tablet terminal 9600 but also as an interface that can switch various functions. For example, at least one of the switch 9625 to the switch 9627 may have a function of switching on/off of the tablet terminal 9600. For another example, at least one of the switch 9625 to the switch 9627 may have a function of switching display between a portrait mode and a landscape mode and a function of switching display between monochrome display and color display. For another example, at least one of the switch 9625 to the switch 9627 may have a function of adjusting the luminance of the display portion 9631. The display luminance of the display portion 9631 can be optimized in accordance with the amount of external light in use of the tablet terminal 9600 detected by an optical sensor incorporated in the tablet terminal 9600. Note that another sensing device including a sensor for measuring inclination, such as a gyroscope sensor or an acceleration sensor, may be incorporated in the tablet terminal, in addition to the optical sensor.

The display portion 9631a on the housing 9630a side and the display portion 9631b on the housing 9630b side have substantially the same display area in FIG. 32A; however, there is no particular limitation on the display areas of the display portions 9631a and 9631b, and the display portions may have different areas or different display quality. For example, one of the display portions 9631a and 9631b may display higher definition images than the other.

The tablet terminal 9600 is folded in half in FIG. 32B. The tablet terminal 9600 includes a housing 9630, a solar cell 9633, and a charge and discharge control circuit 9634 including a DCDC converter 9636. The power storage unit of one embodiment of the present invention is used as the power storage unit 9635.

The tablet terminal 9600 can be folded in half such that the housings 9630a and 9630b overlap with each other when not in use. The display portion 9631 can be protected owing to the holding, which increases the durability of the tablet terminal 9600. With the power storage unit 9635 including the secondary battery of one embodiment of the present invention, which has high capacity and excellent cycle performance, the tablet terminal 9600 that can be used for a long time over a long period can be provided.

The tablet terminal 9600 shown in FIG. 32A and FIG. 32B can also have a function of displaying various kinds of data (e.g., a still image, a moving image, and a text image), a function of displaying a calendar, a date, or the time on the display portion, a touch-input function of operating or editing data displayed on the display portion by touch input, a function of controlling processing by various kinds of software (programs), and the like.

The solar cell 9633, which is attached on the surface of the tablet terminal 9600, supplies electric power to a touch panel, a display portion, a video signal processing portion, and the like. Note that the solar cell 9633 can be provided on one or both surfaces of the housing 9630 and the power storage unit 9635 can be charged efficiently. The use of a lithium-ion battery as the power storage unit 9635 brings an advantage such as a reduction in size.

The structure and operation of the charge and discharge control circuit 9634 shown in FIG. 32B are described with reference to a block diagram in FIG. 32C. The solar cell 9633, the power storage unit 9635, the DCDC converter 9636, a converter 9637, switches SW1 to SW3, and the display portion 9631 are shown in FIG. 32C, and the power storage unit 9635, the DCDC converter 9636, the converter 9637, and the switches SW1 to SW3 correspond to the charge and discharge control circuit 9634 in FIG. 32B.

First, an operation example in which electric power is generated by the solar cell 9633 using external light is described. The voltage of electric power generated by the solar cell is raised or lowered by the DCDC converter 9636 to a voltage for charging the power storage unit 9635. When the display portion 9631 is operated with the electric power from the solar cell 9633, the switch SW1 is turned on and the voltage of the electric power is raised or lowered by the converter 9637 to a voltage needed for operating the display portion 9631. When display on the display portion 9631 is not performed, the switch SW1 is turned off and the switch SW2 is turned on, so that the power storage unit 9635 can be charged.

The solar cell 9633 is described as an example of a power generation unit; one embodiment of the present invention is not limited to this example. The power storage unit 9635 may be charged using another power generation unit such as a piezoelectric element or a thermoelectric conversion element (Peltier element). For example, the power storage unit 9635 may be charged with a non-contact power transmission module that transmits and receives power wirelessly (without contact), or with a combination of other charge units.

FIG. 33 shows other examples of electronic devices. In FIG. 33, a display device 8000 is an example of an electronic device using a secondary battery 8004 of one embodiment of the present invention. Specifically, the display device 8000 corresponds to a display device for TV broadcast reception and includes a housing 8001, a display portion 8002, speaker portions 8003, a secondary battery 8004, and the like. The secondary battery 8004 of one embodiment of the present invention is provided in the housing 8001. The display device 8000 can receive electric power from a commercial power source or can use electric power stored in the secondary battery 8004. Thus, the display device 8000 can be operated with the use of the secondary battery 8004 of one embodiment of the present invention as an uninterruptible power supply even when electric power cannot be supplied from a commercial power supply due to power failure or the like.

A semiconductor display device such as a liquid crystal display device, a light-emitting device in which a light-emitting element such as an organic EL element is provided in each pixel, an electrophoretic display device, a DMD (Digital Micromirror Device), a PDP (Plasma Display Panel), or an FED (Field Emission Display) can be used to the display portion 8002.

Note that the display device includes, in its category, all of information display devices for personal computers, advertisement displays, and the like other than TV broadcast reception.

In FIG. 33, an installation lighting device 8100 is an example of an electronic device using a secondary battery 8103 of one embodiment of the present invention. Specifically, the lighting device 8100 includes a housing 8101, a light source 8102, the secondary battery 8103, and the like. Although FIG. 33 shows the case where the secondary battery 8103 is provided inside a ceiling 8104 on which the housing 8101 and the light source 8102 are installed, the secondary battery 8103 may be provided inside the housing 8101. Alternatively, the lighting device 8100 can use electric power stored in the secondary battery 8103. Thus, the lighting device 8100 can be operated with the use of the secondary battery 8103 of one embodiment of the present invention as an uninterruptible power supply even when electric power cannot be supplied from a commercial power supply due to power failure or the like.

The installation lighting device 8100 provided in the ceiling 8104 is shown in FIG. 33; the secondary battery of one embodiment of the present invention can also be used for an installation lighting device provided in, for example, a wall 8105, a floor 8106, a window 8107, or the like other than the ceiling 8104, or can be used in a tabletop lighting device or the like.

As the light source 8102, an artificial light source which emits light artificially by using power can be used. Specifically, an incandescent lamp, a discharge lamp such as a fluorescent lamp, and a light-emitting element such as an LED or an organic EL element are given as examples of the artificial light source.

In FIG. 33, an air conditioner including an indoor unit 8200 and an outdoor unit 8204 is an example of an electronic device using a secondary battery 8203 of one embodiment of the present invention. Specifically, the indoor unit 8200 includes a housing 8201, an air outlet 8202, the secondary battery 8203, and the like. Although FIG. 33 shows the case where the secondary battery 8203 is provided in the indoor unit 8200, the secondary battery 8203 may be provided in the outdoor unit 8204. Alternatively, the secondary batteries 8203 may be provided in both the indoor unit 8200 and the outdoor unit 8204. The air conditioner can receive electric power from a commercial power source, or can use electric power stored in the secondary battery 8203. Particularly in the case where the secondary batteries 8203 are provided in both the indoor unit 8200 and the outdoor unit 8204, the air conditioner can be operated with the use of the secondary battery 8203 of one embodiment of the present invention as an uninterruptible power supply even when electric power cannot be supplied from a commercial power supply due to power failure or the like.

The split-type air conditioner composed of the indoor unit and the outdoor unit is shown in FIG. 33; the secondary battery of one embodiment of the present invention can also be used in an integrated air conditioner in which one housing has the function of an indoor unit and the function of an outdoor unit.

In FIG. 33, an electric refrigerator-freezer 8300 is an example of an electronic device using a secondary battery 8304 of one embodiment of the present invention. Specifically, the electric refrigerator-freezer 8300 includes a housing 8301, a door for refrigerator compartment 8302, a door for freezer compartment 8303, the secondary battery 8304, and the like. The secondary battery 8304 is provided inside the housing 8301 in FIG. 33. The electric refrigerator-freezer 8300 can receive electric power from a commercial power source, or can use electric power stored in the secondary battery 8304. Thus, the electric refrigerator-freezer 8300 can be operated with the use of the secondary battery 8304 of one embodiment of the present invention as an uninterruptible power supply even when electric power cannot be supplied from a commercial power supply due to power failure or the like.

Note that among the electronic devices described above, a high-frequency heating apparatus such as a microwave oven and an electronic device such as an electric rice cooker require high power in a short time. The tripping of a breaker of a commercial power supply in use of an electronic device can be prevented by using the secondary battery of one embodiment of the present invention as an auxiliary power supply for supplying electric power which cannot be supplied enough by a commercial power supply.

In addition, in a time period when electronic devices are not used, particularly when the proportion of the amount of electric power which is actually used to the total amount of electric power which can be supplied from a commercial power source (such a proportion referred to as a usage rate of electric power) is low, electric power can be stored in the secondary battery, whereby an increase in the usage rate of electric power can be reduced in a time period when the electronic devices are used. For example, in the case of the electric refrigerator-freezer 8300, electric power can be stored in the secondary battery 8304 in night time when the temperature is low and the door for refrigerator compartment 8302 and the door for freezer compartment 8303 are not often opened and closed. On the other hand, in daytime when the temperature is high and the door for refrigerator compartment 8302 and the door for freezer compartment 8303 are frequently opened and closed, the secondary battery 8304 is used as an auxiliary power source; thus, the usage rate of electric power in daytime can be reduced.

According to one embodiment of the present invention, the secondary battery can have excellent cycle performance and improved reliability. Furthermore, according to one embodiment of the present invention, a secondary battery with high capacity can be obtained; thus, the secondary battery itself can be made more compact and lightweight as a result of improved characteristics of the secondary battery. Thus, the secondary battery of one embodiment of the present invention is used in the electronic device described in this embodiment, whereby a more lightweight electronic device with a longer lifetime can be obtained.

This embodiment can be implemented in appropriate combination with the other embodiments.

### Embodiment 6

In this embodiment, examples of vehicles each including the secondary battery of one embodiment of the present invention are described.

The use of secondary batteries in vehicles enables production of next-generation clean energy vehicles such as hybrid electric vehicles (HEVs), electric vehicles (EVs), and plug-in hybrid electric vehicles (PHEVs).

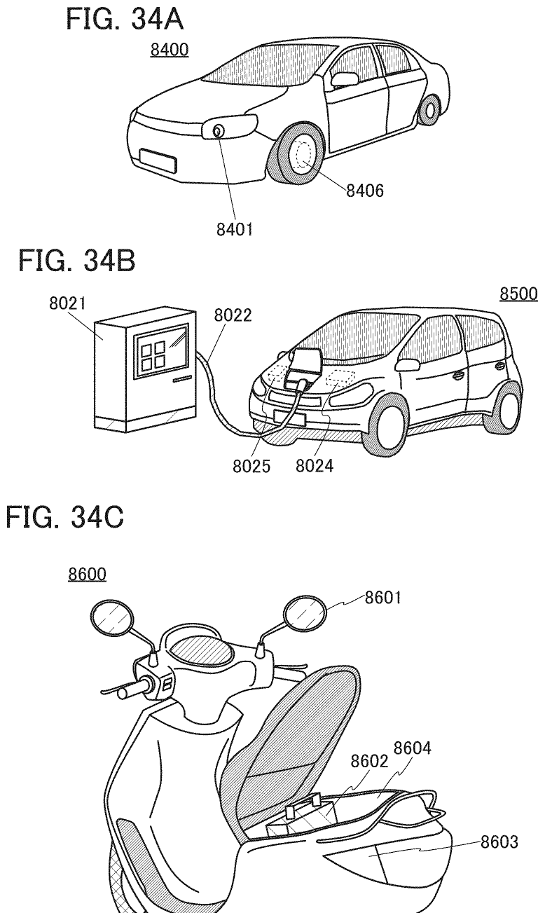

FIG. 34 shows examples of vehicles each using the secondary battery of one embodiment of the present invention. An automobile 8400 shown in FIG. 34A is an electric vehicle that runs on an electric motor as a power source. Alternatively, the automobile 8400 is a hybrid electric vehicle capable of driving using either an electric motor or an engine with an appropriate selection. The use of one embodiment of the present invention can achieve a high-mileage vehicle. The automobile 8400 includes the secondary battery. As the secondary battery, the modules of the secondary batteries shown in FIG. 19C and FIG. 19D may be arranged to be used in a floor portion in the automobile. Alternatively, a battery pack in which a plurality of secondary batteries shown in FIG. 22 are combined may be placed in the floor portion in the automobile. The secondary battery is used not only for driving an electric motor 8406, but also for supplying electric power to a light-emitting device such as a headlight 8401 or a room light (not shown).

The secondary battery can also supply electric power to a display device included in the automobile 8400, such as a speedometer or a tachometer. Furthermore, the secondary battery can supply electric power to a semiconductor device included in the automobile 8400, such as a navigation system.

FIG. 34B shows an automobile 8500 including the secondary battery. The automobile 8500 can be charged when the secondary battery is supplied with electric power through external charge equipment of a plug-in system, a contactless power feeding system, or the like. In FIG. 34B, a secondary battery 8024 included in the automobile 8500 are charged with the use of a ground-based charge apparatus 8021 through a cable 8022. In charging, a given method such as CHAdeMO (registered trademark) or Combined Charging System may be employed as a charging method, the standard of a connector, or the like as appropriate. The charging apparatus 8021 may be a charging station provided in a commerce facility or a power source in a house. For example, with a plug-in technique, the secondary battery 8024 incorporated in the automobile 8500 can be charged by power supply from the outside. The charging can be performed by converting AC electric power into DC electric power through a converter, such as an AC-DC converter.

Although not illustrated, the vehicle may include a power receiving device so that it can be charged by being supplied with electric power from an above-ground power transmitting device in a contactless manner. In the case of the contactless power feeding system, by incorporating a power transmitting device in a road or an exterior wall, charging can be performed not only when the electric vehicle is stopped but also when driven. In addition, the contactless power feeding system may be utilized to perform transmission and reception of electric power between vehicles. Furthermore, a solar cell may be provided in the exterior of the vehicle to charge the secondary battery while the vehicle is stopped or while the vehicle is running. To supply electric power in such a contactless manner, an electromagnetic induction method or a magnetic resonance method can be used.

FIG. 34C shows an example of a motorcycle including the secondary battery of one embodiment of the present invention. A motor scooter 8600 shown in FIG. 34C includes a secondary battery 8602, side mirrors 8601, and indicators 8603. The secondary battery 8602 can supply electricity to the direction indicators 8603.

Furthermore, in the motor scooter 8600 shown in FIG. 34C, the secondary battery 8602 can be held in a storage unit under seat storage 8604. The secondary battery 8602 can be stored in the under-seat storage 8604 even when the under-seat storage 8604 is small. The secondary battery 8602 is detachable; thus, the secondary battery 8602 is carried indoors when charged, and is stored before the motor scooter is driven.

According to one embodiment of the present invention, the secondary battery can have improved cycle performance and the capacity of the secondary battery can be increased. Thus, the secondary battery itself can be made more compact and lightweight. The compact and lightweight secondary battery contributes to a reduction in the weight of a vehicle, and thus increases the mileage. Furthermore, the secondary battery included in the vehicle can be used as a power source for supplying electric power to products other than the vehicle. In such a case, the use of a commercial power supply can be avoided at peak time of electric power demand, for example. Avoiding the use of a commercial power supply at peak time of electric power demand can contribute to energy saving and a reduction in carbon dioxide emissions. Moreover, the secondary battery with excellent cycle performance can be used over a long period; thus, the use amount of rare metals such as cobalt can be reduced.

This embodiment can be implemented in appropriate combination with the other embodiments.

### Example 1

In this example, the positive electrode active material of one embodiment of the present invention and a positive electrode active material as a comparative example were made, and cycle performance at high-voltage charging was evaluated. Characteristics were analyzed using XRD.

### [Making of Positive Electrode Active Material]

### <<Sample 1>>

In Sample 1, a positive electrode active material containing cobalt as a transition metal was made with the manufacturing method shown in FIG. 13 in Embodiment 1. First, LiF and MgF₂ were weighted so that the molar ratio of LiF to MgF₂ was LiF:MgF₂=1:3, acetone was added as a solvent, and mixing and grinding were performed on the materials by a wet process. The mixing and the grinding were performed in a ball mill using a zirconia ball at 150 rpm for one hour. The materials after the treatments were collected to be a first mixture (Step S11 to Step S14 of FIG. 13).

In Sample 1, CELLSEED C-10N manufactured by NIPPON CHEMICAL INDUSTRIAL CO., LTD. was used for lithium cobaltate synthesized in advance (Step S25 in FIG. 13). As described in Embodiment 1, CELLSEED C-10N is lithium cobaltate having the average particle diameter (D50) of approximately 12 μm and few impurities.

Next, the first mixture was weighted so that the atomic weight of magnesium contained in the first mixture was 0.5 atomic % with respect to the molecular weight of lithium cobaltate, and the first mixture and lithium cobaltate were mixed by a dry process. The mixing was performed in a ball mill using a zirconia ball at 150 rpm for one hour. The materials after the treatments were collected to be a second mixture (Step S31 to Step S33 of FIG. 13).

Next, the second mixture was put in an alumina crucible and annealed at 850° C. using a muffle furnace in an oxygen atmosphere for 60 hours. At the time of annealing, the alumina crucible was covered with a lid. The flow rate of oxygen was 10 L/min. The temperature rising was 200° C./hr, and the temperature lowering took longer than or equal to 10 hours. The material after the heat treatment was the positive electrode active material of Sample 1 (Steps S34 and S35 in FIG. 13).

### [Making of Secondary Batteries]

Next, a CR2032 type coin secondary battery (a diameter of 20 mm, a height of 3.2 mm) was made using Sample 1 made in the above manner.

A positive electrode where slurry in which the positive electrode active material manufactured in the above manner, acetylene black (AB), and polyvinylidene fluoride (PVDF) were mixed at the positive electrode active material:AB:PVDF=95:3:2 (weight ratio) was applied to a current collector was used. The loaded amount of the positive electrode active material layer was approximately 8.2 mg/cm².

Lithium metal was used as a counter electrode.

As an electrolyte contained in an electrolyte solution, 1 mol/L lithium hexafluorophosphate (LiPF₆) was used, and as the electrolyte solution, an electrolyte solution in which ethylene carbonate (EC) and diethyl carbonate (DEC) at EC:DEC=3:7 (volume ratio) and vinylene carbonate (VC) at 2 wt % were mixed was used.

As a separator, 25-μm-thick polypropylene was used.

A positive electrode can and a negative electrode can formed of stainless steel (SUS) were used.

The positive electrode of the secondary battery was pressed. Specifically, pressure was applied at 210 kN/m, and then pressure was applied at 1467 kN/m.

[Cycle Performance and dQ/dV Vs V Curve]

The secondary battery using Sample 1 was measured at 25° C. for two cycles when CCCV charging (0.05 C, 4.5 V or 4.6 V, a termination current of 0.005 C) and CC discharging (0.05 C, 2.5 V) were performed.

After that, the cycle performance was measured. Specifically, CCCV charging (0.2 C, 4.5 V or 4.6 V, a termination current of 0.02 C) and CC discharging (0.2 C, 2.5 V) were repeatedly performed at 25° C. on the secondary batteries using Sample 1, and then cycle performance was evaluated.

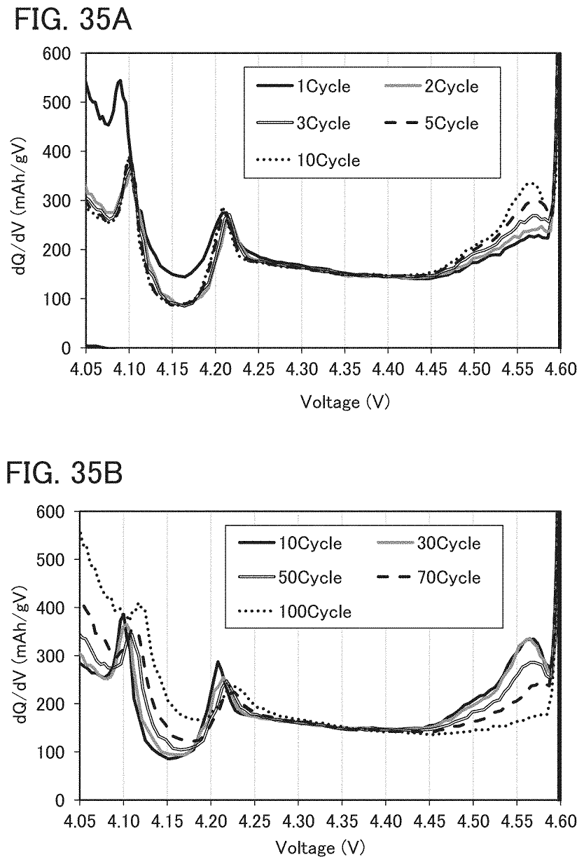

FIG. 35 shows dQ/dV vs V curves calculated from the charging curves at the cycles. FIG. 35A shows the dQ/dV vs V curves at the 1st, 3rd, 4th, 5th, and 10th cycles. FIG. 35B shows the dQ/dV vs V curves at the 10th, 30th, 50th, 70th, and 100th cycles.

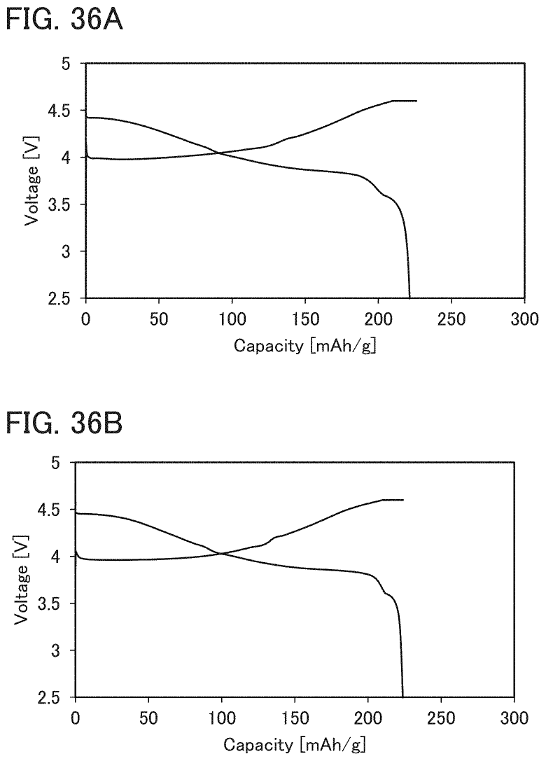

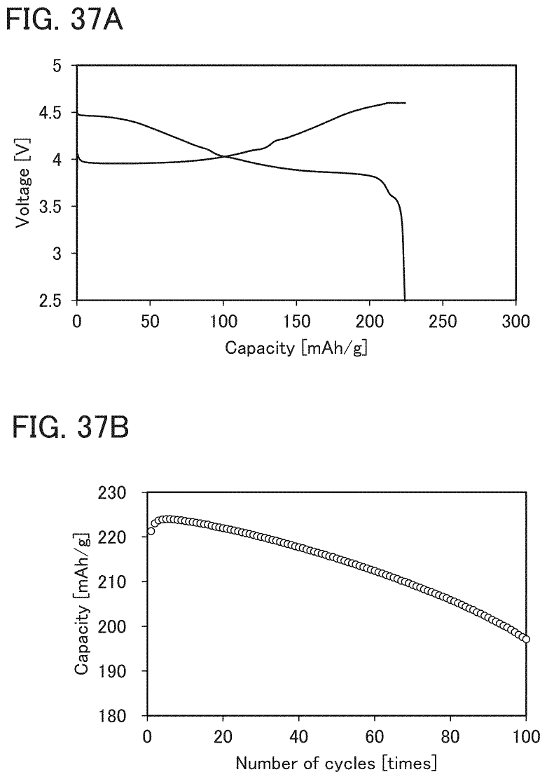

FIG. 36A shows the charge and discharge curves at the first cycle, FIG. 36B shows those at the third cycle, and FIG. 37A shows those at the fifth cycle. FIG. 37B shows the discharge capacity at each cycle.

As shown in FIG. 35A and FIG. 35B, the first peaks greater than or equal to 4.08 V and less than or equal to 4.18 V, the second peaks greater than or equal to 4.18 V and less than or equal to 4.25 V, and the third peaks greater than or equal to 4.54 V and less than or equal to 4.58 V were observed.

As shown in FIG. 35A, the peak intensity of the third peak tended to increase as the number of cycles increased from the 1st cycle to the 10th cycle.

As shown in FIG. 35B, the first peak shifted to right and the voltage values corresponding to the peak increased as the number of cycles increased after the 30th cycle. The peak intensity of the third peak decreased as the number of cycles increased, and the third peak was hardly observed at the 100th cycle.

### Example 2

In this example, Sample 1, which was made in the above example, was evaluated with XRD.

### [XRD(1)]

The positive electrode using Sample 1 before being charged was analyzed with a powder XRD analysis using the CuKα1 ray. The XRD was measured in the air, and the electrode was attached to glass plate to maintain flatness. An XRD apparatus was set for a powder sample, and the height of the sample was set in accordance with the measurement surface required by the apparatus.

On obtained XRD patterns, background removal and Kα2 removal were performed using DIFFRAC. EVA (XRD data analysis software manufactured by Bruker Corporation). Accordingly, signals derived from conductive additives, binders, airtight containers, and the like were also removed.

After that, the lattice constants were calculated using TOPAS. At this time, atomic positions and the like were not optimized and only the lattice constants were fitted. GOF (good of fitness), estimated crystallite sizes, and the respective lattice constants of the a-axis and the c-axis were calculated.

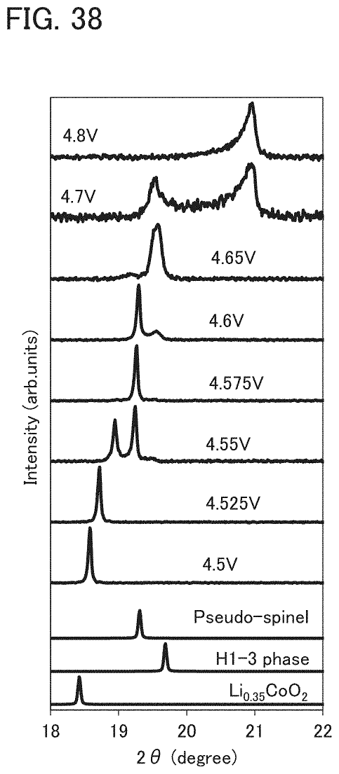

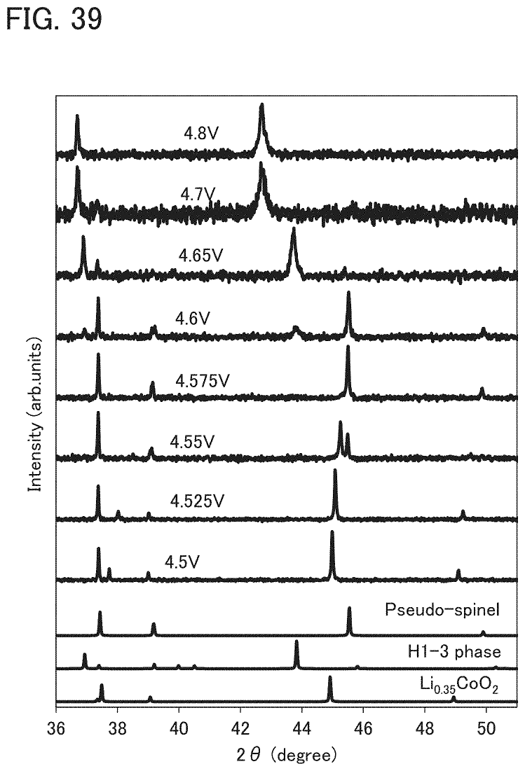

Next, secondary batteries using Sample 1 were made, and CCCV charging was conducted. A positive electrode was made using Sample 1 as a positive electrode active material. The loaded amount of the positive electrode was approximately 7 mg/cm². Charging voltages were the following five conditions: 4.5 V, 4.525 V, 4.55 V, 4.575 V, and 4.6 V. A secondary battery was made for each condition and was evaluated. Specific charging condition was that constant current charging was performed at 0.5 C to each charging voltage, and then constant voltage charging was performed until a current value reached 0.01 C. Note that here 1 C was set to 137 mA/g. Then, the secondary batteries in the charged state were disassembled in a glove box under an argon atmosphere to take out the positive electrodes, and the positive electrodes were cleaned with DMC (dimethyl carbonate) to remove electrolyte. Then, the positive electrodes were enclosed in airtight containers with an argon atmosphere and analyzed with XRD. FIG. 38 and FIG. 39 show XRD patterns of the positive electrodes under each charging voltage condition. FIG. 38 and FIG. 39 show different ranges of 2θ. For comparison, the patterns of the pseudo-spinel crystal structure, the H1-3 type crystal structure, and the crystal structure (space group R-3m, O3) of Li_{0.35}CoO₂ are also shown. Li_{0.35}CoO₂ corresponds to the crystal structure when a charge depth is 0.65.

Using a secondary battery which was different from the secondary battery charged with various charging conditions, 10 cycles of charging and discharging were conducted, the secondary battery was disassembled in a glove box to take out the positive electrode, the positive electrode was cleaned with DMC to remove electrolyte and enclosed in an airtight container with an argon atmosphere, and an XRD analysis was conducted. The charging condition was such that, after constant current charging was performed at 0.5 C up to 4.6 V, constant voltage charging was performed until the current value reached 0.01 C. The discharging condition was CC discharging at 0.2 C and 2.5 V.

Table 2 to Table 5 show the values analyzed with XRD. The XRD before charging is described with “before charging”; the XRDs after charging to 4.5 V, 4.525 V, 4.55 V, 4.575 V, and 4.6 V are respectively described with “4.5 V”, “4.525 V”, “4.55 V”, “4.575 V”, and “4.6 V”; the XRD after a discharge and further 9 times of charges and discharges, that is, the XRD after 10 cycles of charges and discharges is described with “after 10cy discharging”.

Table 2 shows crystallite sizes, volume ratios, and lattice constants when fitting was conducted assuming an O3-type crystal structure; Table 3 shows crystallite sizes, volume ratios, and lattice constants when fitting was conducted assuming a pseudo-spinel-type crystal structure; Table 4 shows crystallite sizes, volume ratios, and lattice constants when fitting was conducted assuming an H1-3 type crystal structure. Each table also shows GOF (good of fitness).

TABLE 2

| | | | Crystallite | Volume | Lattice constant | |
|---|---|---|---|---|---|---|
| | | | size | ratio | a | c |
| | | GOF | (nm) | (w %) | (×10⁻¹⁰m) | (×10⁻¹⁰m) |
| Before charging | | 1.2 | 790 | 100 | 2.816088 | 14.05354 |
| After 10 cy discharging | | 1.14 | 726 | 100 | 2.816206 | 14.05831 |
| 4.5 | V | 1.35 | 497 | 100 | 2.811714 | 14.27400 |
| 4.525 | V | 1.33 | 427.2 | 100 | 2.812763 | 14.16348 |
| 4.55 | V | 1.22 | 201.1 | 62.51 | 2.814379 | 13.99417 |
| 4.575 | V | 1.25 | — | — | — | — |
| 4.6 | V | 1.23 | — | — | — | — |

TABLE 3

| | | | Crystallite | Volume | Lattice constant | |
|---|---|---|---|---|---|---|
| | | | size | ratio | a | c |
| | | GOF | (nm) | (w %) | (×10⁻¹⁰m) | (×10⁻¹⁰m) |
| Before charging | | 1.2 | — | — | — | — |
| After 10 cy discharging | | 1.14 | — | — | — | — |
| 4.5 | V | 1.35 | — | — | — | — |
| 4.525 | V | 1.33 | — | — | — | — |
| 4.55 | V | 1.22 | 248.3 | 37.49 | 2.814861 | 13.78608 |
| 4.575 | V | 1.25 | 397.5 | 100 | 2.815384 | 13.77465 |
| 4.6 | V | 1.23 | 297.5 | 58.34 | 2.815792 | 13.74933 |

TABLE 4

| | | | Crystallite | Volume | Lattice constant | |
|---|---|---|---|---|---|---|
| | | | size | ratio | a | c |
| | | GOF | (nm) | (w %) | (×10⁻¹⁰m) | (×10⁻¹⁰m) |
| Before charging | | 1.2 | — | — | — | — |
| After 10 cy discharging | | 1.14 | — | — | — | — |
| 4.5 | V | 1.35 | — | — | — | — |
| 4.525 | V | 1.33 | — | — | — | — |
| 4.55 | V | 1.22 | — | — | — | — |
| 4.575 | V | 1.25 | — | — | — | — |
| 4.6 | V | 1.23 | 69.4 | 41.66 | 2.81392 | 27.1534 |

Table 5 shows the peak values and the half widths of the two peaks (Peak 1 and Peak 2) which seem to correspond to an O3-type crystal structure, and Table 6 shows the peak values and the full widths at half maximum (FWHM) of the two peaks (Peak 3 and Peak 4) which seem to correspond to a pseudo-spinel-type crystal structure. The peak values and the FWHMs were calculated using TOPAS. L in the tables means the value of adjustability to the Lorentz function.

TABLE 5

| | | Peak 1 | | | Peak 2 | | |
|---|---|---|---|---|---|---|---|
| | | 2θ | FWHM | | 2θ | FWHM | |
| | | [°] | [°] | L | [°] | [°] | L |
| Before charging | | 18.88 | 0.0148 | 0.97 | 45.18 | 0.0269 | 1.00 |
| After 10 cy discharging | | 18.87 | 0.0144 | 0.99 | 45.17 | 0.0300 | 1.00 |
| 4.5 | V | 18.59 | 0.0175 | 0.97 | 44.99 | 0.0415 | 1.00 |
| 4.525 | V | 18.73 | 0.0215 | 0.95 | 45.09 | 0.0438 | 1.00 |
| 4.55 | V | 18.96 | 0.0484 | 1.00 | 45.26 | 0.0662 | 1.00 |
| 4.575 | V | — | — | — | — | — | — |
| 4.6 | V | — | — | — | — | — | — |

TABLE 6

| | | Peak 3 | | | Peak 4 | | |
|---|---|---|---|---|---|---|---|
| | | 2θ | FWHM | | 2θ | FWHM | |
| | | [°] | [°] | L | [°] | [°] | L |
| Before charging | | — | — | — | — | — | — |
| After 10 cy discharging | | — | — | — | — | — | — |
| 4.5 | V | — | — | — | — | — | — |
| 4.525 | V | — | — | — | — | — | — |
| 4.55 | V | 19.25 | 0.0410 | 0.99 | 45.50 | 0.0413 | 1.00 |
| 4.575 | V | 19.27114 | 0.0226904 | 0.94 | 45.5041 | 0.0574491 | 1 |
| 4.6 | V | 19.30626 | 0.0306832 | 1 | 45.52767 | 0.0671726 | 1 |

It was suggested that an O3-type crystal structure and a pseudo-spinel-type crystal structure co-existed at 4.55 V. A pseudo-spinel-type crystal structure became dominant at 4.575 or more.

The lattice constants of the a-axis at charging voltages of 4.5 V and 4.525 V were decreased within the range greater than or equal to 2.81×10⁻¹⁰ m and less than or equal to 2.83×10⁻¹⁰ m compared to the values before charging or after discharging. As the charging voltage increased, that is, the charge depth became deep, the lattice constants had a tendency to increase and to be close to the values before charging or after discharging.

The increase of the half width was approximately 3.4 times larger than the values before charging or after discharging at most.

### [XRD(2)]

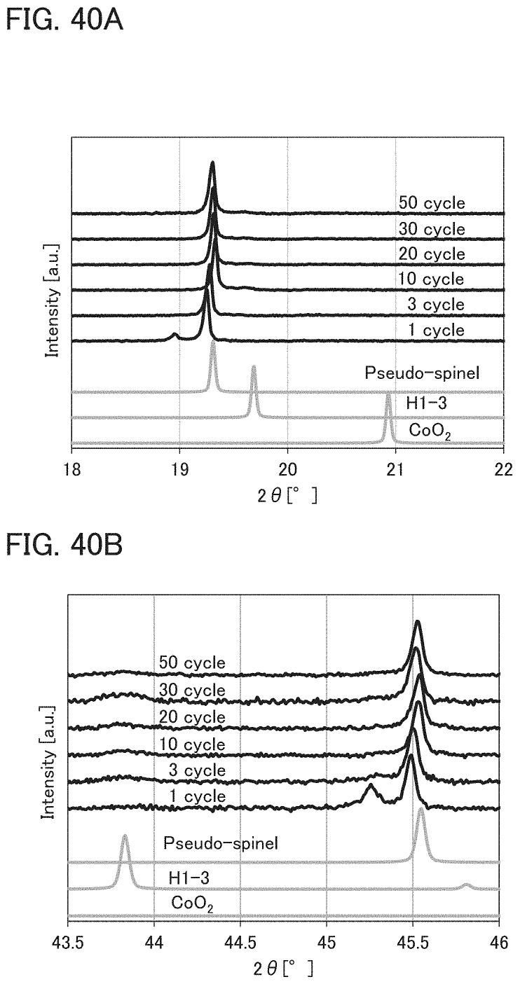

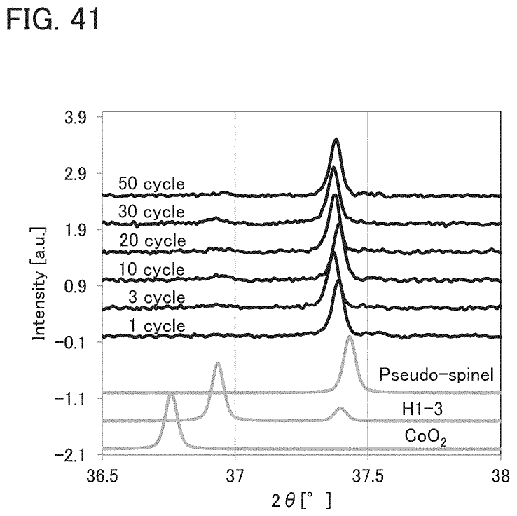

Charge-and-discharge cycles with the conditions in the above example were conducted, and XRDs at 1st, 3rd, 10th, 20th, 30th, and 50th cycles were evaluated. In each cycle, CCCV charging was conducted at the last charging; a charging voltage was 4.6 V; discharging after charging was not conducted; disassembling was conducted in a glove box to take out the positive electrode; the positive electrode was cleaned with DMC to remove electrolyte and enclosed in an airtight container with an argon atmosphere; and an XRD analysis was conducted. FIG. 40A, FIG. 40B, and FIG. 41 show XRD spectra. FIG. 40A, FIG. 40B, and FIG. 41 each show different ranges of the angles of 2θ. Table 7 shows peak values, FWHMs, and L values of three peaks (Peak 3, Peak 4, and Peak 5).

TABLE 7

| | Peak 3 | | | Peak 5 | | | Peak 4 | | |
|---|---|---|---|---|---|---|---|---|---|
| | 2 | FWHM | | 2 | FWHM | | 2 | FWHM | |
| cycle | [°] | [°] | L | [°] | [°] | L | [°] | [°] | L |
| 1 | 19.26 | 0.0264 | 0.99 | 37.38 | 0.0270 | 1.00 | 45.49 | 0.0815 | 1.00 |
| 3 | 19.29 | 0.0301 | 0.92 | 37.37 | 0.0254 | 1.00 | 45.50 | 0.0620 | 1.00 |
| 10 | 19.34 | 0.0262 | 1.00 | 37.40 | 0.0283 | 0.88 | 45.53 | 0.0549 | 1.00 |
| 20 | 19.32 | 0.0222 | 0.97 | 37.38 | 0.0231 | 1.00 | 45.54 | 0.0579 | 1.00 |
| 30 | 19.32 | 0.0250 | 1.00 | 37.38 | 0.0282 | 1.00 | 45.52 | 0.0670 | 1.00 |
| 50 | 19.31 | 0.0331 | 1.00 | 37.38 | 0.0251 | 0.99 | 45.53 | 0.0536 | 0.98 |

The peaks observed at 2θ=19.30±0.20° tended to shift to large degrees as the number of cycles increased. It is suggested that the amount of lithium ions which are released becomes large as the peak values become large, which can increase discharge capacity.

### Example 3

In this example, a secondary battery was made using the positive electrode active material of one embodiment of the present invention and a dQ/dV vs V curve was calculated.

A secondary battery using Sample 1 was measured at 25° C. for two cycles when CCCV charging (0.05 C, 4.5 V, a termination current of 0.005 C) and CC discharging (0.05 C, 2.5 V) were performed.

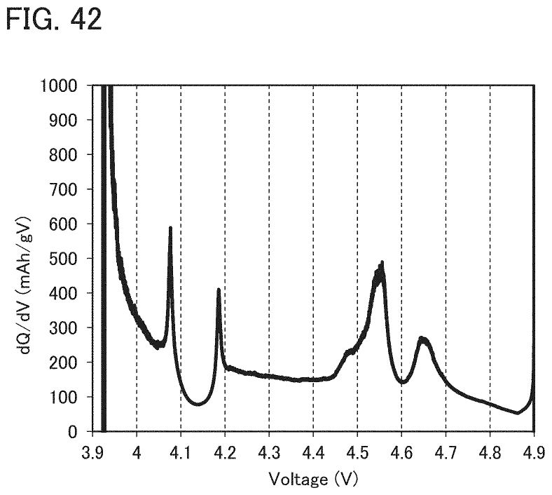

After that, the secondary battery was charged with CCCV (0.05 C, 4.9 V, a termination current of 0.005C, 1C=200 mA/g) at 25° C., and a charging curve was measured. Next, a dQ/dV vs V curve was calculated from the measured charging curve. FIG. 42 shows the results.

FIG. 42 shows the first maximum peak at approximately 4.08 V, the second maximum peak at approximately 4.19 V, the third maximum peak at approximately 4.56 V, and the fourth maximum peak at approximately 4.65 V.

When FIG. 35A and FIG. 42 are compared, it was found that as the charging rate became small (charging speed became slow), the peaks shifted to smaller values by approximately 0.2 V.

### REFERENCE NUMERALS

100: positive electrode active material

1. A positive electrode active material comprising:
a compound comprising lithium, cobalt, oxygen, and magnesium; and
wherein a space group of the compound is represented as R-3m,
wherein the compound is a compound in which magnesium is substituted for a lithium position and a cobalt position in a composite oxide comprising lithium and cobalt,
wherein the compound is a particle,
wherein magnesium substituted for the lithium position and the cobalt position exists more in a region from a surface of the particle to a depth of 5 nm than in a region at a depth of 10 nm or more from the surface, and
wherein more magnesium is substituted for the lithium position than for the cobalt position.

2. The positive electrode active material according to claim 1, further comprising fluorine.

3. The positive electrode active material according to claim 1,
wherein the compound has a charge depth with a cobalt coordinate (0,0,0.5) and an oxygen coordinate (0,0,x) (0.20≤x≤0.25) in a unit cell, and
wherein a volume of the unit cell at the charge depth differs from a volume of a unit cell at a charge depth of 0 by 2.5% or less.

4. A secondary battery comprising the positive electrode active material according to claim 1.

5. A secondary battery,
a positive electrode, and
wherein the positive electrode is taken out from the secondary battery,
wherein a charging voltage is V and an amount of change of V is dV,
wherein a charging capacity is Q and an amount of change of Q is dQ,
wherein a dQ/dV vs V curve is measured using lithium metal as a counter electrode of the positive electrode,
wherein in the dQ/dV vs V curve which shows a relation between dQ/dV, which is a ratio of dQ to dV, and V,
the dQ/dV vs V curve is measured at a rate greater than or equal to 0.1 C and less than or equal to 1.0 C at a temperature greater than or equal to of 10° C. and less than or equal to 35° C.,
the dQ/dV vs V curve is measured twice within the V range greater than or equal to 4.54 V and less than or equal to 4.58 V, and
the dQ/dV vs V curve comprises a first peak in the second measurement within the V range greater than or equal to 4.54 V and less than or equal to 4.58 V, and
wherein the voltage is a voltage with reference to a redox potential of lithium metal.

6. The secondary battery according to claim 5,
wherein the dQ/dV vs V curve is measured within the V range greater than or equal to 4.05 V and less than or equal to 4.58 V,
wherein the dQ/dV vs V curve comprises a second peak within the V range greater than or equal to 4.08 V and less than or equal to 4.18 V,
wherein the dQ/dV vs V curve comprises a third peak within the V range greater than or equal to 4.18 V and less than or equal to 4.25 V, and
wherein the voltage is a voltage with reference to a redox potential of lithium metal.

7. The secondary battery according to claim 6,
wherein at a charging voltage V at which the second peak is observed, the positive electrode has a crystal structure corresponding to a space group P2/m, and
wherein at a charging voltage V at which the first peak is observed, the positive electrode has a crystal structure corresponding to a space group R-3m.

8. The secondary battery according to claim 5,
wherein the secondary battery comprises a negative electrode, and
wherein the negative electrode is lithium metal.

9. The secondary battery according to claim 5,
wherein the secondary battery comprises a negative electrode including graphite.

10. A secondary battery,
a positive electrode, and
wherein the positive electrode is taken out from the secondary battery,
wherein a charging voltage is V and an amount of change of V is dV,
wherein a charging capacity is Q and an amount of change of Q is dQ,
wherein a dQ/dV vs V curve is measured using lithium metal as a counter electrode of the positive electrode,
wherein in the dQ/dV vs V curve which shows a relation between dQ/dV, which is a ratio of dQ to dV, and V,
the dQ/dV vs V curve is measured at a rate greater than or equal to 0.1 C and less than or equal to 1.0 C at a temperature greater than or equal to of 10° C. and less than or equal to 35° C.,
the dQ/dV vs V curve is repeatedly measured within the V range greater than or equal to 4.05 V and less than or equal to 4.58 V,
the dQ/dV vs V curve comprises a first peak within the V range greater than or equal to 4.54 V and less than or equal to 4.58 V,
the dQ/dV vs V curve comprises a second peak within the V range greater than or equal to 4.08 V and less than or equal to 4.18 V, and
the dQ/dV vs V curve comprises a third peak within the V range greater than or equal to 4.18 V and less than or equal to 4.25 V,
wherein the voltage is a voltage with reference to a redox potential of lithium metal,
wherein a peak intensity of the first peak increases in 1st to 10th measurements,
wherein the peak intensity of the first peak decreases in 30th to 100th measurements, and
wherein a voltage at a peak position of the second peak increases in the 30th to 100th measurements.

11. The secondary battery according to claim 10,
wherein at the charging voltage V at which the second peak is observed, the positive electrode has a crystal structure corresponding to a space group P2/m, and
wherein at the charging voltage V at which the first peak is observed, the positive electrode has a crystal structure corresponding to a space group R-3m.

12. The secondary battery according to claim 10,
wherein the secondary battery comprises a negative electrode, and
wherein the negative electrode is lithium metal.

13. The secondary battery according to claim 10,
wherein the secondary battery comprises a negative electrode including graphite.

14. An electronic device comprising:
the secondary battery according to claim 4; and
a display portion.

15. A vehicle comprising:
the secondary battery according to claim 4; and
an electric motor.
